(19) United States
(12) Patent Application Publication
(10) Pub. No.: US 2002/0061451 A1
(43) Pub. Date: May 23, 2002

(54) Intermediate transfer recording medium and method for image formation

(75) Inventors: Tatsuya Kita, Tokyo-To (JP); Hitoshi Saito, Tokyo-To (JP); Katsuyuki Oshima, Tokyo-To (JP); Shinji Kometani, Tokyo-To (JP); Masayasu Yamazaki, Tokyo-To (JP); Kouzou Odamura, Tokyo-To (JP); Takayuki Imai, Tokyo-To (JP); Tadahiro Ishida, Tokyo-To (JP); Etsuo Takasaki, Tokyo-To (JP)

Correspondence Address: Parkhurst, Wendel, L.L.P., Suite 210, 1421 Prince Street, Alexandria, VA, 22314-2805, US

(73) Assignee: DAI NIPPON PRINTING CO., LTD.

(21) Appl. No.: 09/951,405

(22) Filed: Sep. 14, 2001

(30) Foreign Application Priority Data
Sep. 14, 2000 (JP) 2000-279135
Dec. 19, 2000 (JP) 2000-386026
Mar. 16, 2001 (JP) 2001-077085
Apr. 16, 2001 (JP) 2001-116713

(51) Int. Cl. G03C 11/12; G03F 7/09; G03F 7/34; G03F 7/42

(52) U.S. Cl. 430/2; 430/200; 430/201; 430/207; 430/256; 430/259; 430/262; 430/263; 503/227

(57) ABSTRACT

Disclosed is an intermediate transfer recording medium for use in a method which comprises the steps of: forming an image using the intermediate transfer recording medium on an object; and forming a protective layer on the image. In this case, fastness properties can be fully imparted to the image, the protective layer can be transferred onto the image with high accuracy in a simple manner, blocking and the like attributable to the exposure of a pressure-sensitive adhesive do not take place, and the design and the fastness properties are excellent. An image forming method using the intermediate transfer recording medium is also disclosed. The intermediate transfer recording medium 1 comprises: a sheet substrate 4 provided with a resin layer 5; and a transparent sheet 2 provided with a receptive layer 3, the transparent sheet 2 provided with the receptive layer 3 having been put on top of the sheet substrate 4 provided with the resin layer 5 so that the resin layer 5 faces the transparent sheet 2 on its side remote from the receptive layer 3, the resin layer 5 being separable from the transparent sheet 2 to transfer the transparent sheet 2 provided with a receptive layer 3 onto an object, the transparent sheet 2 portion provided with the receptive layer 3 having been half cut (8) in a specific shape and in a predetermined width around the outer periphery of the region 7 to be transferred onto the object. A transfer image is formed on the receptive layer, and the portion with the image formed thereon is re-transferred onto an object to form an image on the object.

### TECHNICAL FIELD

The present invention relates to an intermediate transfer recording medium, which can be used to form an Image on an object, can form a protective layer on the image to impart fastness properties to the image, and permits the protective layer to be transferred onto the image with high accuracy in a simple manner, and a method for image formation using said intermediate transfer recording medium.

### BACKGROUND OF THE INVENTION

Various thermal transfer methods have hitherto been known in the art. In these thermal transfer methods, a thermal transfer sheet comprising a color transfer layer provided on a substrate sheet is image-wise heated from its backside, for example, by means of a thermal head to thermally transfer the color transfer layer onto the surface of a thermal transfer image-receiving sheet, thereby forming an image.

The thermal transfer methods are roughly classified according to the construction of the color transfer layer into two methods, i.e., sublimation dye thermal transfer (sublimation-type thermal transfer) and thermal ink transfer (hot melt-type thermal transfer). For both the methods, full-color images can be formed. For example, a thermal transfer sheet comprising colorant layers of three colors of yellow, magenta, and cyan or optionally four colors of yellow, magenta, cyan, and black is provided, and images of the individual colors are thermally transferred in a superimposition manner on the surface of an identical thermal transfer image-receiving sheet to form a full-color image.

The development of various hardwares and softwares associated with multimedia has led to the expansion of the market of the thermal transfer method as a full-color hard copy system for computer graphics, static images through satellite communication, digital images typified, for example, by images of CD-ROMs (compact disc read only memory), and analog images, such as video images.

Specific applications of the thermal transfer image-receiving sheet used in the thermal transfer method are various, and representative examples thereof include proofs of printing, output of images, output of plans and designs, for example, in CAD/CAM, output of various medical analytical instruments and measuring instruments, such as CT scans and endoscope cameras, alternative to instant photographs, output and printing of photograph-like images of a face or the like onto identification cards or ID cards, credit cards, and other cards, and composite photographs and commemorative photographs, for example, in amusement facilities, such as amusement parks, game centers (amusement arcades), museums, and aquaria.

The diversification of the applications has lead to an increasing demand for the formation of a thermally transferred image on a desired object. One method proposed for meeting this demand comprises the steps: providing an intermediate transfer recording medium comprising a substrate and a receptive layer separably provided on the substrate; providing a thermal transfer sheet having a dye layer; transferring the dye from the thermal transfer sheet to the receptive layer in the intermediate transfer recording medium to form an image on the receptive layer; and then heating the intermediate transfer recording medium to transfer the receptive layer onto an object (see Japanese Patent Laid-Open No. 238791/1987). sublimation transfer-type thermal transfer sheets can faithfully form gradational images, such as photograph-like images of a face. Unlike conventional images produced by printing inks, however, these images disadvantageously lack in fastness properties, such as weathering resistance, abrasion resistance, and chemical resistance.

To solve this problem, a method has been proposed wherein a protective layer thermal transfer film having a thermally transferable resin layer is put on top of a thermally transferred image and the transparent thermally transferable resin layer is transferred, for example, by means of a thermal head or heating roll to form a protective layer on the image.

Further, Japanese Patent Application No. 41441/1999 describes a highly fast intermediate transfer medium comprising a receptive layer provided on a separable transparent substrate. In this intermediate transfer medium, after the formation of an image in the receptive layer, the receptive layer with the image formed thereon, together with the transparent substrate, is brought into contact with an object so that the image surface faces the object to transfer the image onto the object.

### DISCLOSURE OF THE INVENTION

According to the present invention, there is provided an intermediate transfer recording medium comprising: a sheet substrate provided with a resin layer; and a transparent sheet provided with a receptive layer, the transparent sheet provided with the receptive layer having been put on top of the sheet substrate provided with the resin layer so that the resin layer faces the transparent sheet on its side remote from the receptive layer, the resin layer being separable from the transparent sheet to transfer the transparent sheet provided with the receptive layer onto an object.

### BRIEF DESCRIPTION OF THE DRAWINGS

Further, according to the present invention, there is provided a method for image formation using the intermediate transfer recording medium.

FIG. 1 is a plan view showing one embodiment of the intermediate transfer recording medium according to the present invention;

FIG. 2 is a cross-sectional view of the intermediate transfer recording medium shown in FIG. 1;

FIG. 3 is a plan view showing another embodiment of the intermediate transfer recording medium according to the present invention;

FIG. 4 is a cross-sectional view showing a further embodiment of the intermediate transfer recording medium according to the present invention;

FIG. 5 is a schematic perspective view showing the intermediate transfer recording medium of the present invention in a continuously wound form;

FIG. 6 is a schematic diagram illustrating an embodiment of half cutting of the intermediate transfer recording medium according to the present invention;

FIG. 7 is a plan view showing an embodiment of the intermediate transfer recording medium according to the present invention;

FIG. 8 is a cross-sectional view showing an embodiment of the intermediate transfer recording medium according to the present invention;

FIG. 9 is a schematic cross-sectional view showing an embodiment of the intermediate transfer recording medium according to the present invention;

FIG. 10 is a schematic cross-sectional view showing another embodiment of the intermediate transfer recording medium according to the present invention;

FIGS. 11A, 11B, 11C, 11D, and 11E are schematic cross-sectional views illustrating an embodiment of the process for producing an intermediate transfer recording medium according to the present invention;

FIG. 12 is a schematic plan view showing another embodiment of the intermediate transfer recording medium according to the present invention;

FIG. 13 is a schematic cross-sectional view showing an embodiment of the intermediate transfer recording medium according to the present invention;

FIG. 14 is a schematic cross-sectional view showing another embodiment of the intermediate transfer recording medium according to the present invention;

FIGS. 15A, 15B, 15C, and 15D are schematic diagrams illustrating an embodiment of the process for producing an intermediate transfer recording medium according to the present invention; and

FIG. 16 is a schematic plan view showing another embodiment of the intermediate transfer recording medium according to the present invention.

### BEST MODE FOR CARRYING OUT THE INVENTION

First Invention

The conventional transfer-type protective layer should be partially transferred at the time of transfer by means of a thermal head or a heat roll and thus should have good transferability. To this end, the protective layer should be a resin layer having a thickness of about several Am. This makes it impossible to impart fastness properties, such as high scratch resistance and chemical resistance, to images.

In the case of the intermediate transfer recording medium, an image is formed on a substrate provided with a receptive layer, and the receptive layer with the image formed thereon, together with the substrate, is transferred onto an object. Therefore, half cuts should be provided in a shape and at a position conforming to the object.

The intermediate transfer medium is preferably transferred onto the whole area of the object from the viewpoint of design. In this case, at the time of transfer, the registration of the transfer medium with the object should be accurately carried out. At the present time, it is difficult to accurately register the transfer medium with the object in a mechanical manner, and, in order to leave a certain margin, the size of the object is made larger than that of the transfer medium. For this reason, for the intermediate transfer medium, the portion (edge portion) other than the image forming portion should be previously removed When the edge portion is not previously removed, a problem occurs such that a portion other than the image forming portion is also transferred at the time of transfer of the image onto the object.

For this reason, when a protective layer is provided using the above intermediate transfer recording medium, the intermediate transfer recording medium is provided in such a state that the portion other than the image forming portion has been removed. In this case, the adhesive layer is exposed on the surface of the intermediate transfer recording medium in its removed portion. Some adhesive used in the adhesive layer is tacky. In this case, when the intermediate transfer recording medium is rolled or cut into sheets, the adhesive layer sometimes sticks to the backside of the intermediate transfer recording medium due to the tackiness of the adhesive layer. That is, blocking occurs. Further, when the intermediate transfer recording medium is rolled, since the thickness of the image forming portion is different from that of the other portion, that is, since there is a difference in thickness level, the intermediate transfer recording medium is sometimes deformed and causes deformation marks which adversely affects the quality of printed images, for example, disadvantageously causes uneven image quality.

Accordingly, in order to solve the above problems of the prior art, it is an object of the first invention to provide an intermediate transfer recording medium, which can be used to form an image on an object, can form a protective layer on the image to fully impart fastness properties to the image, permits the protective layer to be transferred onto the image with high accuracy in a simple manner, does not cause blocking and the like attributable to the exposure of a pressure-sensitive adhesive, and can provide prints possessing excellent design and fastness properties, and a method for image formation using said intermediate transfer recording medium.

The above object can be attained by an intermediate transfer recording medium comprising: a sheet substrate provided with a resin layer; and a transparent sheet provided with a receptive layer, said transparent sheet provided with the receptive layer having been put on top of the sheet substrate provided with the resin layer so that the resin layer faces the transparent sheet on its side remote from the receptive layer, the resin layer being separable from the transparent sheet to transfer the transparent sheet provided with the receptive layer onto an object, the transparent sheet portion including the receptive layer having been half cut in a specific shape.

Preferably, the half cutting in the specific shape has been carried out by removing the transparent sheet provided with the receptive layer in a predetermined width around the outer periphery of the region to be transferred onto the object.

Preferably, the transparent sheet, provided with the receptive layer, in its removed portion is continuous in the direction of flow. According to this construction, refuse generated in the removal of the non-transfer region in a predetermined width in the outer periphery of the region to be transferred can be continuously removed with high efficiency.

Preferably, the intermediate transfer recording medium is in such a form that has been continuously wound.

Further, preferably, the intermediate transfer recording medium has an identification mark for detecting the half cut.

According to the present invention, there is provided a method for image formation, comprising the steps of: providing the above intermediate transfer recording medium; forming a transfer image on the receptive layer in the intermediate transfer recording medium; and re-transferring only the image-formed portion onto an object to form an image on the object.

According to the present invention, there is also provided a method for image formation, comprising the steps of: providing the above intermediate transfer recording medium; forming a transfer image on the receptive layer in the intermediate transfer recording medium; transferring an adhesive layer onto the receptive layer; and re-transferring only the portion with the image and the adhesive layer formed thereon onto an object to form an image on the object.

In the intermediate transfer recording medium according to the present invention, a sheet substrate provided with a resin layer is stacked onto a transparent sheet provided with a receptive layer, and the intermediate transfer recording medium is separable in its portion between the resin layer and the transparent sheet to transfer the transparent sheet provided with the receptive layer onto an object. The transparent sheet portion including the receptive layer having been half cut in a specific shape, preferably by removing the transparent sheet provided with the receptive layer in a predetermined width around the outer periphery of the region to be transferred onto the object.

The intermediate transfer recording medium is used to form a transfer image on the receptive layer, and the image formed portion is then re-transferred onto an object to form an image on the object. Since the transparent sheet provided with the receptive layer is partially removed outward from the end of the region to be transferred onto the object, an unnecessary portion is not transferred onto the object. Further, there is no possibility that, in the intermediate transfer recording medium, a pressure-sensitive adhesive is exposed leading to blocking or the like.

Therefore, the resultant print is such that the transparent sheet covers the surface of the image formed portion and thus functions as an even firm protective layer. Thus, fastness properties can be fully imparted to images Further, since the transparent sheet portion is previously cut in the half cut inside portion, the protective layer can be simply transferred onto the object for each image with high accuracy. By virtue of this, prints thus obtained have excellent design and fastness properties.

The present invention will be described in more detail with reference to the following preferred embodiments.

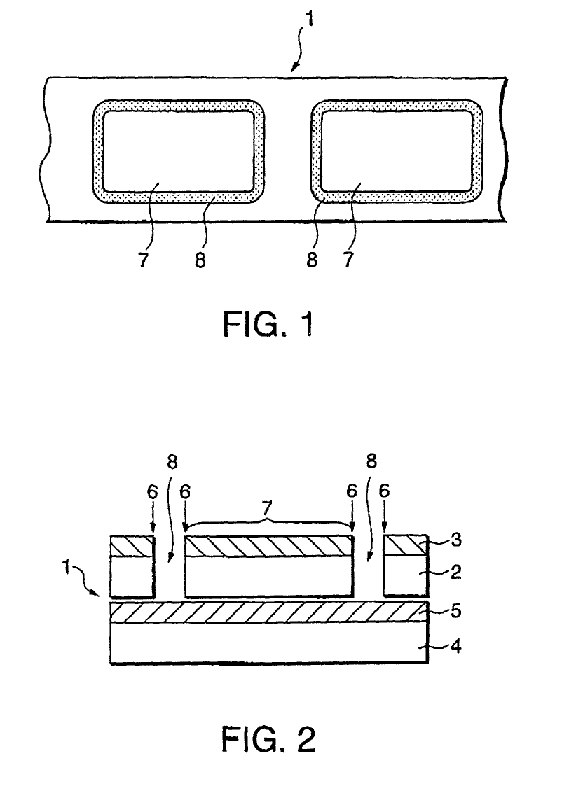

FIG. 1 is a plan view of an embodiment of the intermediate transfer recording medium according to the present invention. A continuous intermediate transfer recording medium 1 has a rectangular region 7 having rounded four corners to be transferred onto an object, and a portion 8, where the transparent sheet provided with the receptive layer has been removed in a predetermined width, is present around the outer periphery of the region 7. The region 7 and the removed portion 8 are repeatedly provided in the direction of flow.

FIG. 2 is a schematic cross-sectional view of a position indicated by an arrow in FIG. 1. In the intermediate transfer recording medium 1, a sheet substrate 4 provided with a resin layer 5 is stacked onto a transparent sheet 2 provided with a receptive layer 3 so that the resin layer 5 faces the transparent sheet 2 on its side remote from the receptive layer 3. The resin layer 5 being separable from the transparent sheet 2 to transfer the transparent sheet 2 provided with a receptive layer 3 onto an object. The transparent sheet 2 portion including the receptive layer 3 has been subjected to half cutting 6 in a specific shape and in a predetermined width around the outer periphery of the region 7, to be transferred onto the object, to provide a removed portion 8.

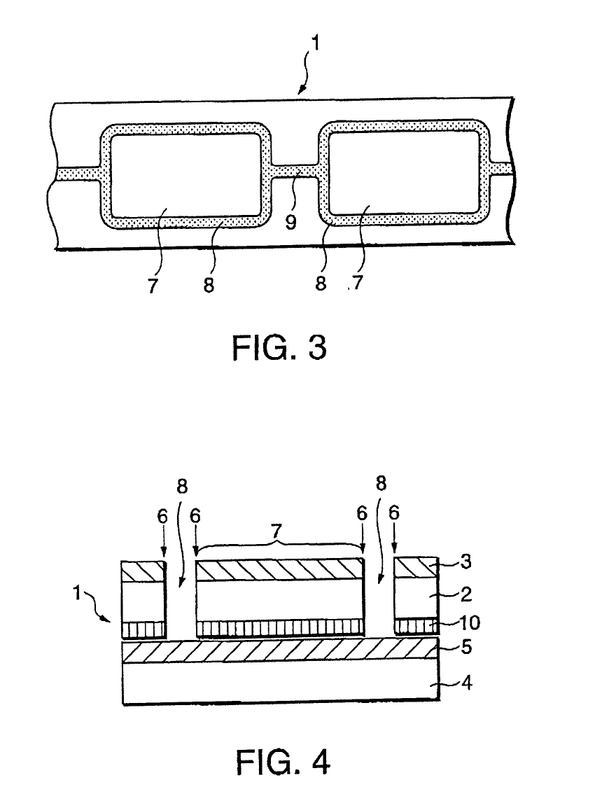

FIG. 3 is a plan view showing another embodiment of the intermediate transfer recording medium according to the present inventions According to this embodiment, in a continuous intermediate transfer recording medium 1, a rectangular region 7 having rounded four corners to be transferred onto an object is repeatedly provided in the direction of flow, and a portion 8, where the transparent sheet provided with the receptive layer has been removed in a predetermined width, is present around the outer periphery of the region 7. Further, adjacent removed portions 8 are continuously connected to each other through a connection 9 in the direction of flow. By virtue of this, refuse generated in the removal of the non-transfer region in a predetermined width in the outer periphery of the region to be transferred can be continuously removed with high efficiency.

FIG. 4 is a cross-sectional view showing a further embodiment of the intermediate transfer recording medium according to the present invention. This intermediate transfer recording medium 1 comprises: a sheet substrate 4 provided with a resin layer 5; and a transparent sheet 2 having a receptive layer 3 on its one side with the other side having been subjected to release treatment 10, the sheet substrate 4 provided with resin layer 5 having been put on top of the transparent sheet 2 provided with the receptive layer 3 so that the resin layer 5 faces the surface subjected to the release treatment 10, the resin layer 5 being separable from the surface subjected to the release treatment 10. The transparent sheet 2 portion including the receptive layer 3 and the portion subjected to the release treatment 10 has been subjected to half cutting 6 in a predetermined width around the outer periphery of a region 7, to be transferred onto an object, to provide a removed portion indicated by numeral 8.

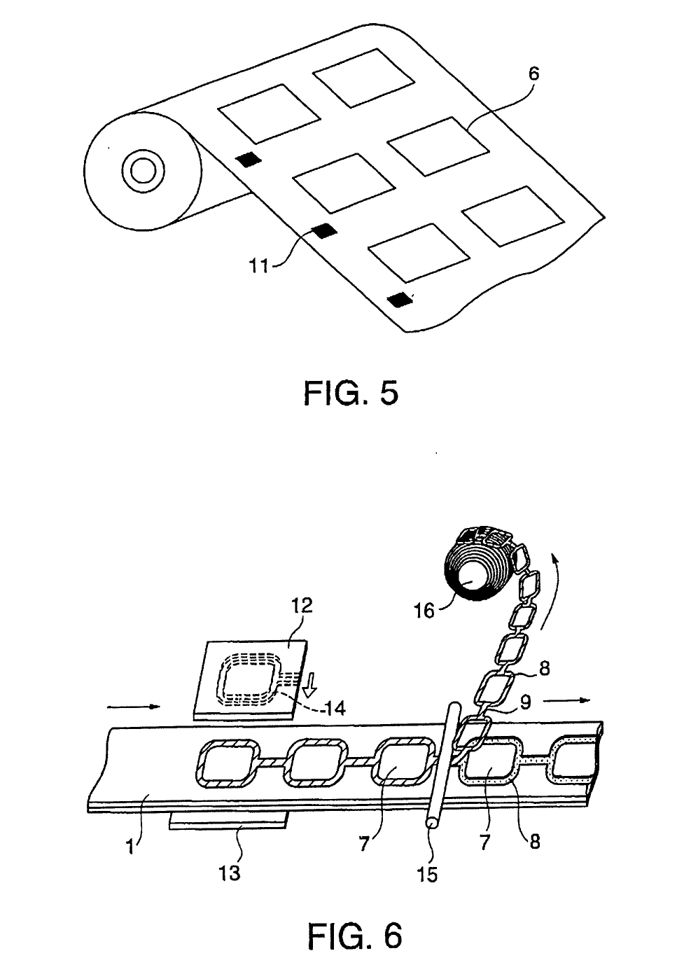

FIG. 5 is a schematic perspective view showing the intermediate transfer recording medium of the present invention in a continuously wound form. In this intermediate transfer recording medium, identification marks 11 for detecting the half cuts 6 are provided. The identification marks can be detected to transfer the transparent sheet, provided with the receptive layer with an image formed thereon, onto an object and, in addition, to form an image on the receptive layer in its predetermined position. Detection marks for image formation can also be provided separately from the identification marks.

(Transparent Sheet)

In the transparent sheet 2 in the intermediate transfer recording medium according to the present invention, the transparent sheet portion is cut using the half cut portion as the boundary between the removal portion and the portion remaining unremoved, and the transparent sheet can function as a protective layer in such a state that the transparent sheet covers the surface of the image formed portion.

The transparent sheet may be any one so far as the sheet is transparent and has fastness properties, such as weathering resistance, abrasion resistance, and chemical resistance. Examples of transparent sheets usable herein include about 0.5 to 100 μm-thick, preferably about 10 to 40 μm-thick, films of polyethylene terephthalate, 1,4-polycyclohexylene dimethylene terephthalate, polyethylene naphthalate, polyphenylene sulfide, polystyrene, polypropylene, polysulfone, aramid, polycarbonate, polyvinyl alcohol, cellulose derivatives, such as cellophane and cellulose acetate, polyethylene, polyvinyl chloride, nylon, polyimide, and ionomer.

(Release Treatment)

The transparent sheet in its side facing the resin layer may be subjected to release treatment 10 to facilitate the separation of the transparent sheet from the resin layer.

In the release treatment 8, a release layer is provided on the transparent sheet. The release layer may be formed by coating a coating liquid containing a wax, silicone wax, a silicone resin, a fluororesin, an acrylic resin, a polyvinyl alcohol rein, or a cellulose derivative resin or a copolymer of monomers constituting the above group of resins onto the transparent sheet by conventional means, such as gravure printing, screen printing, or reverse roll coating using a gravure plate, and drying the coating.

The thickness of the release layer is about 0.1 to 10 μm on a dry basis.

(Receptive Layer)

The receptive layer 3 may be formed on the transparent sheet either directly or through a primer layer. The construction of thereceptive layer 3 varies depending upon the recording system, that is, whether the recording system is hot-melt transfer recording or sublimation transfer recording. In the hot-melt transfer recording, a method may also be adopted wherein a color transfer layer is thermally transferred from the thermal transfer sheet directly onto the transparent sheet without providing the receptive layer. In the hot-melt transfer recording and the sublimation transfer recording, the receptive layer functions to receive a colorant thermally transferred from the thermal transfer sheet. In particular, in the case of the sublimable dye, preferably, the receptive layer receives the dye, develops a color, and, at the same time, does not permit re-sublimation of the once received dye.

A transfer image is formed on a receptive layer in an intermediate transfer recording medium, and only the image formed portion is re-transferred onto an object to form an image on the object. The receptive layer according to the present invention is generally transparent so that an image transferred onto the object can be clearly viewed from the top. However, it is also possible to intentionally make the receptive layer opaque or to intentionally lightly color the receptive layer to render the re-transferred image distinct.

The receptive layer is generally composed mainly of a thermoplastic resin. Examples of materials usable for forming the receptive layer include: polyolefin resins such as polypropylene; halogenated polymers such as vinyl chloride-vinyl acetate copolymer, ethylene-vinyl acetate copolymer, and polyvinylidene chloride; polyester resins such as polyvinyl acetate and polyacrylic esters; polystyrene resins; polyamide resins; copolymer resins produced from olef ins, such as ethylene and propylene, and other vinyl monomers; ionomers; cellulosic resins such as cellulose diacetate; and polycarbonate resins. Among them, polyester resins and vinyl chloride-vinyl acetate copolymer and mixtures of these resins are particularly preferred.

In sublimation transfer recording, a release agent may be incorporated into the receptive layer, for example, from the viewpoint of preventing fusing between the thermal transfer sheet having a color transfer layer and the receptive layer in the intermediate transfer recording medium at the time of image formation or preventing a lowering in sensitivity in printing. Preferred release agents usable as a mixture include silicone oils, phosphoric ester surfactants, and fluorosurfactants. Among them, silicone oils are preferred. Preferred silicone oils include epoxy-modified, vinyl-modified, alkyl-modified, amino-modified, carboxyl-modified, alcohol-modified, fluorine-modified, alkyl aralkyl polyether-modified, epoxy-polyether-modified, polyether-modified and other modified silicone oils.

A single or plurality of release agents may be used. The amount of the release agent added is preferably 0.5 to 30 parts by weight based on 100 parts by weight of the resin for the receptive layer. When the amount of the release agent added is outside the above amount range, problems some times occur such as fusing between the sublimation-type thermal transfer sheet and the receptive layer in the intermediate transfer recording medium or a lowering in sensitivity in printing. The addition of the release agent to the receptive layer permits the release agent to bleed out on the surface of the receptive layer after the transfer to form a release layer. Alternatively, these release agents may be separately coated onto the receptive layer without being incorporated into the receptive layer.

The receptive layer may be formed by coating a solution of a mixture of the above resin with a necessary additive, such as a release agent, in a suitable organic solvent, or a dispersion of the mixture in an organic solvent or water onto a transparent sheet by conventional forming means such as gravure coating, gravure reverse coating, or roll coating, and drying the coating.

The receptive layer may be formed in any thickness. In general, however, the thickness of the receptive layer is 1 to 50 μm on a dry basis.

The receptive layer is preferably in the form of a continuous coating. However, the receptive layer may be in the form of a discontinuous coating formed using a resin emulsion, a water-soluble resin, or a resin dispersion. Further, an antistatic agent may be coated onto the receptive layer from the viewpoint of realizing stable carrying of sheets through a thermal transfer printer.

(Sheet Substrate)

The sheet substrate 4 used in the present invention is not particularly limited, and examples thereof include: various types of paper, for example, capacitor paper, glassine paper, parchment paper, or paper having a high sizing degree, synthetic paper (such as polyolefin synthetic paper and polystyrene synthetic paper), cellulose fiber paper, such as wood free paper, art paper, coated paper, cast coated paper, wall paper, backing paper, synthetic resin- or emulsion-impregnated paper, synthetic rubber latex-impregnated paper, paper with synthetic resin internally added thereto, and paperboard; and films of polyester, polyacrylate, polycarbonate, polyurethane, polyimide, polyether imide, cellulose derivative, polyethylene, ethylene-vinyl acetate copolymer, polypropylene, polystyrene, acrylic resin, polyvinyl chloride, polyvinylidene chloride, polyvinyl alcohol, polyvinyl butyral, nylon, polyether ether ketone, polysulfone, polyether sulfone, tetrafluoroethylene-perfluoroalkyl vinyl ether, polyvinyl fluoride, tetrafluoroethylene-ethylene, tetrafluoroethylene-hexafluoropropylene, polychlorotri-fluoroethylene, polyvinylidene fluoride and the like.

The thickness of the sheet substrate is preferably 10 to 100 μm. When the sheet substrate is excessively thin, the resultant intermediate transfer recording medium is not sturdy and thus cannot be carried by means of a thermal transfer printer or is disadvantageously curled or cockled. On the other hand, when the sheet substrate is excessively thick, the resultant intermediate transfer recording medium is excessively thick. In this case, the driving force of the thermal transfer printer necessary for carrying the intermediate transfer recording medium is excessively large, resulting in a printer trouble or a failure of the intermediate transfer recording medium to be normally carried.

(Resin Layer)

The resin layer 5 may be provided as a pressure-sensitive adhesive layer, an easy-adhesion adhesive layer, or an extrusion coating (EC) on the sheet substrate.

The pressure-sensitive adhesive layer may be formed of a conventional solvent-type or aqueous pressure-sensitive adhesive. Pressure-sensitive adhesives include, for example, vinyl acetate resins, acrylic resins, vinyl acetate-acryl copolymers, vinyl acetate-vinyl chloride copolymers, ethylene-vinyl acetate copolymers, polyurethane resins, various silicone resins, natural rubbers, chloroprene rubbers, and nitrile rubbers.

The coverage of the pressure-sensitive adhesive layer is generally about 8 to 30 g/m² on a solid basis, and the pressure-sensitive adhesive layer may be formed by coating the pressure-sensitive adhesive by a conventional method, for example, gravure coating, gravure reverse coating, roll coating, Komma coating, or die coating, on a release sheet and drying the coating. The adhesive strength of the pressure-sensitive adhesive layer is preferably approximately in the range of 5 to 1,000 g, in terms of peel strength between the transparent sheet and the pressure-sensitive adhesive layer, as measured by a 180-degree peel method according to JIS Z 0237.

In the formation of the pressure-sensitive adhesive layer on the sheet substrate, the above-described type of adhesive and coverage are preferably selected so that the peel strength is in the above-defined range. When the pressure-sensitive adhesive layer is provided on the sheet substrate and the transparent sheet is stacked onto the pressure-sensitive adhesive layer, a method may be adopted such as dry lamination or hot-melt lamination of the pressure-sensitive adhesive layer.

In the formation of the easy-adhesion adhesive layer, preferably, a latex of styrene-butadiene copolymer rubber (SBR), an acrylic resin, such as acrylonitrile-butadiene copolymer rubber (NBR) or a polyacrylic ester, a rubbery resin, a wax, or a mixture of two or more of the above materials is coated onto a sheet substrate by a conventional coating method, and the easy-adhesion adhesive layer is then stacked onto the transparent sheet by dry lamination with heating. The easy-adhesion adhesive layer after the separation of the transparent sheet from the sheet substrate has lowered tackiness and no longer can be used in the application of the transparent sheet to the sheet substrate.

When this easy-adhesion adhesive layer is used, a primer layer may be provided between the sheet substrate and the easy-adhesion adhesive layer.

Further, an EC layer may be provided as the resin layer according to the present invention on the sheet substrate.

The thermoplastic resin used for forming the EC layer is not particularly limited so far as the resin is not virtually adhered to the transparent sheet and is extrudable. In particular, however, a polyolefin resin is preferred which is not virtually adhered to PET films generally utilized in the transparent sheet and has excellent processability. More specifically, for example, LDPE, MDPE, HDPE, and PP resins are usable. In extrusion coating these resins, when a matte roll is used as a cooling roll, the matte face may be transferred onto the surface of the EC layer, whereby fine concaves and convexes can be formed to render the EC layer opaque.

Alternatively, a method may be used wherein a white pigment, such as calcium carbonate or titanium oxide, is mixed into the polyolefin resin to form an opaque EC layer.

The EC layer may be either a single-layer structure or a multi-layer structure of two or more layers The peel strength of the EC layer from the transparent sheet may be regulated according to the processing temperature in the extrusion and the type of the resin.

Thus, simultaneously with the extrusion of the EC layer on the sheet substrate, the sheet substrate can be stacked onto the transparent sheet through the EC layer by the so-called “EC lamination.”

(Primer Layer)

In providing the resin layer on the sheet substrate, a primer layer may be provided on the surface of the sheet substrate to improve the adhesion between the sheet substrate and the resin layer. Instead of the provision of the primer layer, the surface of the sheet substrate may be subjected to corona discharge treatment.

The primer layer may be formed by providing a coating liquid in the form of a solution or dispersion of a polyester resin, a polyacrylic ester resin, a polyvinyl acetate resin, a polyurethane resin, a polyamide resin, a polyethylene resin, a polypropylene resin or the like in a solvent and coating the coating liquid by the same means as used in the formation of the receptive layer.

The thickness of the primer layer is about 0.1 to 5 μm on a dry basis.

The primer layer may also be formed between the transparent sheet and the receptive layer in the same manner as described above.

A suitable slip layer (not shown) may be provided on the sheet substrate in its side remote from the resin layer, for example, from the viewpoint of improving carriabiltiy at the time of sheet feeding in the thermal transfer printer. The slip layer may be formed of a single resin or a blend of two or more resin selected from conventional resins, such as butyral resins, polyacrylic esters, polymethacrylic esters, polyvinylidene chloride, polyesters, polyurethane, polycarbonate, and polyvinyl acetate, a lubricant, such as various fine particles or silicone, having been added to the single resin or the resin blend.

The intermediate transfer recording medium according to the present invention has a construction such that at least a receptive layer, a transparent sheet, a resin layer, and a sheet substrate are stacked in that order on top of one another and the resin layer is separably applied to the transparent sheet. An antistatic layer may be provided on the surface of the receptive layer, the backside of the sheet substrate, or the outermost surface of both sides. The antistatic layer may be formed by coating a solution or dispersion of an antistatic agent, such as a fatty ester, a sulfuric ester, a phosphoric ester, an amide, a quaternary ammonium salt, a betaine, an amino acid, an acrylic resin, or an ethylene oxide adduct, in a solvent. The forming means used may be the same as that used in the formation of the receptive layer. The coverage of the antistatic layer is preferably 0.001 to 0.1 g/m² on a dry basis.

An intermediate layer formed of one of various resins may be provided between the substrate and the receptive layer in the transparent sheet. In this case, the intermediate layer is preferably transparent so that the re-transferred image can be viewed. When the intermediate layer has various functions excellent functions can be imparted to the image-receiving sheet For example, a highly elastically deformable or plastically deformable resin, for example, a polyolefin resin, a vinyl copolymer resin, a polyurethane resin, or a polyamide resin, may be used as a cushioning property-imparting resin to improve the sensitivity in printing of the image-receiving sheet or to prevent harshness of images. Antistatic properties may be imparted to the intermediate layer by adding the antistatic agent to the cushioning property-imparting resin, dissolving or dispersing the mixture in a solvent, and coating the solution or dispersion to form an intermediate layer.

(Half Cutting)

In the intermediate transfer recording medium according to the present invention, the transparent sheet portion including the receptive layer has been subjected to half cutting 6. The half cut may be formed by any method without particular limitation so far as half cutting is possible. Examples of methods usable for half cutting include a method wherein the intermediate transfer recording medium is inserted into between an upper die, provided with a cutter blade, and a pedestal and the upper die is then vertically moved, a method wherein a cylinder-type rotary cutter is used, and a method wherein heat treatment is carried out by means of a laser beam.

FIG. 6 is a schematic diagram illustrating an embodiment of half cutting of the intermediate transfer recording medium according to the present invention. At the outset, the intermediate transfer recording medium 1 composed of the sheet substrate provided with the resin layer and, stacked onto the resin layer, the transparent sheet provided with the receptive layer is fed into between an upper die 12, provided with a cutter blade 14, and a pedestal 13, and the upper die 12 is then moved downward to cut the transparent sheet provided with the receptive layer by means of the cutter blade 14 in the intermediate transfer recording medium 1. In the embodiment shown in the drawing, the region 7 to be transferred onto one unit of object is subjected to half cutting, the adjacent region is then subjected to half cutting, and this procedure is repeated to perform continuous half cutting. In this connection, it should be noted that a plurality of units of the region 7 may be simultaneously subjected to half cutting.

In the intermediate transfer recording medium 1 subjected to half cutting, refuse is then continuously removed from the transparent sheet provided with the receptive layer by means of a separation roll 15 in such a state that a portion (8) around the outer periphery of the region 7 to be transferred onto the object is connected to a connection 9. The refuse is wound by means of a refuse removing roll 16.

Thus, in the intermediate transfer recording medium 1, in the step of removing of refuse, the transparent sheet provided with the receptive layer is removed in the portion 8 around the outer periphery of the region 7 to be transferred onto the object and the connection 9, whereby the intermediate transfer recording medium 1 specified in the present invention is prepared.

As shown in FIG. 1, when only the transparent sheet side in its portion around the outer periphery of the region 7 to be transferred onto an object is removed (that is, when no connection is provided), continuous removal of the refuse as described above is impossible. In this case, for example, the refuse may be removed by a specialty refuse removing tool of vacuum type, tack type or other type which has a size slightly smaller than the size of the portion to be removed on the transparent sheet side.

Thus, in the intermediate transfer recording medium according to the present invention, the provision of a portion subjected to half cutting in a specific shape in the transparent sheet portion including the receptive layer, that is, a portion, from which the transparent sheet provided with the receptive layer has been removed in a predetermined width, around the outer periphery of the region to be transferred onto the object, is advantageous in that, even when the resin layer in contact with the transparent sheet is exposed, since the resin layer is partially exposed, that is, since the unexposed portion is larger than the exposed portion (the exposed portion is surrounded by the unexposed portion), there is no fear of blocking or the like occurring in the exposed portion.

Further, in the intermediate transfer recording medium according to the present invention, the transparent sheet provided with the receptive layer has been removed in a predetermined width in a portion around the outer periphery of the region to be transferred onto the object. Therefore, even when the printing position is slightly deviated from the contemplated position at the time of image formation, printing is made on only the region to be transferred onto the object and the image is not formed at an unnecessary position. Further, in re-transferring the transparent sheet side, with an image formed thereon, onto the object, even when the positional accuracy in the re-transfer is not very high (that is, even when the re-transfer position is somewhat deviated from the contemplated position), any unnecessary portion is not re-transferred and only the proper region is re-transferred onto the object.

At the time of half cutting of the transparent sheet side including the receptive layer in the intermediate transfer recording medium, when the transparent sheet side is excessively cut in the depth direction, that is, when not only the transparent sheet portion but also the sheet substrate is cut, the whole intermediate transfer recording medium is cut at the cut portion during carriage in the printer, often leading to carriage troubles. On the other hand, when the cut level is excessively low in the depth direction, for example, when a cut is provided, for example, only in the receptive layer without the provision of a cut in the transparent sheet, cutting-off disadvantageously occurs at a position different from the proper cut position at the time of the removal of the refuse on the transparent sheet side.

Therefore, as shown in FIGS. 2 and 4, the depth of the cutting (half cutting) is preferably on a level such that passes through the receptive layer and the transparent sheet and slightly bites the resin layer in the thicknesswise direction.

The half cutting according to the present invention may be previously carried out before the formation of an image on the receptive layer in the intermediate transfer recording medium, or alternatively, the half cutting may be carried out according to the image region after the formation of an image on the receptive layer in the intermediate transfer recording medium.

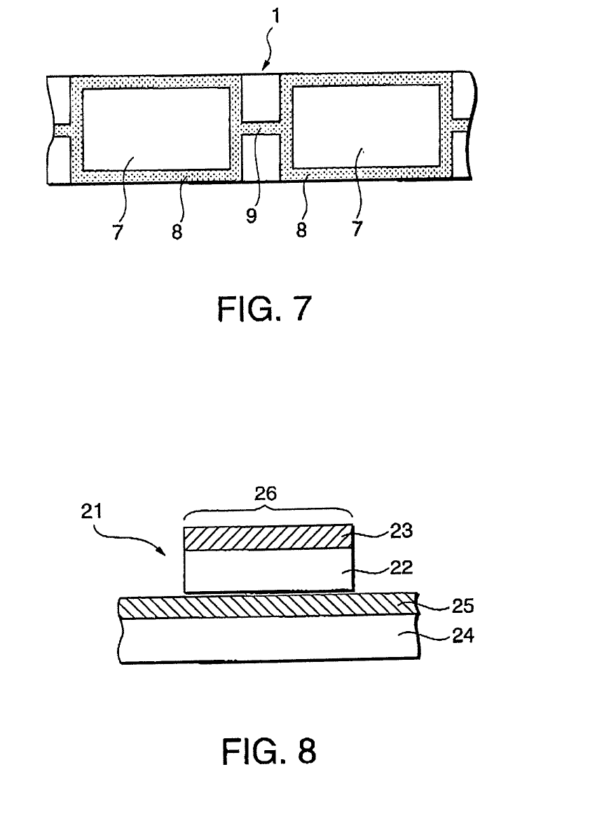

FIG. 7 is a plan view showing one embodiment of the intermediate transfer recording medium according to the present invention. In this embodiment, a rectangular region 7 to be transferred onto an object is repeatedly provided in the flow direction of a continuous intermediate transfer recording medium 1, and portions 8, where the transparent sheet side including the receptive layer has been removed in a predetermined width around the outer periphery of the region 7 and the adjacent portions 8, from which the transparent sheet side including the receptive layer has been removed, are continuously connected to each other through a connection 9 in the flow direction. This can realize continuous removal of refuse with high efficiency. The intermediate transfer recording medium shown in FIG. 7 is different from the intermediate transfer recording medium shown in FIG. 3 in that the portion 8 in the outer periphery of the rectangular region 7 to be transferred onto the object is located at a position that overlaps with the end of the intermediate transfer recording medium per se at both end portions in the flow direction.

FIG. 7 shows an embodiment where the corners of the rectangular region 7 to be transferred onto an object and the angle of the corners of the connection 9 are formed at right angle. Preferably, as shown in FIGS. 1, 3, and 6, the corners of the region 7 to be transferred onto an object and the corners of the connection 9 are rounded (R is provided) so as to avoid cutting of refuse on the transparent sheet side from the right-angle corners at the time of the removal of the refuse.

(Identification Mark)

An identification mark 11 for detecting the half cut portion may be provided in the intermediate transfer recording medium according to the present invention.

For example, the shape or the color of the identification mark is not particularly limited so far as the identification mark is detectable with a detector. Examples of shapes of the identification mark include quadrangle as shown in FIG. 5, circle, bar cord, and line extending from the end to end in the widthwise direction of the intermediate transfer recording medium.

The color of the identification mark may be any one detectable with a detector. For example, when a light transmission detector is used, silver, black and other colors having a high level of opaqueness may be mentioned as the color of the identification mark. When a light reflection detector is used, for example, a highly light reflective metalescent color may be mentioned as the color of the identification mark.

The identification mark may be formed by any method without particular limitation, and examples of methods usable herein include the provision of through holes which extend from the surface to the backside of the intermediate transfer recording medium, gravure printing or offset printing, the provision of a deposit film by hot stamping using a transfer foil, and the application of a deposit film provided with a pressure-sensitive adhesive on the backside of the intermediate transfer recording medium.

(Method for Image Formation)

The method for image formation according to the present invention comprises the steps of: providing the above intermediate transfer recording medium; putting the intermediate transfer recording medium and a thermal transfer sheet on top of each other so that a transfer layer in the thermal transfer sheet comes into contact with the receptive layer; heating the assembly to form a transfer image on the receptive layer; putting the intermediate transfer recording medium and an object on top of each other so that the receptive layer face comes into contact with the object; and pressing the assembly with heating to re-transfer only a region 7 with the image formed thereon onto the object to form an image on the object.

In this case, when the image formed portion is put on top of the object followed by pressing with heating, the image formed portion is included in the area of pressing with heating. Even when the area of pressing with heating is somewhat different from the portion 8 having a predetermined width, around the outer periphery of the region 7, from which the transparent sheet provided with the receptive layer has been removed, the image provided with the transparent sheet, that is, a protective layer, can be transferred onto the object with good accuracy in a simple manner, because the region 7 is independently provided and is not connected to other portions.

Alternatively, the method for image formation may comprise the steps of: providing the above intermediate transfer recording medium; putting the intermediate transfer recording medium and a thermal transfer sheet on top of each other so that a transfer layer in the thermal transfer sheet comes into contact with the receptive layer; heating the assembly to form a transfer image on the receptive layer; further transferring an adhesive layer onto the receptive layer; putting the intermediate transfer recording medium and an object on top of each other so that the adhesive layer face comes into contact with the object; and pressing the assembly with heating to retransfer only a region with the image and the adhesive layer formed thereon onto the object to form an image on the object.

The transfer of the adhesive layer onto the receptive layer will be described in detail.

The adhesive layer may be transferred onto the receptive layer, for example, by providing an adhesive sheet, which has been formed into a film, inserting the adhesive sheet into between the receptive layer face with the image formed thereon and the object and heat pressing the assembly to adhere the image-receptive layer and the transparent sheet onto the object.

A method may also be adopted which comprises the steps of: providing an adhesive layer transfer sheet comprising an adhesive layer provided on a release paper; and heat pressing the adhesive layer in the adhesive layer transfer sheet against the surface of the receptive layer with the image formed thereon to transfer the adhesive layer.

Adhesive components usable in the adhesive sheet or the adhesive layer transfer sheet include thermoplastic synthetic resins, naturally occurring resins, rubbers, and waxes, and examples thereof include: synthetic resins, for example, cellulose derivatives such as ethylcellulose and cellulose acetate propionate, styrene polymers such as polystyrene and poly-α-methylstyrene, acrylic resins such as polymethyl methacrylate, polyethyl methacrylate, and polyethyl acrylate, vinyl resins such as polyvinyl chloride, polyvinyl acetate, vinyl chloride-vinyl acetate copolymer, and polyvinyl butyral, polyester resins, polyamide resins, epoxy resins, polyurethane resins, ionomers, olef ins, and ethylene-acrylic acid copolymers; and tackifiers, for example, naturally occurring resin and synthetic rubber derivatives, such as rosins, rosin-modified maleic acid resins, ester gums, polyisobutylene rubbers, butyl rubbers, styrene-butadiene rubbers, and butadiene-acrylonitrile rubbers. A single or plurality of adhesive components may be used, and the use of a material, which can develop adhesive properties upon heating, is preferred.

The thickness of the adhesive sheet or the adhesive layer in the adhesive layer transfer sheet is about 0.1 to 500 μm.

In the transfer of the adhesive layer, for example, a thermal head used in the formation of a transferred image, a line heater, a neat roll, or a hot stamp may be used as heating means An image may be formed on the intermediate transfer recording medium by a conventional sublimation thermal transfer method or hot-melt thermal transfer method. For example, a thermal transfer sheet comprising color transfer layers of three colors of yellow, cyan, and magenta provided in a face serial manner is used to form a desired full-color image on the receptive layer in the intermediate transfer recording medium by a conventional thermal transfer printer of thermal head type or laser heating type. Next, the transparent sheet including the receptive layer with the image formed thereon may be separated from the sheet substrate provided with the resin layer and transferred and applied to a desired object.

For example, a thermal head used in the formation of a transferred image, a line heater, a heat roll, or a hot stamp may be used as means for transferring the transparent sheet including the receptive layer with the image formed thereon onto an object.

It should be noted that, in order that the image finally formed on the object according to the present invention is properly oriented, an image, which is in a mirror image relationship with the final image, should be formed on the receptive layer in the intermediate transfer recording medium.

The object, on which the image is re-transferred from the intermediate transfer recording medium according to the present invention, is not particularly limited. For example, any sheet of plain paper, wood free paper, tracing paper, and plastic film may be used. Regarding the shape of the object, for example, any of cards, postal cards, passports, letter paper, report pads, notebooks, catalogs, cups, and cases may be used.

Second Invention

When an Image is formed using a conventional hot-melt transfer-type thermal transfer sheet, the resultant image disadvantageously lacks in a fastness property, that is, abrasion resistance. On the other hand, sublimation transfer-type thermal transfer sheets can faithfully form gradational (halftone) images, such as photograph-like images of a face. Unlike conventional images produced by printing inks, however, these images disadvantageously lack in fastness properties, such as weathering resistance, abrasion resistance, and chemical resistance.

To solve this problem, a method has been proposed wherein a protective layer thermal transfer film having a thermally transferable resin layer is put on top of a thermally transferred image and the transparent thermally transferable resin layer is transferred, for example, by means of a thermal head or heating roll to form a protective layer on the image.

Further, Japanese Patent Application No. 41441/1999 describes a highly fast intermediate transfer recording medium comprising a transparent substrate, provided with a receptive layer, and a sheet substrate, the transparent substrate having been separably stacked onto the sheet substrate through a resin layer. In this intermediate transfer recording medium, after the formation of an image in the receptive layer, the receptive layer with the image formed thereon, together with the transparent substrate, is brought into contact with an object so that the image surface faces the object to transfer the image onto the object.

The conventional transfer-type protective layer should be partially transferred at the time of transfer by means of a thermal head or a heat roll and thus should have good transferability. To this end, the protective layer should be a resin layer having a thickness of about several μm. This makes it impossible to impart fastness properties, such as high scratch resistance and chemical resistance, to images.

Further, in the case of the above intermediate transfer recording medium, for example, in a pressure-sensitive adhesive layer or an easy-adhesion adhesive layer used as the resin layer, the peel force is likely to be increased, for example, with the elapse of time, and this poses a problem that, in the transfer of an image onto an object, the resin layer is left on the object side, or otherwise, image formation cannot be normally carried out.

Further, in the above intermediate transfer recording medium, when the portion except for the image forming region is previously removed, the resin layer is exposed on the surface. In this case, at the time of thermal transfer, the image forming portion is frequently shifted to the resin layer. This causes fusing between the thermal transfer sheet and the intermediate transfer recording medium, disadvantageously leading to breaking of the thermal transfer sheet.

Accordingly, in order to solve the above problems of the prior art, it is an object of the second invention to provide an intermediate transfer recording medium, which can be used to form an image on an object, can form a protective layer on the image to fully impart fastness properties to the image, is free from fusing between a thermal transfer sheet and the intermediate transfer recording medium, and can form a good image on an object.

The above object can be attained by an intermediate transfer recording medium comprising: a sheet substrate provided with a resin layer; and a transparent sheet provided with a receptive layer, the transparent sheet provided with the receptive layer having been put on top of the sheet substrate provided with the resin layer so that the resin layer faces the transparent sheet on its side remote from the receptive layer, the resin layer being separable from the transparent sheet to transfer the transparent sheet provided with the receptive layer onto an object, the resin layer being formed of a hydrosilylation-type silicone pressure-sensitive adhesive. According to this construction, the use of the hydrosilylation-type silicone pressure-sensitive adhesive in the resin layer can complete the curing reaction of the resin layer in a short time at a low temperature and can eliminate a change in peel force between the resin layer and the transparent sheet with the elapse of time.

The peel force between the resin layer and the transparent sheet is preferably 0.01 to 0.5 N/inch. This facilitates the separation of the sheet substrate from the transparent sheet at the time of the transfer of an image onto the object after the formation of the image on the receptive layer.

A filler is preferably incorporated into the resin layer, and this can improve the strength of the resin layer.

The intermediate transfer recording medium according to the present invention comprises: a sheet substrate provided with a resin layer; and a transparent sheet provided with a receptive layer, the transparent sheet provided with the receptive layer having been put on top of the sheet substrate provided with the resin layer so that the resin layer faces the transparent sheet on its side remote from the receptive layer, the resin layer being separable from the transparent sheet to transfer the transparent sheet provided with the receptive layer onto an object, the resin layer being formed of a hydrosilylation-type silicone pressure-sensitive adhesive. According to this construction, the use of the hydrosilylation-type silicone pressure-sensitive adhesive in the resin layer can complete the curing reaction of the resin layer in a short time at a low temperature and can eliminate a change in peel force between the resin layer and the transparent sheet with the elapse of time. Further, by virtue of the hydrosilylation-type silicone pressure-sensitive adhesive, even when the resin layer is exposed on the surface, fusing between the resin layer and the thermal transfer sheet can be prevented, and, in addition, at the time of the transfer of the image onto an object, the sheet substrate can be stably separated from the intermediate transfer recording medium.

Thus, the transparent sheet covers the surface of the image formed portion and hence can function as an even firm protective layer. Therefore, fastness properties can be fully imparted to the image.

The present invention will be described in more detail with reference to the following preferred embodiments.

FIG. 8 is a cross-sectional view showing one embodiment of the intermediate transfer recording medium according to the present invention. In an intermediate transfer recording medium 21 according to this embodiment, a sheet substrate 24 provided with a resin layer 25 is stacked onto a transparent sheet 22 provided with a receptive layer 23 so that the transparent sheet 22 faces the resin layer 25. The intermediate transfer recording medium 21 is separable in its portion between the resin layer 25 and the transparent sheet 22 to transfer the transparent sheet 22 provided with the receptive layer 23 onto an object. A thermal transfer sheet is separately provided and used to form a thermally transferred image on the receptive layer 23 in the intermediate transfer recording medium 21. The receptive layer with the image formed thereon is put on top of an object, and the assembly is pressed with heating to transfer the transparent sheet 22 provided with the receptive layer 23 onto the object.

In order to facilitate the registration between the object and the image transfer position at the time of the transfer of the image onto the object, a method may be used wherein, as shown in FIG. 8, a region 26 to be transferred onto an object is previously independently formed and the transparent sheet 22, provided with the receptive layer 23, in its portion located around the outer periphery of the region 26 is previously removed.

(Transparent Sheet)

In the transparent sheet 22 used in the intermediate transfer recording medium according to the present invention, the transparent sheet portion is cut using the half cut portion as the boundary between the removal portion and the portion remaining unremoved, and the transparent sheet can function as a protective layer in such a state that the transparent sheet covers the surface of the image formed portion.

The transparent sheet may be any one so far as the sheet is transparent and has fastness properties, such as weathering resistance, abrasion resistance, and chemical resistance. Examples of transparent sheets usable herein include about 0.5 to 100 μm-thick, preferably about 10 to 40 μm-thick, films of polyethylene terephthalate, 1,4-polycyclohexylene dimethylene terephthalate, polyethylene naphthalate, polyphenylene sulfide, polystyrene, polypropylene, polysulfone, aramid, polycarbonate, polyvinyl alcohol, cellulose derivatives, such as cellophane and cellulose acetate, polyethylene, polyvinyl chloride, nylon, polyimide, and ionomer.

(Release Treatment)

The transparent sheet in its side facing the resin layer may be subjected to release treatment to facilitate the separation of the transparent sheet from the resin layer.

In the release treatment, a release layer is provided on the transparent sheet. The release layer may be formed by coating a coating liquid containing, for example, a wax, silicone wax, a silicone resin, a fluororesin, an acrylic resin, a polyvinyl alcohol rein, or a cellulose derivative resin or a copolymer of monomers constituting the above group of resins onto the transparent sheet by conventional means such as gravure printing, screen printing, or reverse roll coating using a gravure plate, and drying the coating.

The coverage of the release layer is about 0.1 to 10 g/m² on a dry basis.

(Receptive Layer)

The receptive layer 23 may be formed on the transparent sheet either directly or through a primer layer. The construction of the receptive layer 23 varies depending upon the recording system, that is, whether the recording system is hot-melt transfer recording or sublimation transfer recording. In the hot-melt transfer recording, a method may also be adopted wherein a color transfer layer is thermally transferred from the thermal transfer sheet directly onto the transparent sheet without providing the receptive layer. In the hot-melt transfer recording and the sublimation transfer recording, the receptive layer functions to receive a colorant thermally transferred from the thermal transfer sheet. In particular, in the case of the sublimable dye, preferably, the receptive layer receives the dye, develops a color, and, at the same time, does not permit re-sublimation of the once received dye.

A transfer image is formed on a receptive layer in an intermediate transfer recording medium, and only the image formed portion is re-transferred onto an object to form an image on the object. The receptive layer according to the present invention is generally transparent so that an image transferred onto the object can be clearly viewed from the top. However, it is also possible to intentionally make the receptive layer opaque or to intentionally lightly color the receptive layer to render the re-transferred image distinct.

The receptive layer is generally composed mainly of a thermoplastic resin. Examples of materials usable for forming the receptive layer include: polyolefin resins such as polypropylene; halogenated polymers such as vinyl chloride-vinyl acetate copolymer, ethylene-vinyl acetate copolymer, and polyvinylidene chloride; polyester resins such as polyvinyl acetate and polyacrylic esters; polystyrene resins; polyamide resins; copolymer resins produced from olefins, such as ethylene and propylene, and other vinyl monomers; ionomers; cellulosic resins such as cellulose diacetate; and polycarbonate resins. Among them, polyester resins and vinyl chloride-vinyl acetate copolymer and mixtures of these resins are particularly preferred.

If necessary, particles may be incorporated into the receptive layer to intentionally render the receptive layer opaque, to improve the storage stability of the formed image, and to improve the slipperiness of the surface of the receptive layer. Particles usable herein include inorganic particles and organic particles. Examples of inorganic particles include those having an average particle diameter of about 1 to 20 μM, such as silica, talc, calcium carbonate, magnesium carbonate, titanium oxide, zinc oxide, barium sulfate, and boron nitride. In order to permit the receptive layer to be transparent, the average particle diameter of the particles added is preferably not more than 0.1 μm. Likewise, examples of organic particles usable herein include finely divided powder having an average particle diameter of about 2 to 20 μm of polyethylene wax, nylon, benzoguanamine resin, collagen, crosslinked resins such as crosslinked polystyrene, silicone-modified resin, and fluororesin.

The amount of these particles used is preferably in the range of 1 to 50 parts by mass based on 100 parts by mass of the resin used for the formation of the dye-receptive layer. When the amount of the particles used is excessively small, the slipperiness of the surface of the dye-receptive layer is unsatisfactory and, thus, desired scratch resistance cannot be provided. On the other hand, when the amount of the particles used is excessively large, dyeability with the dye is unsatisfactory. This makes it difficult to form a high-density image, and, at the same time, disadvantageously, the strength of the dye-receptive layer is also deteriorated.

In sublimation transfer recording, a release agent may be incorporated into the receptive layer, for example, from the viewpoint of preventing fusing between the thermal transfer sheet having a color transfer layer and the receptive layer in the intermediate transfer recording medium at the time of image formation or preventing a lowering in sensitivity in printing. Preferred release agents usable as a mixture include silicone oils, phosphoric ester surfactants, and fluorosurfactants. Among them, silicone oils are preferred. Preferred silicone oils include epoxy-modified, vinyl-modified, alkyl-modified, amino-modified, carboxyl-modified, alcohol-modified, fluorine-modified, alkyl aralkyl polyether-modified, epoxy-polyether-modified, polyether-modified and other modified silicone oils.

A single or plurality of release agents may be used. The amount of the release agent added is preferably 0.5 to 30 parts by mass based on 100 parts by mass of the resin for the receptive layer. When the amount of the release agent added is outside the above amount range, problems some times occur such as fusing between the sublimation-type thermal transfer sheet and the receptive layer in the intermediate transfer recording medium or a lowering in sensitivity in printing. The addition of the release agent to the receptive layer permits the release agent to bleed out on the surface of the receptive layer after the transfer to form a release layer. Alternatively, these release agents may be separately coated onto the receptive layer without being incorporated into the receptive layer.

The receptive layer may be formed by coating a solution of a mixture of the above resin with a necessary additive, such as a release agent, in a suitable organic solvent, or a dispersion of the mixture in an organic solvent or water onto a transparent sheet by conventional forming means such as gravure coating, gravure reverse coating, or roll coating, and drying the coating.

The receptive layer may be formed at any coverage. In general, however, the coverage of the receptive layer is about 1 to 50 g/m² on a dry basis.

The receptive layer is preferably in the form of a continuous coating. However, the receptive layer may be in the form of a discontinuous coating formed using a resin emulsion, a water-soluble resin, or a resin dispersion. Further, an antistatic agent may be coated onto the receptive layer from the viewpoint of realizing stable carrying of sheets through a thermal transfer printer.

(Sheet Substrate)

The sheet substrate 24 used in the present invention is not particularly limited, and examples thereof include: various types of paper, for example, capacitor paper, glassine paper, parchment paper, or paper having a high sizing degree, synthetic paper (such as polyolefin synthetic paper and polystyrene synthetic paper), cellulose fiber paper, such as wood free paper, art paper, coated paper, cast coated paper, wall paper, backing paper, synthetic resin- or emulsion-impregnated paper, synthetic rubber latex-impregnated paper, paper with synthetic resin internally added thereto, and paperboard; and films of polyester, polyacrylate, polycarbonate, polyurethane, polyimide, polyether imide, cellulose derivative, polyethylene, ethylene-vinyl acetate copolymer, polypropylene, polystyrene, acrylic resin, polyvinyl chloride, polyvinylidene chloride, polyvinyl alcohol, polyvinyl butyral, nylon, polyether ether ketone, polysulfone, polyether sulfone, tetrafluoroethylene-perfluoroalkyl vinyl ether, polyvinyl fluoride, tetrafluoroethylene-ethylene, tetrafluoroethylene-hexafluoropropylene, polychlorotri-fluoroethylene, polyvinylidene fluoride and the like.

The thickness of the sheet substrate is preferably 10 to 100 μm. When the sheet substrate is excessively thin, the resultant intermediate transfer recording medium is not sturdy and thus cannot be carried by means of a thermal transfer printer or is disadvantageously curled or cockled. On the other hand, when the sheet substrate is excessively thick, the resultant intermediate transfer recording medium is excessively thick. In this case, the driving force of the thermal transfer printer necessary for carrying the intermediate transfer recording medium is excessively large, resulting in a printer trouble or a failure of the intermediate transfer recording medium to be normally carried.

(Resin Layer)

The resin layer 25 provided on the sheet substrate is composed mainly of a hydrosilylation-type silicone pressure-sensitive adhesive. The resin layer 25 may be formed by adding a filler to the adhesive, for example, for improving the strength of the resin layer and preventing blocking, and, if necessary, adding various additives, such as antioxidants, to the adhesive, dissolving the mixture in a suitable organic solvent, or dispersing the mixture in an organic solvent or water, coating the solution or the dispersion onto the sheet substrate by conventional forming means such as gravure coating, gravure reverse coating, or roll coating, and drying the coating.

The coverage of the resin layer is about 0.5 to 10 g/m² on a solid basis, and the tackiness, i.e., the peel force, is preferably approximately in the range of 0.01 to 0.5 N/inch, in terms of peel strength between the transparent sheet and the resin layer, as measured by a 180-degree peel method according to JIS Z 0237. The peel force can be regulated in the above range by varying or regualting the type of the hydrosilylation-type silicone pressure-sensitive adhesive, the content of the adhesive in the resin layer, the coverage of the resin layer and the like.

When the peel force is less than 0.01 N/inch, the transparent sheet is likely to be separated, for example, during carriage through a thermal transfer printer for image formation or during handling. On the other hand, a peel force exceeding 0.5 N/inch makes it difficult for the transparent sheet to be separated from the resin layer at the time of the transfer of an image onto the object after the formation of a thermally transferred image on the receptive layer.

When the resin layer is provided on the sheet substrate and the transparent sheet is stacked onto the resin layer, use may be made of, for example, dry lamination and hot-melt lamination of the resin layer.

In the hydrosilylation-type silicone pressure-sensitive adhesive contained in the resin layer, a silicon hydride is addition reacted with the vinyl-containing crosslinkable silicone elastomer. In this case, when a metal, such as platinum (Pt), rhodium (Rh), or ruthenium (Ru), or a compound thereof is added as a catalyst, the curing reaction takes place and is completed at room temperature, i.e., about 10 to 30° C., in a shorter time. The amount of this catalyst added is about 0.1 to 2% (mass ratio) based on the hydrosilylation-type silicone pressure-sensitive adhesive.

The addition of a filler to the resin layer is preferred. This can offer improved effects, that is, can improve the strength of the resin layer, can prevent the cohesive failure of the resin layer at the time of the separation of the transparent sheet from the intermediate transfer recording medium, and can prevent a change in peel force between the resin layer and the transparent sheet with the elapse of time.

Fillers usable herein include inorganic fillers, such as silica, colloidal silica, alumina, kaolin, clay, calcium carbonate, talc, and titanium dioxide. The average particle diameter of the filler added is generally about 0.01 to 5 μm, preferably about 0.01 to 1 μm. When the average particle diameter is excessively small, the contemplated effect cannot be satisfactorily attained. On the other hand, when the average particle diameter is excessively large, for example, the peel force between the resin layer and the transparent sheet is disadvantageously lowered. The amount of the filler added is about 10 to 150% (mass ratio) based on the hydrosilylation-type silicone pressure-sensitive adhesive.

(Primer Layer)

In providing the resin layer on the sheet substrate, a primer layer may be provided on the surface of the sheet substrate to improve the adhesion between the sheet substrate and the resin layer. Instead of the provision of the primer layer, the surface of the sheet substrate may be subjected to corona discharge treatment.

The primer layer may be formed by providing a coating liquid in the form of a solution or dispersion of a polyester resin, a polyacrylic ester resin, a polyvinyl acetate resin, a polyurethane resin, a polyamide resin, a polyethylene resin, a polypropylene resin or the like in a solvent and coating the coating liquid by the same means as used in the formation of the receptive layer.

The coverage of the primer layer is about 0.1 to 5 g/m² on a dry basis.

The primer layer may also be formed between the transparent sheet and the receptive layer in the same manner as described above.

A suitable slip layer may be provided on the sheet substrate in its side remote from the resin layer, for example, from the viewpoint of improving carriabiltiy at the time of sheet feeding in the thermal transfer printer. The slip layer may be formed of a single resin or a blend of two or more resin selected from conventional resins, such as butyral resins, polyacrylic esters, polymethacrylic esters, polyvinylidene chloride, polyesters, polyurethane, polycarbonate, and polyvinyl acetate, a lubricant, such as various fine particles or silicone, having been added to the single resin or the resin blend.

The intermediate transfer recording medium according to the present invention has a construction such that at least a receptive layer, a transparent sheet, a resin layer, and a sheet substrate are stacked in that order on top of one another and the resin layer is separably applied to the transparent sheet. An antistatic layer may be provided on the surface of the receptive layer, the backside of the sheet substrate, or the outermost surface of both sides. The antistatic layer may be formed by coating a solution or dispersion of an antistatic agent, such as a fatty ester, a sulfuric ester, a phosphoric ester, an amide, a quaternary ammonium salt, a betaine, an amino acid, an acrylic resin, or an ethylene oxide adduct, in a solvent. The forming means used may be the same as that used in the formation of the receptive layer. The coverage of the antistatic layer is preferably 0.001 to 0.1 g/m² on a dry basis.

An intermediate layer formed of one of various resins may be provided between the substrate and the receptive layer in the transparent sheet. In this case, the intermediate layer is preferably transparent so that the re-transferred image can be viewed.

When the intermediate layer has various functions, excellent functions can be imparted to the image-receiving sheet For example, a highly elastically deformable or plastically deformable resin, for example, a polyolefin resin, a vinyl copolymer resin, a polyurethane resin, or a polyamide resin, may be used as a cushioning property-imparting resin to improve the sensitivity in printing of the image-receiving sheet or to prevent harshness of images. Antistatic properties may be imparted to the intermediate layer by adding the antistatic agent to the cushioning property-imparting resin, dissolving or dispersing the mixture in a solvent, and coating the solution or dispersion to form an intermediate layer.

In the intermediate transfer recording medium according to the present invention, in order to facilitate the registration between the object and the image transfer position at the time of the transfer of an image onto the object, as shown in FIG. 8, a method is preferably adopted wherein the region 26 to be transferred onto the object is previously independently formed and the transparent sheet 22, provided with the receptive layer 23, in its portion located around the outer periphery of the region 26 is previously removed. In this case, an example of a method for removing the transparent sheet 22, provided with the receptive layer 23, in its portion located around the outer periphery of the region 26 is such that the peripheral portion of the region 26 is subjected to half cutting for cutting the transparent sheet 2 portion including the receptive layer 23, and the transparent sheet provided with the receptive layer in its portion around the region 26 is torn off while leaving the region 26 to be transferred onto the object.

The half cut may be formed by any method without particular limitation so far as half cutting is possible. Examples of methods usable for half cutting include a method wherein the intermediate transfer recording medium is inserted into between an upper die provided with a cutter blade and a pedestal and the upper die is then vertically moved, a method wherein a cylinder-type rotary cutter is used, and a method wherein heat treatment is carried out by means of a laser beam.

The transparent sheet provided with the receptive layer in its portion around the region 26 may be torn off by winding the refuse, for example, by means of a refuse removing roll or may be torn off by the hand.

The method for image formation may comprise the steps of: providing the above intermediate transfer recording medium; putting the intermediate transfer recording medium and a thermal transfer sheet on top of each other so that a transfer layer in the thermal transfer sheet comes into contact with the receptive layer; heating the assembly to form a transfer image on the receptive layer; further transferring an adhesive layer onto the receptive layer; putting the intermediate transfer recording medium and an object on top of each other so that the adhesive layer face comes into contact with the object; and pressing the assembly with heating to re-transfer only a region with the image and the adhesive layer formed thereon onto the object to form an image on the object.

The adhesive layer may be transferred onto the receptive layer, for example, by providing an adhesive sheet, which has been formed into a film, inserting the adhesive sheet into between the receptive layer face with the image formed thereon and the object and heat pressing the assembly to adhere the image-receptive layer and the transparent sheet onto the object.

A method may also be adopted which comprises the steps of: providing an adhesive layer transfer sheet comprising an adhesive layer provided separably on a substrate; and heat pressing the adhesive layer in the adhesive layer transfer sheet against the surface of the receptive layer with the image formed thereon to transfer the adhesive layer.

Adhesive components usable in the adhesive sheet or the adhesive layer transfer sheet include thermoplastic synthetic resins, naturally occurring resins, rubbers, and waxes, and examples thereof include: synthetic resins, for example, cellulose derivatives such as ethylcellulose and cellulose acetate propionate, styrene polymers such as polystyrene and poly-α-methylstyrene, acrylic resins such as polymethyl methacrylate, polyethyl methacrylate, and polyethyl acrylate, vinyl resins such as polyvinyl chloride, polyvinyl acetate, vinyl chloride-vinyl acetate copolymer, and polyvinyl butyral, polyester resins, polyamide resins, epoxy resins, polyurethane resins, ionomers, olefins, and ethylene-acrylic acid copolymers; and tackifiers, for example, naturally occurring resins and synthetic rubber derivatives, such as rosins, rosin-modified maleic acid resins, ester gums, polyisobutylene rubbers, butyl rubbers, styrene-butadiene rubbers, and butadiene-acrylonitrile rubbers. A single or plurality of adhesive components may be used, and the use of a material, which can develop adhesive properties upon heating, is preferred.

The coverage of the adhesive sheet or the adhesive layer in the adhesive layer transfer sheet is about 0.1 to 500 g/m².

In the transfer of the adhesive layer, for example, a thermal head used in the formation of a transferred image, a line heater, a heat roll, or a hot stamp may be used as heating means.

An image may be formed on the intermediate transfer recording medium by a conventional sublimation thermal transfer method or hot-melt thermal transfer method. For example, a thermal transfer sheet comprising color transfer layers of three colors of yellow, cyan, and magenta provided in a face serial manner is used to form a desired full-color image on the receptive layer in the intermediate transfer recording medium by a conventional thermal transfer printer of thermal head type or laser heating type. Next, the transparent sheet including the receptive layer with the image formed thereon may be separated from the sheet substrate provided with the resin layer and transferred and applied to a desired object.

For example, a thermal head used in the formation of a transferred image, a line heater, a heat roll, or a hot stamp may be used as means for transferring the transparent sheet including the receptive layer with the image formed thereon onto an object.

It should be noted that, in order that the image finally formed on the object according to the present invention is properly oriented, an image, which is in a mirror image relationship with the final image, should be formed on the receptive layer in the intermediate transfer recording medium.

The object, on which the image is re-transferred from the intermediate transfer recording medium according to the present invention, is not particularly limited. For example, any sheet of plain paper, wood free paper, tracing paper, and plastic film may be used. Regarding the shape of the object, for example, any of cards, postal cards, passports, letter paper, report pads, notebooks, catalogs, cups, and cases may be used.

Specific applications of the thermal transfer image-receiving sheet used in the thermal transfer method are various, and representative examples thereof include proofs of printing, output of images, output of plans and designs, for example, in CAD/CAM, output of various medical analytical instruments and measuring instruments, such as CT scans and endoscope cameras, alternative to instant photographs, output and printing of photograph-like images of a face or the like onto identification cards or ID cards, credit cards, and other cards, and composite photographs and commemorative photographs, for example, in amusement facilities, such as amusement parks, game centers, museums, and aquaria. The diversification of the applications had lead to an increasing demand for the formation of a thermally transferred image on a desired object. One method proposed for meeting this demand comprises the steps: providing an intermediate transfer recording medium comprising a substrate and a receptive layer separably provided on the substrate; providing a thermal transfer sheet having a dye layer; transferring the dye from the thermal transfer sheet to the receptive layer in the intermediate transfer recording medium to form an image on the receptive layer; and then heating the intermediate transfer recording medium to transfer the receptive layer onto an object (see Japanese Patent Laid-Open No. 238791/1987).

Third Invention

Conventional sublimation transfer-type thermal transfer sheets can faithfully form gradational images, such as photograph-like images of a face. Unlike conventional images produced by printing inks, however, these images disadvantageously lack in fastness properties, such as weathering resistance, abrasion resistance, and chemical resistance. To solve this problem, a method has been proposed wherein a protective layer thermal transfer film having a thermally transferable resin layer is put on top of a thermally transferred image and the transparent thermally transferable resin layer is transferred, for example, by means of a thermal head or heating roll to form a protective layer on the image.

The above protective layer should be partially transferred at the time of transfer by means of a thermal head or a heat roll and thus should have good transferability. To this end, the protective layer should be a resin layer having a thickness of about several μm. This makes it impossible to impart fastness properties, such as high scratch resistance and chemical resistance, to images. Also regarding the protective layer formed in the intermediate transfer recording medium, satisfactory fastness properties, such as satisfactory scratch resistance and chemical resistance, cannot be imparted when the transferability is taken into consideration. A method can also be considered wherein the intermediate transfer recording medium is used to form an image on an object and a resin film is laminated so as to cover the image formed on the object to form a protective layer. This, however, is considered to be disadvantageous in that, for some shape in the object, the resin film is cockled at the time of the lamination, and, in addition, for example, a specialty device, such as a laminator, should be used, resulting in the increased number of steps.

The formation of an image on an object using the conventional intermediate transfer recording medium is unsatisfactory in the prevention of alteration and forgery.

Accordingly, in order to solve the above problems of the prior art, it is an object of the present invention to provide an intermediate transfer recording medium, which can form thermally transferred images possessing excellent various fastness properties even under severe service conditions, can realize the transfer of a protective layer on the image with high accuracy in a simple manner, and can fully prevent the alteration or forgery of the object with the image formed thereon, a process for producing the same, and a method for image formation.

In order to attain the above object, according to the third invention, there is provided an intermediate transfer recording medium comprising: a sheet substrate provided with a resin layer; a transparent sheet provided with a receptive layer, the transparent sheet provided with the receptive layer having been put on top of the sheet substrate provided with the resin layer so that the resin layer faces the transparent sheet on its side remote from the receptive layer, the transparent sheet portion including the receptive layer having been half cut, the resin layer being separable from the transparent sheet; and a hologram formation layer provided between the transparent sheet and the receptive layer.

In this construction, preferably, the whole portion except for the image forming portion has been separated and removed using the half cut as a boundary between the image forming portion remaining unremoved and the removal portion. This permits the patch portion of the image forming portion in the intermediate transfer recording medium to be simply transferred in a sharp and accurate edge shape.

The patch portion as the image forming portion, which has been separated by the half cut, preferably has a size smaller than an object in its whole area on which an image is to be transferred. In this case, there is no fear of the patch portion being projected from the end of the object.

Preferably, the patch portion as the image forming portion, which has been separated by the half cut, has a partially removed portion relative to an object. In this case, for example, a portion where the formation of no image as the patch portion is desired, such as a hologram portion or a logo portion in an object, for example, a sign panel, an IC chip, a magnetic stripe, or a credit card, can be registered with the partially removed portion, followed by the re-transfer of the patch onto an object.

Preferably, the total width of the intermediate transfer recording medium is larger than the width of an object in its face on which an image is to be transferred. According to this construction, in the formation of an image on the receptive layer in the intermediate transfer recording medium followed by the re-transfer of the image formed portion onto an object, a heating device, such as a thermal head, a press roll, or a press plate, does not come into direct contact with the object, and, thus, damage to the object can be avoided.

Further, according to the present invention, there is provided a process for producing an intermediate transfer recording medium comprising a sheet substrate provided with a resin layer and a transparent sheet provided with a receptive layer, the transparent sheet provided with the receptive layer having been put on top of the sheet substrate provided with the resin layer so that the resin layer faces the transparent sheet on its side remote from the receptive layer, the transparent sheet portion including the receptive layer having been half cut, a hologram formation layer being stacked on the transparent sheet, the resin layer being separable from the transparent sheet, said process comprising the steps of: providing an original sheet comprising a hologram formation layer stacked on a transparent sheet; forming a receptive layer by coating on the original sheet; applying the transparent sheet on its side remote from the receptive layer onto a sheet substrate, in which register marks have been previously provided at respective positions for one screen unit, through a resin layer; and then reading the register marks to perform registration for half cutting and then to perform half cutting.

Preferably, after the half cutting, the whole portion except for the image forming portion is separated and removed using the half cut as the boundary between the removal portion and the image forming portion remaining unremoved. According to this construction, the patch portion of the image forming portion in the intermediate transfer recording medium can be simply transferred in a sharp and accurate edge shape.

Furthermore, according to the present invention, there is provided a method for image formation, comprising the steps of: providing any one of the above intermediate transfer recording media; forming a transfer image on the receptive layer; and re-transferring only the image formed portion onto an object to form an image on the object.

According to the present invention, the process for producing an intermediate transfer recording medium comprising a sheet substrate provided with a resin layer and a transparent sheet provided with a receptive layer, the transparent sheet provided with the receptive layer having been put on top of the sheet substrate provided with the resin layer so that the resin layer faces the transparent sheet on its side remote from the receptive layer, the transparent sheet portion including the receptive layer having been half cut, a hologram formation layer being stacked on the transparent sheet, the resin layer being separable from the transparent sheet, comprises the steps of: providing an original sheet comprising a hologram formation layer stacked on a transparent sheet; forming a receptive layer by coating on the original sheet; applying the transparent sheet on its side remote from the receptive layer onto a sheet substrate, in which register marks have been previously provided at respective positions for one screen unit, through a resin layer; and then reading the register marks to perform registration for half cutting and then to perform half cutting.

The intermediate transfer recording medium thus obtained can be used to form thermally transferred images possessing excellent various fastness properties even under severe service conditions, can realize the transfer of a protective layer (transparent sheet) onto the image with high accuracy in a simple manner by virtue of half cutting, and can fully prevent the alteration or forgery of the object with the image formed thereon by thermal transfer by virtue of the provision of the hologram image on the transparent sheet.

The present invention will be described in more detail with reference to the following preferred embodiments,

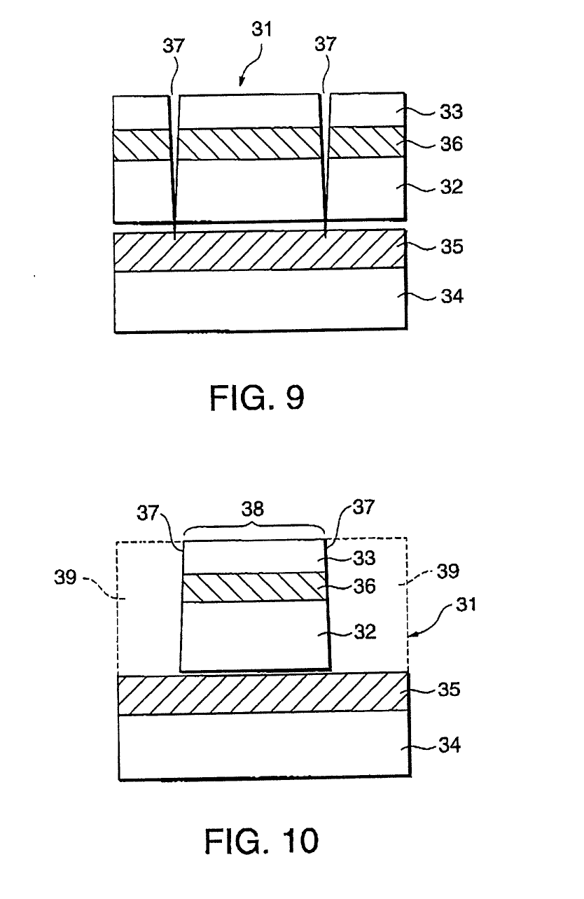

FIG. 9 is a schematic cross-sectional view showing one embodiment of an intermediate transfer recording medium 31 according to the present invention. The intermediate transfer recording medium 31 comprises: a sheet substrate 34 having thereon a resin layer 35 and a transparent sheet 32 having thereon a hologram formation layer 36 and a receptive layer 33 in that order, the transparent sheet 32 provided with the hologram formation layer 36 and the receptive layer 33 having been put on top of the sheet substrate 34 provided with the resin layer 35 so that the resin layer 35 faces the transparent sheet 32 in its side remote from the hologram formation layer 36 and receptive layer 33, the resin layer 35 being separable from the transparent sheet 32, the transparent sheet portion 32 including the receptive layer 33 and the hologram formation layer 36 having been subjected to half cutting 37.

FIG. 10 is a schematic cross-sectional view showing another embodiment of the intermediate transfer recording medium 31 according to the present invention. This intermediate transfer recording medium 31 comprises: a sheet substrate 34 having thereon a resin layer 35 and a transparent sheet 32 having thereon a hologram formation layer 36 and a receptive layer 33 in that order, the transparent sheet 32 provided with the hologram formation layer 36 and the receptive layer 33 having been put on top of the sheet substrate 34 provided with the resin layer 35 so that the resin layer 35 faces the transparent sheet 32 in its side remote from the hologram formation layer 36 and receptive layer 33, the resin layer 35 being separable from the transparent sheet 32, the transparent sheet portion 32 including the receptive layer 33 and the hologram formation layer 36 having been subjected to half cutting 37, the whole portion 39 except for the image forming portion 38 having been separated and removed using the half cut portion 37 as the boundary between the image forming portion 38 remaining unmoved and the removal region. In this embodiment, before the step of forming an image by thermal transfer and re-transferring the transfer portion onto an object, the step of separating and removing the portion 39 except for the image forming portion 38 using the half cut portion 37 as the boundary between the portion remaining unremoved and the removal portion is provided. In this case, when the transfer portion is re-transferred onto the object, only the image forming portion may be transferred. This can further simplify re-transfer onto the object.

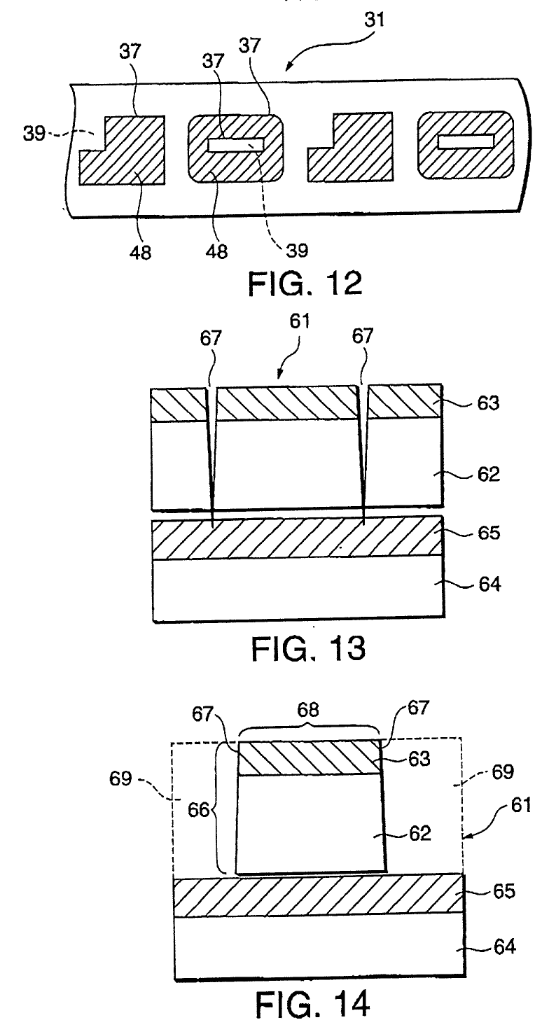

FIG. 12 is a schematic plan view showing a further embodiment of the intermediate transfer recording medium 31 according to the present invention. The intermediate transfer recording medium 31 comprises: a transparent sheet having thereon a hologram forming layer and a receptive layer in that order; and a sheet substrate, the transparent sheet having been separably put on top of the substrate sheet through a resin layer. The transparent sheet portion including the hologram formation layer and the receptive layer has been subjected to half cutting 37. A patch portion 48 as the image forming portion is left using the half cut portion 37 as the boundary between the removal portion and the image forming portion remaining unremoved, and, as shown in the drawing, the outside of the patch portion 48 and the inside removal portion surrounded by the patch portion 48 are separated and removed. Upon the re-transfer of this patch portion 48 onto an object, the patch portion 48 has a partially removed portion 39 relative to the object. In this case, for example, a portion where the formation of no image as the patch portion is desired, such as a hologram portion or a logo portion in an object, for example, a sign panel, an IC chip, a magnetic stripe, or a credit card, is registered with the partially removed portion 39. By virtue of this, no image is present in a position where the formation of no image is contemplated. Thus, the occurrence of troubles can be prevented.

(Transparent Sheet)

In the transparent sheet 32 used in the intermediate transfer recording medium according to the present invention, the transparent sheet portion is cut using the half cut portion as the boundary between the removal portion and the portion remaining unremoved, and the transparent sheet can function as a protective layer in such a state that the transparent sheet covers the surface of the image formed portion. The transparent sheet may be any one so far as the sheet is transparent and has fastness properties, such as weathering resistance, abrasion resistance, and chemical resistance. Examples of transparent sheets usable herein include about 0.5 to 100 μm-thick, preferably about 10 to 40 μm-thick, films of polyethylene terephthalate, 1,4-polycyclohexylene dimethylene terephthalate, polyethylene naphthalate, polyphenylene sulfide, polystyrene, polypropylene, polysulfone, aramid, polycarbonate, polyvinyl alcohol, cellulose derivatives, such as cellophane and cellulose acetate, polyethylene, polyvinyl chloride, nylon, polyimide, and ionomer.

The transparent sheet in its side facing the resin layer may be subjected to release treatment to facilitate the separation of the transparent sheet from the resin layer. In the release treatment, a release layer is provided on the transparent sheet. The release layer may be formed by coating a coating liquid containing, for example, a wax, silicone wax, a silicone resin, a fluororesin, an acrylic resin, a polyvinyl alcohol rein, or a cellulose derivative resin or a copolymer of monomers constituting the above group of resins onto the transparent sheet by conventional means, such as gravure printing, screen printing, or reverse roll coating using a gravure plate, and drying the coating. The coverage of the release layer is about 0.1 to 10 g/m² on a dry basis.

(Receptive Layer)

The receptive layer 33 may be formed on the transparent sheet either directly or through a primer layer. The construction of the receptive layer 33 varies depending upon the recording system, that is, whether the recording system is hot-melt transfer recording or sublimation transfer recording. In the hot-melt transfer recording, a method may also be adopted wherein a color transfer layer is thermally transferred from the thermal transfer sheet directly onto the transparent sheet without providing the receptive layer. In the hot-melt transfer recording and the sublimation transfer recording, the receptive layer functions to receive a colorant thermally transferred from the thermal transfer sheet. In particular, in the case of the sublimable dye, preferably, the receptive layer receives the dye, develops a color, and, at the same time, does not permit re-sublimation of the once received dye. A transfer image is formed on a receptive layer in an intermediate transfer recording medium, and only the image formed portion is re-transferred onto an object to form an image on the object. The receptive layer according to the present invention is generally transparent so that an image transferred onto the object can be clearly viewed from the top. However, it is also possible to intentionally make the receptive layer opaque or to intentionally lightly color the receptive layer to render the re-transferred image distinct.

The receptive layer is generally composed mainly of a thermoplastic resin. Examples of materials usable for forming the receptive layer include: polyolefin resins such as polypropylene; halogenated polymers such as vinyl chloride-vinyl acetate copolymer, ethylene-vinyl acetate copolymer, and polyvinylidene chloride; polyester resins such as polyvinyl acetate and polyacrylic esters; polystyrene resins; polyamide resins; copolymer resins produced from olefins, such as ethylene and propylene, and other vinyl monomers; ionomers; cellulosic resins such as cellulose diacetate; and polycarbonate resins Among them, polyester resins and vinyl chloride-vinyl acetate copolymer and mixtures of these resins are particularly preferred.

In sublimation transfer recording, a release agent may be incorporated into the receptive layer, for example, from the viewpoint of preventing fusing between the thermal transfer sheet having a color transfer layer and the receptive layer in the intermediate transfer recording medium at the time of image formation or preventing a lowering in sensitivity in printing. Preferred release agents usable as a mixture include silicone oils, phosphoric ester surfactants, and fluorosurfactants. Among them, silicone oils are preferred. Preferred silicone oils include epoxy-modified, vinyl-modified, alkyl-modified, amino-modified, carboxyl-modified, alcohol-modified, fluorine-modified, alkyl aralkyl polyether-modified, epoxy-polyether-modified, polyether-modified and other modified silicone oils.

A single or plurality of release agents may be used. The amount of the release agent added is preferably 0.5 to 30 parts by weight based on 100 parts by weight of the resin for the receptive layer. When the amount of the release agent added is outside the above amount range, problems sometimes occur such as fusing between the sublimation-type thermal transfer sheet and the receptive layer in the intermediate transfer recording medium or a lowering in sensitivity in printing. The addition of the release agent to the receptive layer permits the release agent to bleed out on the surface of the receptive layer after the transfer to form a release layer. Alternatively, these release agents may be separately coated onto the receptive layer without being incorporated into the receptive layer. The receptive layer may be formed by coating a solution of a mixture of the above resin with a necessary additive, such as a release agent, in a suitable organic solvent, or a dispersion of the mixture in an organic solvent or water onto a transparent sheet by conventional forming means such as gravure coating, gravure reverse coating, or roll coating, and drying the coating. The receptive layer may be formed at any coverage. In general, however, the coverage of the receptive layer is 1 to 50 g/m² on a dry basis. The receptive layer is preferably in the form of a continuous coating. However, the receptive layer may be in the form of a discontinuous coating formed using a resin emulsion, a water-soluble resin, or a resin dispersion. Further, an antistatic agent may be coated onto the receptive layer from the viewpoint of realizing stable carrying of sheets through a thermal transfer printer.

(Sheet Substrate)

The sheet substrate 34 used in the present invention is not particularly limited, and examples thereof include: various types of paper, for example, capacitor paper, glassine paper, parchment paper, or paper having a high sizing degree, synthetic paper (such as polyolefin synthetic paper and polystyrene synthetic paper), cellulose fiber paper, such as wood free paper, art paper, coated paper, cast coated paper, wall paper, backing paper, synthetic resin- or emulsion-impregnated paper, synthetic rubber latex-impregnated paper, paper with synthetic resin internally added thereto, and paperboard; and films of polyester, polyacrylate, polycarbonate, polyurethane, polyimide, polyether imide, cellulose derivative, polyethylene, ethylene-vinyl acetate copolymer, polypropylene, polystyrene, acrylic resin, polyvinyl chloride, polyvinylidene chloride, polyvinyl alcohol, polyvinyl butyral, nylon, polyether ether ketone, polysulfone, polyether sulfone, tetrafluoroethylene-perfluoroalkyl vinyl ether, polyvinyl fluoride, tetrafluoroethylene-ethylene, tetrafluoroethylene-hexafluoropropylene, polychlorotri-fluoroethylene, polyvinylidene fluoride and the like.

The thickness of the sheet substrate is preferably 10 to 100 μm. When the sheet substrate is excessively thin, the resultant intermediate transfer recording medium is not sturdy and thus cannot be carried by means of a thermal transfer printer or is disadvantageously curled or cockled. On the other hand, when the sheet substrate is excessively thick, the resultant intermediate transfer recording medium is excessively thick. In this case, the driving force of the thermal transfer printer necessary for carrying the intermediate transfer recording medium is excessively large, resulting in a printer trouble or a failure of the intermediate transfer recording medium to be normally carried.

(Resin Layer)

The resin layer 35 may be provided as a pressure-sensitive adhesive layer, an easy-adhesion adhesive layer, or an extrusion coating (EC) on the sheet substrate. The pressure-sensitive adhesive layer may be formed of a conventional solvent-type or aqueous pressure-sensitive adhesive. Pressure-sensitive adhesives include, for example, vinyl acetate resins, acrylic resins, vinyl acetate-acryl copolymers, vinyl acetate-vinyl chloride copolymers, ethylene-vinyl acetate copolymers, polyurethane resins, natural rubbers, chloroprene rubbers, and nitrile rubbers. The coverage of the pressure-sensitive adhesive layer is generally about 8 to 30 g/m² on a solid basis, and the pressure-sensitive adhesive layer may be formed by coating the pressure-sensitive adhesive by a conventional method, for example, gravure coating, gravure reverse coating, roll coating, Komma coating, or die coating, on a release sheet and drying the coating. The adhesive strength of the pressure-sensitive adhesive layer is preferably approximately in the range of 5 to 1,000 g, in terms of peel strength between the transparent sheet and the pressure-sensitive adhesive layer, as measured by a 180-degree peel method according to JIS Z 0237. In the formation of the pressure-sensitive adhesive layer on the sheet substrate, the above-described type of adhesive and coverage are preferably selected so that the peel strength is in the above-defined range. When the pressure-sensitive adhesive layer is provided on the sheet substrate and the transparent sheet is stacked onto the pressure-sensitive adhesive layer, a method may be adopted such as dry lamination or hot-melt lamination of the pressure-sensitive adhesive layer.

In the formation of the easy-adhesion adhesive layer, preferably, a latex of styrene-butadiene copolymer rubber (SBR), an acrylic resin, such as acrylonitrile-butadiene copolymer rubber (NBR) or a polyacrylic ester, a rubbery resin, a wax, or a mixture of two or more of the above materials is coated onto a sheet substrate by a conventional coating method, and the easy-adhesion adhesive layer is then stacked onto the transparent sheet by dry lamination with heating. The easy-adhesion adhesive layer after the separation of the transparent sheet from the sheet substrate has lowered tackiness and no longer can be used in the application of the transparent sheet to the sheet substrate. When this easy-adhesion adhesive layer is used, a primer layer may be provided between the sheet substrate and the easy-adhesion adhesive layer.

Further, an EC layer may be provided as the resin layer according to the present invention on the sheet substrate. The thermoplastic resin used for forming the EC layer is not particularly limited so far as the resin is not virtually adhered to the transparent sheet and is extrudable. In particular, however, a polyolefin resin is preferred which is not virtually adhered to PET films generally utilized in the transparent sheet and has excellent processability. More specifically, for example, LDPE, MDPE, HDPE, and PP resins are usable. In extrusion coating these resins, when a matte roll is used as a cooling roll, the matte face may be transferred onto the surface of the EC layer, whereby fine concaves and convexes can be formed to render the EC layer opaque. Alternatively, a method may be used wherein a white pigment, such as calcium carbonate or titanium oxide, is mixed into the polyolefin resin to form an opaque EC layer. The EC layer may be either a single-layer structure or a multi-layer structure of two or more layers. The peel strength of the EC layer from the transparent sheet may be regulated according to the processing temperature in the extrusion and the type of the resin. Thus, simultaneously with the extrusion of the EC layer on the sheet substrate, the sheet substrate can be stacked onto the transparent sheet through the EC layer by the so-called “EC lamination.”

In providing the resin layer on the sheet substrate, a primer layer may be provided on the surface of the sheet substrate to improve the adhesion between the sheet substrate and the resin layer. Instead of the provision of the primer layer, the surface of the sheet substrate may be subjected to corona discharge treatment. The primer layer may be formed by providing a coating liquid in the form of a solution or dispersion of a polyester resin, a polyacrylic ester resin, a polyvinyl acetate resin, a polyurethane resin, a polyamide resin, a polyethylene resin, a polypropylene resin or the like in a solvent and coating the coating liquid by the same means as used in the formation of the receptive layer. The thickness of the primer layer is about 0.1 to 5 g/m² on a dry basis. The primer layer may also be formed between the transparent sheet and the receptive layer in the same manner as described above.

In the intermediate transfer recording medium according to the present invention, if necessary, a heat-resistant slip layer may be provided on the backside of the sheet substrate, that is, on the sheet substrate in its side remote from the resin layer, from the viewpoints of preventing adverse effect, such as sticking, caused by heat of a thermal head, a heat roll or the like as means for re-transferring the image formed portion onto an object, or cockling.

Any conventional resin may be used as the resin for constituting the heat-resistant slip layer, and examples thereof include polyvinyl butyral resins, polyvinyl acetoacetal resins, polyester resins, vinyl chloride-vinyl acetate copolymers, polyether resins, polybutadiene resins, styrene-butadiene copolymers, acrylic polyols, polyurethane acrylates, polyester acrylates, polyether acrylates, epoxy acrylates, prepolymers of urethane or epoxy, nitrocellulose resins, cellulose nitrate resins, cellulose acetopropionate resins, cellulose acetate butyrate resins, cellulose acetate hydrogen phthalate resins, cellulose acetate resins, aromatic polyamide resins, polyimide resins, polycarbonate resins, chlorinated polyolefin resins, and chlorinated polyolefin resins.

Slipperiness-imparting agents added to or topcoated on the heat-resistant slip layer formed of the above resin include phosphoric esters, silicone oils, graphite powder, silicone graft polymers, fluoro graft polymers, acrylsilicone graft polymers, acrylsiloxanes, arylsiloxanes, and other silicone polymers. Preferred is a layer formed of a polyol, for example, a high-molecular weight polyalochol compound, a polyisocyanate compound and a phosphoric ester compound. Further, the addition of a filler is more preferred.

The heat-resistant slip layer may be formed by dissolving or dispersing the resin, the slipperiness-imparting agent, and a filler in a suitable solvent to prepare an ink for the formation of a heat-resistant slip layer, coating the ink onto the backside of the substrate sheet by forming means, such as gravure printing, screen printing, or reverse coating using a gravure plate, and drying the coating.

(Hologram Formation Layer)

The hologram formation layer 6 provided on the transparent sheet in the intermediate transfer recording medium according to the present invention is generally formed as a resin layer. This layer per se may have a single-layer structure or a multi-layer structure. Various hologram images (pattern) are formed in the resin layer.

The size and the form of the hologram image (pattern) are not particularly limited and vary according to the form of required prints. The hologram image may be formed by a conventional methods for example, by providing an original plate having a concave-convex pattern of interference fringes of the hologram and forming fine concaves and convexes, for example, by embossing.

According to the present invention, by virtue of the provision of this hologram formation layer, in the resultant object with an image thermally transferred thereon from the intermediate transfer recording medium, alternation and forgery can be fully prevented.

The hologram image provided in the hologram formation layer may be either a plane hologram or a volume hologram. In the plane hologram, among others, a relief hologram is preferred from the viewpoints of mass productivity and cost. Other holograms usable herein include Fresnel holograms, Fraunhofer holograms, lensless Fourier transformation holograms, image holgorams and other holograms reproducible by laser, rainbow holograms and other holograms reproducible by white light, and holograms utilizing the above principles, for example, color holograms, computer holograms, hologram displays, multiplex holograms, holographic stereograms, and holographic diffraction gratings.

Photosensitive materials in the hologram formation layer for recording interference fringes include silver salts, gelatin bichromate, thermoplastics, diazo photosensitive material photoresists, ferroelectrics, photochromic materials, and chalcogen glasses. Materials for the hologram layer include: thermoplastic resins, such as polyvinyl chloride, acrylic resins (for example, polymethyl methacrylate), polystyrene, and polycarbonate; cured products of thermosetting resins, such as unsaturated polyesters, melamine, epoxy, polyester (meth)acrylate, urethane (meth)acrylate, epoxy (meth)acrylate, polyether (meth)acrylate, polyol (meth)acrylate, melamine (meth)acrylate, and triazine acrylate; cured products of ultraviolet-curable resins, for example, a composition comprising a suitable mixture of an unsaturated ethylene monomer with an unsaturated ethylene oligomer and, added thereto, a sensitizer; and mixtures of thermoplastic resins with thermosetting resins; and thermoformable materials containing a radically polymerizable unsaturated group. In particular, thermosetting resins and ultraviolet-curable resins having excellent fastness properties, such as chemical resistance, lightfastness and weathering resistance, are preferred as the resin for forming the hologram formation layer.

The intermediate transfer recording medium according to the present invention comprises at least a receptive layer, a transparent sheet, a hologram formation layer, a resin layer, and a sheet substrate. An antistatic layer may be provided on the surface of the receptive layer, the backside of the sheet substrate, or the outermost surface of both sides. The antistatic layer may be formed by coating a solution or dispersion of an antistatic agent, such as a fatty ester, a sulfuric ester, a phosphoric ester, an amide, a guaternary ammonium salt, a betaine, an amino acid, an acrylic resin, or an ethylene oxide adduct, in a solvent. The forming means used may be the same as that used in the formation of the receptive layer. The coverage of the antistatic layer is preferably 0.001 to 0.1 g/m² on a dry basis.

An intermediate layer formed of one of various resins may be provided between the substrate and the receptive layer in the transparent sheet. In this case, the intermediate layer is preferably transparent so that the re-transferred image can be viewed. When the intermediate layer has various functions, excellent functions can be imparted to the image-receiving sheet. For example, a highly elastically deformable or plastically deformable resin, for example, a polyolefin resin, a vinyl copolymer resin, a polyurethane resin, or a polyamide resin, may be used as a cushioning property-imparting resin to improve the sensitivity in printing of the image-receiving sheet or to prevent harshness of images Antistatic properties may be imparted to the intermediate layer by adding the antistatic agent to the cushioning property-imparting resin, dissolving or dispersing the mixture in a solvent, and coating the solution or dispersion to form an intermediate layer.

(Half Cutting)

In the intermediate transfer recording medium according to the present invention, the transparent sheet portion including the receptive layer and the hologram formation layer has been subjected to half cutting 37. The half cut may be formed by any method without particular limitation so far as half cutting is possible. Examples of methods usable for half cutting include a method wherein the intermediate transfer recording medium is inserted into between an upper die provided with a cutter blade and a pedestal and the upper die is then vertically moved and a method wherein a cylinder-type rotary cutter is used, and a method wherein heat treatment is carried out by means of a laser beam. As shown in FIG. 10, the portion 39 except for the image forming portion 38 is previously separated using the half cut portion 37 as the boundary between the portion remaining unremoved and the removal portion, and, at the time of image formation, the receptive layer 33 provided on the transparent sheet 32 is left only in the image forming portion 38. The removal of refuse in this way can eliminate a fear of the transparent sheet portion being cut by the half cut portion at the time of the re-transfer of the image onto the object. Thus, the image formed portion can be surely transferred onto the object.

Regarding the half cut portion 37, it is common practice to continuously provide a cut one round by one round around the image forming portion. In this case, an uncut (no cut) portion may be partially provided, for example, at four corners, to prevent the a trouble of separation of the half cut portion during handling, for example, during carriage through a thermal transfer printer. However, it should be noted that, in order that, at the time of the re-transfer of the image formed portion onto the object, the uncut portion is melt cut and the portion surrounded by the continuous half cut portion including the melt cut portion is transferred onto the object, the length of the uncut is preferably small and about 0.1 to 0.5 mm. Alternatively, perforation, such that half cuts and uncuts are alternately provided, may be provided. In the case of the perforation, for example, preferably, the length of the cut portion is about 2 to 5 mm, and the length of the uncut portion is about 0.1 to 0.5 mm. Examples of methods usable for the formation of the perforation include a method wherein the intermediate transfer recording medium is inserted into between an upper die provided with a perforating blade and a pedestal and the upper die is then vertically moved and a method wherein a cylinder-type rotary cutter.

At the time of half cutting, when the depth of the cut portion is excessively large in the depth direction, that is, when not only the transparent sheet portion but also the sheet substrate is cut, the intermediate transfer recording medium is cut at the half cut portion during carriage in the printer, often leading to carriage troubles. On the other hand, when the cut level is excessively low in the depth direction, for example, when a half cut is provided, for example, only in the receptive layer without the provision of a half cut in the transparent sheet, the resin layer and the transparent sheet cannot be separated from each other at the time of the re-transfer of the image-formed portion onto an object. Therefore, as shown in FIG. 9, the depth of the half cutting is preferably on a level such that passes through the receptive layer, the hologram formation layer, and the transparent sheet and slightly bites the resin layer in the thicknesswise direction. Preferably, the half cutting according to the present invention is previously carried out before the formation of an image on the receptive layer in the intermediate transfer recording medium. However, alternatively, the half cutting may be carried out according to the image region after the formation of an image on the receptive layer in the intermediate transfer recording medium.

(Production Process of Intermediate Transfer Recording Medium)

According to the present invention, there is provided a process for producing an intermediate transfer recording medium comprising a sheet substrate provided with a resin layer and a transparent sheet provided with a receptive layer, the transparent sheet provided with the receptive layer having been put on top of the sheet substrate provided with the resin layer so that the resin layer faces the transparent sheet on its side remote from the receptive layer, the transparent sheet portion including the receptive layer having been half cut, a hologram formation layer being stacked on the transparent sheet, the resin layer being separable from the transparent sheet, said process comprising the steps of: providing an original sheet comprising a hologram formation layer stacked on a transparent sheet; forming a receptive layer by coating on the original sheet; applying the transparent sheet on its side remote from the receptive layer onto a sheet substrate, in which register marks have been previously provided at respective positions for one screen unit, through a resin layer; and then reading the register marks to perform registration for half cutting and then to perform half cutting.

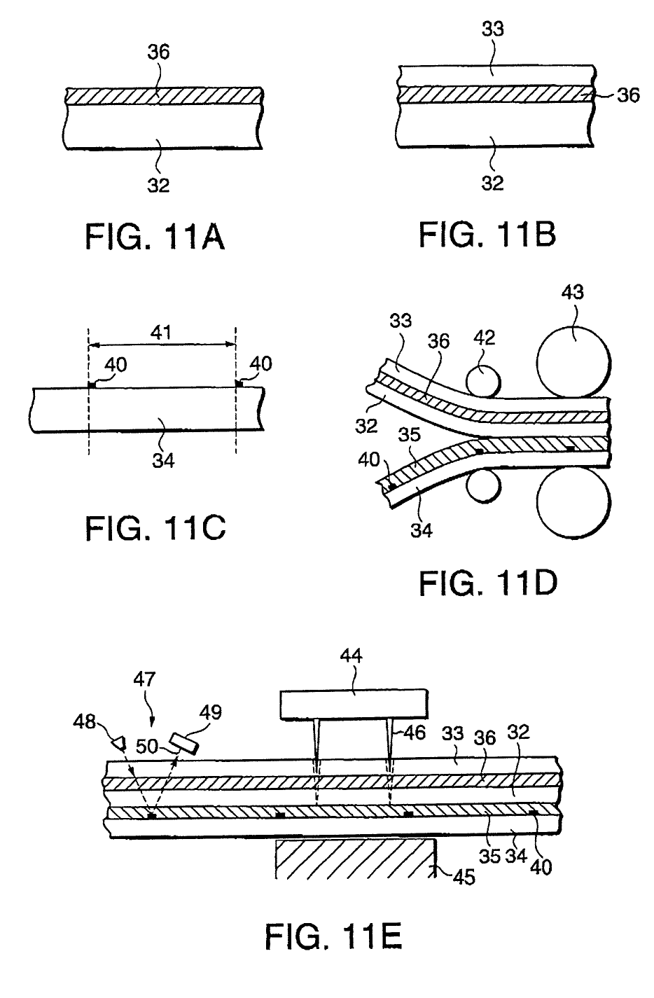

An embodiment of the production process of an intermediate transfer recording medium will be described with reference to FIG. 11.

As shown in FIG. 11A, an original sheet composed of a transparent sheet 32 and a hologram formation layer 36 stacked onto the transparent sheet 32 is provided. Next, as shown in FIG. 11B, a receptive layer 33 is formed on the hologram formation layer 36 in the original sheet by coating and drying by a conventional method as described above in connection with the intermediate transfer recording medium.

As shown in FIG. 11C, register marks 40 are repeatedly provided on a sheet substrate 34 for each screen 41. The register marks 40 may be formed by any method, and examples of methods usable herein include gravure printing or offset printing, the provision of a deposit film by hot stamping using a transfer foil, the application of a deposit film provided with a pressure-sensitive adhesive on the backside of the sheet substrate, and the provision of through holes which extend from the surface to the backside of the sheet substrate 34. In this case, the register marks 40 are provided while leaving a space for each screen 41.

For example, the shape or the color of the register mark is not particularly limited so far as the register mark is detectable with a detector. Examples of shapes of the register mark include quadrangle, circle, bar cord, and line extending from end to end in the widthwise direction of the intermediate transfer recording medium.

The color of the register mark may be any one detectable with a detector. For example, when a light transmission detector is used, silver, black and other colors having a high level of opaqueness may be mentioned as the color of the register mark. On the other hand, when a light reflection detector is used, for example, a highly light reflective metalescent color may be mentioned as the color of the register mark.

A hologram mark (a mark having a hologram pattern) may be used as the register mark. The hologram mark may be formed by any conventional method for the formation of a hologram pattern, for example, by providing an original plate having a concave-convex pattern of interference fringes of a hologram and forming fine concaves and convexes by embossing. The so-called “hologram sensor” may be utilized as a sensor for the hologram mark. In this sensor, light emitted from a light emitting device is irregularly reflected from the hologram mark and emits diffracted light which is then detected with a photodetector to detect the position of the hologram mark.

The position of the register mark is not limited to the position shown in the drawing. For example, when the sheet substrate is transparent, the register mark may be provided on the sheet substrate in its side remote from the side on which the resin layer is to be formed.

As shown in FIG. 11D, the assembly comprising the hologram formation layer 36 and the receptive layer 33 provided on the transparent sheet 32 as described above in conjunction with FIG. 11B are laminated onto the sheet substrate 34 provided with the register mark 40 as described above in conjunction with FIG. 11C through a resin layer 35 so that the transparent sheet 32 on its side remote from the receptive layer 33 faces the sheet substrate 34 on its register mark 40 side.

In this lamination, the transparent sheet 32 side and the sheet substrate 34 side are guided by means of guide rolls 42 and are put on top of each other. In this case, a resin layer 35 is previously formed by coating on the sheet substrate by a conventional method although this is not shown in the drawing.

In this way, the transparent sheet 32 side and the sheet substrate 34 side are put on top of each other through the resin layer 35, and both the assemblies are pressed by laminate rolls 43 optionally with heating and consequently laminated to form an integral structure.

The resin layer may be in the form of a pressure-sensitive-adhesive layer, an easy-adhesion adhesive layer, or an extrusion coating (EC), and lamination methods, such as dry lamination, hot-melt lamination, and EC lamination, may be used according to the form of the resin layer.

In the embodiment shown in FIG. 11D, the resin layer 35 is coated onto the sheet substrate 34, and the transparent sheet 32 side and the sheet substrate 34 side are laminated onto each other through the resin layer 35. Alternatively, a method may also be used wherein the resin layer is coated on the transparent sheet side and the transparent sheet side and the sheet substrate side are laminated onto each other through the resin layer.

As shown in the drawing, in a construction such that the register mark 40 comes into direct contact with the resin layer 35, for example, when an aqueous solvent is used in the coating liquid for the resin layer, it is important that a solvent, such as toluene or methyl ethyl ketone, be used in the coating liquid for the register mark from the viewpoint of rendering the register mark and the resin layer incompatible with each other at the time of the lamination of the sheet substrate and the transparent sheet through the resin layer. The reason for this is as follows. When the register mark is incompatible with the layer in contact with the register mark, adverse effect on the register mark print, such as bleeding of the register mark or trapping, can be avoided.

As shown in FIG. 11E, the intermediate transfer recording medium 31 produced by providing the hologram formation layer 36 and the receptive layer 33 on the transparent sheet 32 and laminating the transparent sheet 32 on its side remote from the receptive layer 33 onto the sheet substrate 34, provided with the register mark 40, through the resin layer 35, is subjected to half cutting using an upper die 44, provided with a half cutting blade 46 having predetermined size and pattern, and a pedestal 45. specifically, the intermediate transfer recording medium 31 is placed between the upper die 44, provided with the cutter blade 46, and the pedestal 45, and the upper die 44 is pressed toward the pedestal 45 to perform half cutting 37 in the intermediate transfer recording medium 31.

This half cutting should be carried out at predetermined positions in the intermediate transfer recording medium 31. To this end, the register mark 40 provided in the intermediate transfer recording medium is read by a specialty detector 44 for register mark reading, and, in synchronization of the read signal, the upper die 44 provided with the cutter blade 46 is dropped toward the pedestal 45. The registration for half cutting 37 is then carried out followed by half cutting 37.

Regarding the detector 47 shown in the drawing, light emitted from a light emitting device 48 is reflected from the register mark 40 provided in the intermediate transfer recording medium 31, and the reflected light 50 is detected with a photodetector 49 to detect the position of the register mark 40. In this embodiment, the register mark is detected with a light reflection sensor. The detection method, however, is not limited to this only. For example, a transmission sensor may also be utilized wherein a light emitting device provided on one side of the intermediate transfer recording medium emits light toward the register mark, and the transmitted light is detected with a photodetector provided on the other side of the intermediate transfer recording medium.

As described above, after the half cutting, the portion except for the image forming portion is preferably separated and removed using the half cut portion as the boundary between the portion remaining unremoved and the removal portion from the viewpoint of production. This permits the patch portion (the portion separated by the half cutting) of the image forming portion of the intermediate transfer recording medium to be easily transferred in a sharp and accurate edge shape on an object.

In the transfer of the patch portion onto the object, the area of the patch portion is smaller than or equal to the total transfer area of the object. In order to avoid an unfavorable phenomenon such that the end of the patch portion is transferred onto the object and projected from the object to a noticeable extent, the patch portion as the image forming portion is preferably smaller than the total transfer area of the object by one to several dots or by about 0.5 to 2 mm in terms of the end portion length.

In connection with the size of the transfer face, the total width of the intermediate transfer recording medium is preferably larger than the width of the transfer face of the object. In this case, when an image is formed on the receptive layer of the intermediate transfer recording medium followed by the transfer of the image formed portion onto the object, the object does not come into direct contact with a heating device, such as a thermal head, a press roll, or a press plate. Therefore, damage to the object can be prevented.

In reading the register mark to perform the registration for half cutting in the intermediate transfer recording medium and to perform half cutting, care should be taken so that the hologram image provided in the hologram formation layer of the intermediate transfer recording medium is not cut at the half cut portion. In order to avoid this unfavorable phenomenon, the use of the following method is preferred. A part of the hologram image provided in the hologram formation layer is read as a detection mark. Alternatively, a hologram detection mark is provided, and the detection mark is read. This reading is synchronized with the reading of the register mark to regulate the position of half cutting and the position of hologram image. When the hologram detection mark is used, a hologram detection sensor should be provided.

(Method for Image Formation)

The method for image formation according to the present invention comprises the steps of: providing the above intermediate transfer recording medium; transferring an image onto the receptive layer in the intermediate transfer recording medium to form an image on the receptive layer; and re-transferring only the image formed portion onto an object to form an image on the object.

In the thermal transfer recording method for forming an image on the receptive layer, thermal energy controlled by an image signal is generated by means of a thermal head and is used as activation energy of a recoding material such as ink. In this method, a thermal transfer sheet comprising a thermally transferable colorant layer provided on a substrate sheet is put on top of recording paper. The assembly is passed through between a thermal head and a platen under suitable pressure, and the recording material is activated by the thermal head at a temperature increased by energization and transferred onto the recording paper with the aid of pressure of the platen.

The transfer recording method is classified into sublimation dye thermal transfer (sublimation-type thermal transfer) and thermal ink transfer (hot melt-type thermal transfer). Both the types can be used in the formation of an image on an object according to the present invention. Further, the sublimation dye thermal transfer may be used in combination with the thermal ink transfer. In this case, for example, a halftone image may be formed by the sublimation dye thermal transfer recording while forming character images by the thermal ink transfer recording.

The thermal transfer recording can be carried out by the thermal head, as well as by thermal transfer means utilizing laser beam irradiation heating.

According to the present invention, examples of means for re-transferring the image formed portion onto an object include: one wherein the object and the intermediate transfer recording medium with an image formed thereon are sandwiched between a thermal head and a platen and the assembly is heated by the thermal head; one wherein a heat roll system is used (a commercially available laminator is in many cases of this type wherein hot pressing is carried out by a pair of heat rolls); one wherein the object and the intermediate transfer recording medium are sandwiched between a heated flat plate and a flat plate or between a heated flat plate and a roll followed by hot pressing; and one wherein thermal transfer is carried out by heating utilizing laser beam irradiation.

When the thermal head is used as means for re-transferring the image onto the object, the thermal head may be the same as used in the image formation, or alternatively, may be different from the thermal head used in the image formation. In the method for image formation according to the present invention, the thermal transfer means for image formation and the means for the re-transfer of the image onto the object are preferably carried out on an in-line basis by means of one thermal transfer printer from the viewpoint of efficiency.

Fourth Invention

The conventional protective layer should be partially transferred at the time of transfer by means of a thermal head or a heat roll and thus should have good transferability. To this end, the protective layer should be a resin layer having a thickness of about several μm. This makes it impossible to impart fastness properties, such as high scratch resistance and chemical resistance, to images. Also regarding the protective layer formed in the intermediate transfer recording medium, satisfactory fastness properties, such as satisfactory scratch resistance and chemical resistance, cannot be imparted when the transferability is taken into consideration. A method can also be considered wherein the intermediate transfer recording medium is used to form an image on an object and a resin film is laminated so as to cover the image formed on the object to form a protective layer. This, however, is considered to be disadvantageous in that, for some shape in the object, the resin film is cockled at the time of the lamination, and, in addition, for example, a specialty device, such as a laminator, should be used, resulting in the increased number of steps.

Accordingly, in order to solve the above problems of the prior art, it is an object of the present invention to provide an intermediate transfer recording medium, which can form thermally transferred images possessing excellent various fastness properties even under severe service conditions, can realize the transfer of a protective layer on the image in the object with high accuracy without a failure of transfer in a simple manner, and a method for image formation.

The above object can be attained by an intermediate transfer recording medium comprising: a sheet substrate provided with a resin layer; and a transparent sheet provided with a receptive layer, the transparent sheet provided with the receptive layer having been put on top of the sheet substrate provided with the resin layer so that the resin layer faces the transparent sheet on its side remote from the receptive layer, the transparent sheet portion including the receptive layer having been half cut, the resin layer being separable from the transparent sheet, the peel force necessary for separating the transparent sheet portion from the sheet substrate provided with the resin layer at the time of the transfer of the transparent sheet portion including the receptive layer onto an object being in the range of 5 to 100 gf/inch as measured by the 180-degree peel method according to JIS Z 0237.

In this construction, preferably, the whole portion except for the image forming portion has been separated and removed using the half cut as a boundary between the image forming portion remaining unremoved and the removal portion. This permits the patch portion of the image forming portion in the intermediate transfer recording medium to be simply transferred in a sharp and accurate edge shape.

The patch portion as the image forming portion, which has been separated by the half cutting, preferably has a size smaller than an object in its whole area on which an image is to be transferred. In this case, there is no fear of the patch portion being projected from the end of the object.

Preferably, the patch portion as the image forming portion, which has been separated by the half cutting, has a partially removed portion relative to an object In this case, for example, the position of an object in its portion where the formation of no image is desired, for example, a sign panel, IC chip, magnetic stripe or other portion, or a design portion previously printed on the object, such as a logo or a hologram, can be registered with the partially removed portion, followed by the re-transfer of the patch onto the object. By virtue of this, in the sign panel, IC chip, magnetic stripe or other portion, a deterioration in performance in the post treatment of the portion can be prevented. Further, in the design portion, such as logo or hologram, the formation of an image on that portion deteriorates the transparent in that portion, that is, increases the opaqueness in that portion, leading to lowered quality. For this reason, that portion is excluded from the image forming portion. The sign panel portion is a portion where handwriting with writing implements, such as ballpoint pens, numbering by stamping ink, and sealing by vermilion inkpad or stamping ink.

Preferably, the total width of the intermediate transfer recording medium is larger than the width of an object in its face on which an image is to be transferred. According to this construction, in the formation of an image on the receptive layer in the intermediate transfer recording medium followed by the re-transfer of the image formed portion onto an object, a heating device, such as a thermal head, a press roll, or a press plate, does not come into direct contact with the object, and, thus, damage to the object can be avoided.

Further, according to the present invention, there is provided a method for image formation, comprising the steps of: providing any one of the above intermediate transfer recording media; and transferring an image onto the receptive layer in the intermediate transfer recording medium to form an image on the receptive layer; and re-transferring only the image formed portion onto an object to form an image on the object.

The intermediate transfer recording medium according to the present invention comprises: a sheet substrate provided with a resin layer; and a transparent sheet provided with a receptive layer, the transparent sheet provided with the receptive layer having been put on top of the sheet substrate provided with the resin layer so that the resin layer faces the transparent sheet on its side remote from the receptive layer, the transparent sheet portion including the receptive layer having been half cut, the resin layer being separable from the transparent sheet, the peel force necessary for separating the transparent sheet portion from the sheet substrate provided with the resin layer at the time of the transfer of the transparent sheet portion including the receptive layer onto an object being in the range of 5 to 100 gf/inch as measured by the 180-degree peel method according to JIS Z 0237. The use of this intermediate transfer recording medium can provide thermally transferred images possessing excellent various fastness properties even under severe service conditions and, by virtue of the half cutting, permits the protective layer (transparent sheet) to be transferred onto the image with high accuracy in a simple manner. Further, the regulation of the peel force for separating the transparent sheet portion from the sheet substrate provided with the resin layer in the above-defined range can prevent a failure of transfer and permits the transparent sheet portion to be simply transferred onto the object.

The present invention will be described in more detail with reference to the following preferred embodiments.

FIG. 13 is a schematic cross-sectional view showing one embodiment of the intermediate transfer recording medium 61 according to the present invention. In this intermediate transfer recording medium 61, a sheet substrate 64 having thereon a resin layer 65 and a transparent sheet 62 having thereon a receptive layer 63 are stacked onto each other so that the resin layer 65 faces the transparent sheet 62 and, in addition, the resin layer 65 is separable from the transparent sheet 62, wherein the transparent sheet portion 62 including the receptive layer 63 has been subjected to half cutting 67.

FIG. 14 is a schematic cross-sectional view showing another embodiment of the intermediate transfer recording medium 61 according to the present invention. In this intermediate transfer recording medium 61, a sheet substrate 64 having thereon a resin layer 65 and a transparent sheet 62 having thereon a receptive layer 63 are stacked onto each other so that the resin layer 65 faces the transparent sheet 62 and, in addition, the resin layer 65 is separable from the transparent sheet 62, wherein the transparent sheet portion 62 including the receptive layer 63 has been subjected to half cutting 67 and a portion 69 except for an image forming portion 68 has been separated and removed using the half cut portion 67 as the boundary between the image forming portion 68 remaining unremoved and the removal portion. In this embodiment, before the step of forming an image by thermal transfer and re-transferring the transfer portion onto an object, the step of separating and removing the portion 69 except for the image forming portion 68 using the half cut portion 67 as the boundary between the portion remaining unremoved and the removal portion is provided. In this case, a patch portion 66 having thereon the image formed portion 68 is re-transferred onto an object. Therefore, in re-transferring the transfer portion onto the object, only the patch portion may be transferred. This can further simplify re-transfer onto the object.

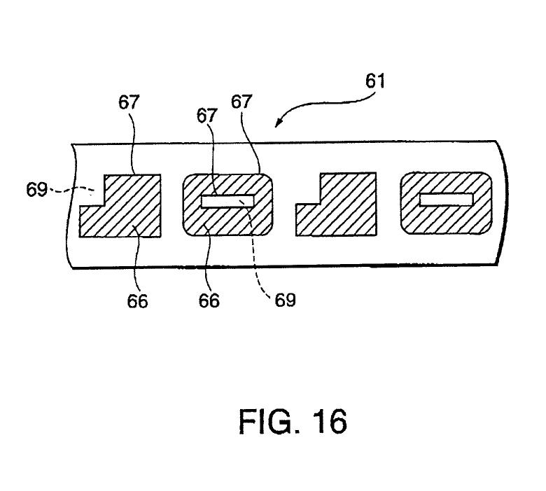

FIG. 16 is a schematic plan view showing a further embodiment of the intermediate transfer recording medium 61 according to the present invention. In this intermediate transfer recording medium 61, a sheet substrate having thereon a resin layer and a transparent sheet having thereon a receptive layer are stacked onto each other so that the resin layer faces the transparent sheet and, in addition, the resin layer is separable from the transparent sheet, wherein the transparent sheet portion including the receptive layer has been subjected to half cutting 67 In this case, a patch portion 66 as the image forming portion is left using the half cut portion 67 as the boundary between the removal portion and the image forming portion remaining unremoved, and, as shown in the drawing, the outside of the patch portion 66 and the inside removal portion surrounded by the patch portion 66 are separated and removed. Upon the re-transfer of this patch portion 66 onto an object, the patch portion 66 has a partially removed portion 69 relative to the object. In this case, for example, a portion where the formation of no image as the patch portion is desired, such as a hologram portion or a logo portion in an object, for example, a sign panel, an IC chip, a magnetic stripe, or a credit card, is registered with the partially removed portion 69. By virtue of this, no image is present in a position where the formation of no image is contemplated. Thus, the occurrence of troubles can be prevented. (Transparent sheet) In the transparent sheet 62 used in the intermediate transfer recording medium according to the present invention, the transparent sheet portion is cut using the half cut portion as the boundary between the removal portion and the portion remaining unremoved, and the transparent sheet can function as a protective layer in such a state that the transparent sheet covers the surface of the image formed portion. The transparent sheet may be any one so far as the sheet is transparent and has fastness properties, such as weathering resistance, abrasion resistance, and chemical resistance. Examples of transparent sheets usable herein include about 0.5 to 100 μm-thick, preferably about 10 to 40 μ-thick, films of polyethylene terephthalate, 1,4-polycyclohexylene dimethylene terephthalate, polyethylene naphthalate, polyphenylenesulfide, polystyrene, polypropylene, polysulfone, arainid, polycarbonate, polyvinyl alcohol, cellulose derivatives, such as cellophane and cellulose acetate, polyethylene, polyvinyl chloride, nylon, polyimide, and ionomer.

The transparent sheet in its side facing the resin layer may be subjected to release treatment to facilitate the separation of the transparent sheet from the resin layer. In the release treatment, a release layer is provided on the transparent sheet. The release layer may be formed by coating a coating liquid containing, for example, a wax, silicone wax, a silicone resin, a fluororesin, an acrylic resin, a polyvinyl alcohol rein, or a cellulose derivative resin or a copolymer of monomers constituting the above group of resins onto the transparent sheet by conventional means, such as gravure printing, screen printing, or reverse roll coating using a gravure plate, and drying the coating. The coverage of the release layer is about 0.1 to 10 g/m² on a dry basis.

(Receptive Layer)

The receptive layer 63 may be formed on the transparent sheet either directly or through a primer layer. The construction of the receptive layer 63 varies depending upon the recording system, that is, whether the recording system is hot-melt transfer recording or sublimation transfer recording. In the hot-melt transfer recording, a method may also be adopted wherein a color transfer layer is thermally transferred from the thermal transfer sheet directly onto the transparent sheet without providing the receptive layer. In the hot-melt transfer recording and the sublimation transfer recording, the receptive layer functions to receive a colorant thermally transferred from the thermal transfer sheet. In particular, in the case of the sublimable dye, preferably, the receptive layer receives the dye, develops a color, and, at the same time, does not permit re-sublimation of the once received dye. A transfer image is formed on a receptive layer in an intermediate transfer recording medium, and only the image formed portion is re-transferred onto an object to form an image on the object. The receptive layer according to the present invention is generally transparent so that an image transferred onto the object can be clearly viewed from the top. However, it is also possible to intentionally make the receptive layer opaque or to intentionally lightly color the receptive layer to render the re-transferred image distinct.

The receptive layer is generally composed mainly of a thermoplastic resin. Examples of materials usable for forming the receptive layer include: polyolefin resins such as polypropylene; halogenated polymers such as vinyl chloride-vinyl acetate copolymer, ethylene-vinyl acetate copolymer, and polyvinylidene chloride; polyester resins such as polyvinyl acetate and polyacrylic esters; polystyrene resins; polyamide resins; copolymer resins produced from olefins, such as ethylene and propylene, and other vinyl monomers; ionomers; cellulosic resins such as cellulose diacetate; and polycarbonate resins. Among them, polyester resins and vinyl chloride-vinyl acetate copolymer and mixtures of these resins are particularly preferred.

In sublimation transfer recording, a release agent may be incorporated into the receptive layer, for example, from the viewpoint of preventing fusing between the thermal transfer sheet having a color transfer layer and the receptive layer in the intermediate transfer recording medium at the time of image formation or preventing a lowering in sensitivity in printing. Preferred release agents usable as a mixture include silicone oils, phosphoric ester surfactants, and fluorosurfactants. Among them, silicone oils are preferred. Preferred silicone oils include epoxy-modified, vinyl-modified, alkyl-modified, amino-modified, carboxyl-modified, alcohol-modified, fluorine-modified, alkyl aralkyl polyether-modified, epoxy-polyether-modified, polyether-modified and other modified silicone oils.

A single or plurality of release agents may be used. The amount of the release agent added is preferably 0.5 to 30 parts by weight based on 100 parts by weight of the resin for the receptive layer. When the amount of the release agent added is outside the above amount range, problems sometimes occur such as fusing between the sublimation-type thermal transfer sheet and the receptive layer in the intermediate transfer recording medium or a lowering in sensitivity in printing. The addition of the release agent to the receptive layer permits the release agent to bleed out on the surface of the receptive layer after the transfer to form a release layer. Alternatively, these release agents may be separately coated onto the receptive layer without being incorporated into the receptive layer. The receptive layer may be formed by coating a solution of a mixture of the above resin with a necessary additive, such as a release agent, in a suitable organic solvent, or a dispersion of the mixture in an organic solvent or water onto a transparent sheet by conventional forming means such as gravure coating, gravure reverse coating, or roll coating, and drying the coating. The receptive layer may be formed at any coverage. In general, however, the coverage of the receptive layer is 1 to 50 g/m² on a dry basis. The receptive layer is preferably in the form of a continuous coating. However, the receptive layer may be in the form of a discontinuous coaling formed using a resin emulsion, a water-soluble resin, or a resin dispersion. Further, an antistatic agent may be coated onto the receptive layer from the viewpoint of realizing stable carrying of sheets through a thermal transfer printer.

(Sheet Substrate)

The sheet substrate 64 used in the present invention is not particularly limited, and examples thereof include: various types of paper, for example, capacitor paper, glassine paper, parchment paper, or paper having a high sizing degree, synthetic paper (such as polyolefin synthetic paper and polystyrene synthetic paper), cellulose fiber paper, such as wood free paper, art paper, coated paper, cast coated paper, wall paper, backing paper, synthetic resin- or emulsion-impregnated paper, synthetic rubber latex-impregnated paper, paper with synthetic resin internally added thereto, and paperboard; and films of polyester, polyacrylate, polycarbonate, polyurethane, polyimide, polyether imide, cellulose derivative, polyethylene, ethylene-vinyl acetate copolymer, polypropylene, polystyrene, acrylic resin, polyvinyl chloride, polyvinylidene chloride, polyvinyl alcohol, polyvinyl butyral, nylon, polyether ether ketone, polysulfone, polyether sulfone, tetrafluoroethylene-perfluoroalkyl vinyl ether, polyvinyl fluoride, tetrafluoroethylene-ethylene, tetrafluoroethylene-hexafluoropropylene, polychlorotri-fluoroethylene, polyvinylidene fluoride and the like.

The thickness of the sheet substrate is preferably 10 to 100 μm. When the sheet substrate is excessively thin, the resultant intermediate transfer recording medium is not sturdy and thus cannot be carried by means of a thermal transfer printer or is disadvantageously curled or cockled. On the other hand, when the sheet substrate is excessively thick, the resultant intermediate transfer recording medium is excessively thick. In this case, the driving force of the thermal transfer printer necessary for carrying the intermediate transfer recording medium is excessively large, resulting in a printer trouble or a failure of the intermediate transfer recording medium to be normally carried.

(Resin Layer)

The resin layer 65 may be provided as a pressure-sensitive adhesive layer, an easy-adhesion adhesive layer, or an extrusion coating (EC) on the sheet substrate.

In the resin layer independently of whether the resin layer is in the form of a pressure-sensitive adhesive layer, an easy-adhesion adhesive layer, or an EC layer, the peel force, that is, the peel force for separating the transparent sheet portion from the sheet substrate provided with the resin layer, should be in the range of 5 to 100 gf/inch as measured by the 180-degree peel method according to JIS Z 0237. The peel force can be regulated in the above range by properly selecting the material (such as a binder) used in the resin layer and properly varying the layer thickness according to the type of the sheet substrate.

When the peel force is below the lower limit of the above range, the patch portion is likely to be separated and removed (for example, rolled up) during handling of the intermediate transfer recording medium. On the other hand, when the peel force is above the upper limit of the above range, the re-transfer of the patch portion onto the object is difficult. At the time of the formation of a thermally transferred image on the patch portion in the intermediate transfer recording medium, heat is more or less applied to the resin layer. It is a matter of course that the peel force should fall within the above-defined range after undergoing the heat history.

Further, the cohesive force of the resin layer is also important, and should be on a level such that, upon the separation, the resin layer is not left on the transparent sheet side, that is, no adhesive is left.

The pressure-sensitive adhesive layer may be formed of a conventional solvent-type or aqueous pressure-sensitive adhesive. Pressure-sensitive adhesives include, for example, acrylic resins, acrylic ester resins, or copolymers thereof, styrene-butadiene copolymers, naturally occurring rubbers, casein, gelatin, rosin esters, terpene resins, phenolic resins, styrene resins, coumarone indene resins, polyvinyl ethers, and silicone resins. Further, α-cyanoacrylate, silicone, maleimide, styrol, polyolefin, resorcinol, and polyvinyl ether adhesives may also be mentioned as the pressure-sensitive adhesive. Further, the pressure-sensitive adhesive layer may also be formed using the so-called “two-pack crosslinkable pressure-sensitive adhesive” wherein, in use, an isocyanate crosslinking agent, a metal chelate crosslinking agent or the like is added for crosslinking. If necessary, a tackifier resin (tackifier) may be added to the pressure-sensitive adhesive layer to bring the peel force to a value falling within the above-defined range. Tackifier resins include rosin tackifier resins, terpene tackifier resins, synthetic resin tackifiers, or mixtures of these tackifiers.

The coverage of the pressure-sensitive adhesive layer is generally about 8 to 30 g/m² on a solid basis, and the pressure-sensitive adhesive layer may be formed by coating the pressure-sensitive adhesive by a conventional method, for example, gravure coating, gravure reverse coating, roll coating, Komma coating, or die coating, on a release sheet and drying the coating. In the formation of the pressure-sensitive adhesive layer on the sheet substrate, the above-described type of adhesive and coverage are selected so that the peel strength is in the above-defined range. When the pressure-sensitive adhesive layer is provided on the sheet substrate and the transparent sheet is stacked onto the pressure-sensitive adhesive layer, a method may be adopted such as dry lamination or hot-melt lamination of the pressure-sensitive adhesive layer.

In the formation of the easy-adhesion adhesive layer, preferably, a latex of styrene-butadiene copolymer rubber (SBR), an acrylic resin, such as acrylonitrile-butadiene copolymer rubber (NBR) or a polyacrylic ester, a rubbery resin, a wax, or a mixture of two or more of the above materials is coated onto a sheet substrate by a conventional coating method, and the easy-adhesion adhesive layer is then stacked onto the transparent sheet by dry lamination with heating. The easy-adhesion adhesive layer after the separation of the transparent sheet from the sheet substrate has lowered tackiness and no longer can be used in the application of the transparent sheet to the sheet substrate. When this easy-adhesion adhesive layer is used, a primer layer may be provided between the sheet substrate and the easy-adhesion adhesive layer.

Further, an EC layer may be provided as the resin layer according to the present invention on the sheet substrate. The thermoplastic resin used for forming the EC layer is not particularly limited so far as the resin is not virtually adhered to the transparent sheet and is extrudable. In particular, however, a polyolefin resin is preferred which is not virtually adhered to PET films generally utilized in the transparent sheet and has excellent processability. More specifically, for example, LDPE, MDPE, HDPE, and PP resins are usable. In extrusion coating these resins, when a matte roll is used as a cooling roll, the matte face may be transferred onto the surface of the EC layer, whereby fine concaves and convexes can be formed to render the EC layer opaque. Alternatively, a method may be used wherein a white pigment, such as calcium carbonate or titanium oxide, is mixed into the polyolefin resin to form an opaque EC layer. The EC layer may be either a single-layer structure or a multi-layer structure of two or more layers. The peel strength of the EC layer from the transparent sheet may be regulated according to the processing temperature in the extrusion and the type of the resin. Thus, simultaneously with the extrusion of the EC layer on the sheet substrate, the sheet substrate can be stacked onto the transparent sheet through the EC layer by the so-called “EC lamination.

In providing the resin layer on the sheet substrate, a primer layer may be provided on the surface of the sheet substrate to improve the adhesion between the sheet substrate and the resin layer. Instead of the provision of the primer layer, the surface of the sheet substrate may be subjected to corona discharge treatment. The primer layer may be formed by providing a coating liquid in the form of a solution or dispersion of a polyester resin, a polyacrylic ester resin, a polyvinyl acetate resin, a polyurethane resin, a polyamide resin, a polyethylene resin, a polypropylene resin or the like in a solvent and coating the coating liquid by the same means as used in the formation of the receptive layer. The thickness of the primer layer is about 0.1 to 5 g/m² on a dry basis. The primer layer may also be formed between the transparent sheet and the receptive layer in the same manner as described above.

In the intermediate transfer recording medium according to the present invention, if necessary, a heat-resistant slip layer may be provided on the backside of the sheet substrate, that is, on the sheet substrate in its side remote from the resin layer, from the viewpoints of preventing adverse effect, such as sticking, caused by heat of a thermal head, a heat roll or the like as means for re-transferring the image formed portion onto an object, or cockling.

Any conventional resin may be used as the resin for constituting the heat-resistant slip layer, and examples thereof include polyvinyl butyral resins, polyvinyl acetoacetal resins, polyester resins, vinyl chloride-vinyl acetate copolymers, polyether resins, polybutadiene resins, styrene-butadiene copolymers, acrylic polyols, polyurethane acrylates, polyester acrylates, polyether acrylates, epoxy acrylates, prepolymers of urethane or epoxy, nitrocellulose resins, cellulose nitrate resins, cellulose acetopropionate resins, cellulose acetate butyrate resins, cellulose acetate hydrogen phthalate resins, cellulose acetate resins, aromatic polyamide resins, polyimide resins, polycarbonate resins, chlorinated polyolefin resins, and chlorinated polyolefin resins.

Slipperiness-imparting agents added to or topcoated on the heat-resistant slip layer formed of the above resin include phosphoric esters, silicone oils, graphite powder, silicone graft polymers, fluoro graft polymers, acrylsilicone graft polymers, acrylsiloxanes, arylsiloxanes, and other silicone polymers. Preferred is a layer formed of a polyol, for example, a high-molecular weight polyalochol compound, a polyisocyanate compound and a phosphoric ester compound. Further, the addition of a filler is more preferred.

The heat-resistant slip layer may be formed by dissolving or dispersing the resin, the slipperiness-imparting agent, and a filler in a suitable solvent to prepare an ink for the formation of a heat-resistant slip layer, coating the ink onto the backside of the substrate sheet by forming means, such as gravure printing, screen printing, or reverse coating using a gravure plate, and drying the coating.

The intermediate transfer recording medium according to the present invention comprises at least a receptive layer, a transparent sheet, a resin layer, and a sheet substrate. An antistatic layer may be provided on the surface of the receptive layer, the backside of the sheet substrate, or the outermost surface of both sides. The antistatic layer may be formed by coating a solution or dispersion of an antistatic agent, such as a fatty ester, a sulfuric ester, a phosphoric ester, an amide, a quaternary ammonium salt, a betaine, an amino acid, an acrylic resin, or an ethylene oxide adduct, in a solvent. The forming means used may be the same as that used in the formation of the receptive layer. The coverage of the antistatic layer is preferably 0.001 to 0.1 g/m² on a dry basis.

An intermediate layer formed of one of various resins may be provided between the substrate and the receptive layer in the transparent sheet. In this case, the intermediate layer is preferably transparent so that the re-transferred image can be viewed. When the intermediate layer has various functions, excellent functions can be imparted to the image-receiving sheet. For example, a highly elastically deformable or plastically deformable resin, for example, a polyolefin resin, a vinyl copolymer resin, a polyurethane resin, or a polyamide resin, may be used as a cushioning property-imparting resin to improve the sensitivity in printing of the image-receiving sheet or to prevent harshness of images. Antistatic properties may be imparted to the intermediate layer by adding the antistatic agent to the cushioning property-imparting resin, dissolving or dispersing the mixture in a solvent, and coating the solution or dispersion to form an intermediate layer.

(Half Cutting)

In the intermediate transfer recording medium according to the present invention, the transparent sheet portion including the receptive layer has been subjected to half cutting 67. The half cut may be formed by any method without particular limitation so far as half cutting is possible. Examples of methods usable for half cutting include a method wherein the intermediate transfer recording medium is inserted into between an upper die provided with a cutter blade and a pedestal and the upper die is then vertically moved, a method wherein a cylinder-type rotary cutter is used, and a method wherein heat treatment is carried out by means of a laser beam. As shown in FIG. 14, the portion 69 except for the patch portion 66 (including the image forming portion 68) is previously separated using the half cut portion 67 as the boundary between the portion remaining unremoved and the removal portion, and, at the time of image formation, the receptive layer 63 provided on the transparent sheet 62 is left only in the image forming portion 68. The removal of refuse in this way can eliminate a fear of the transparent sheet portion being cut by the half cut portion at the time of the re-transfer of the image onto the object. Thus, the patch portion (image formed portion) can be surely transferred onto the object.

Regarding the half cut portion 67, it is common practice to continuously provide a cut one round by one round around the image forming portion. In this case, an uncut (no cut) portion may be partially provided, for example, at four corners, to prevent the a trouble of separation of the half cut portion during handling, for example, during carriage through a thermal transfer printer However, it should be noted that, in order that, at the time of the re-transfer of the image formed portion onto the object, the uncut portion is melt cut and the portion surrounded by the continuous half cut portion including the melt cut portion is transferred onto the object, the length of the uncut is preferably small and about 0.1 to 0.5 mm. Alternatively, perforation, such that half cuts and uncuts are alternately provided, may be provided. In the case of the perforation, for example, preferably, the length of the cut portion is about 2 to 5 mm, and the length of the uncut portion is about 0.1 to 0.5 m. Examples of methods usable for the formation of the perforation include a method wherein the intermediate transfer recording medium is inserted into between an upper die, provided with a perforating blade, and a pedestal and the upper die is then vertically moved and a method wherein a cylinder-type rotary cutter.

At the time of half cutting, when the depth of the cut portion is excessively large in the depth direction, that is, when not only the transparent sheet portion but also the sheet substrate is cut, the intermediate transfer recording medium is cut at the half cut portion during carriage in the printer, often leading to carriage troubles. On the other hand, when the cut level is excessively low in the depth direction, for example, when a half cut is provided, for example, only in the receptive layer without the provision of a half cut in the transparent sheet, the resin layer and the transparent sheet cannot be separated from each other at the time of the re-transfer of the image-formed portion onto an object. Therefore, as shown in FIG. 13, the depth of the half cutting is preferably on a level such that passes through the receptive layer and the transparent sheet and slightly bites the resin layer in the thicknesswise direction. Preferably, the half cutting according to the present invention is previously carried out before the formation of an image on the receptive layer in the intermediate transfer recording medium. However, alternatively, the half cutting may be carried out according to the image region after the formation of an image on the receptive layer in the intermediate transfer recording medium.

(Production Process of Intermediate Transfer Recording Medium)

One of production processes of the intermediate transfer recording medium according to the present invention is a process for producing an intermediate transfer recording medium comprising a sheet substrate provided with a resin layer and a transparent sheet provided with a receptive layer, the transparent sheet provided with the receptive layer having been put on top of the sheet substrate provided with the resin layer so that the resin layer faces the transparent sheet on its side remote from the receptive layer, the transparent sheet portion including the receptive layer having been half cut, the resin layer being separable from the transparent sheet, said process comprising the steps of coating a receptive layer on a transparent sheet; applying the transparent sheet on its side remote from the receptive layer onto a sheet substrate, in which register marks have been previously provided at respective positions for one screen unit, through a resin layer; and then reading the register marks to perform registration for half cutting and then to perform half cutting.

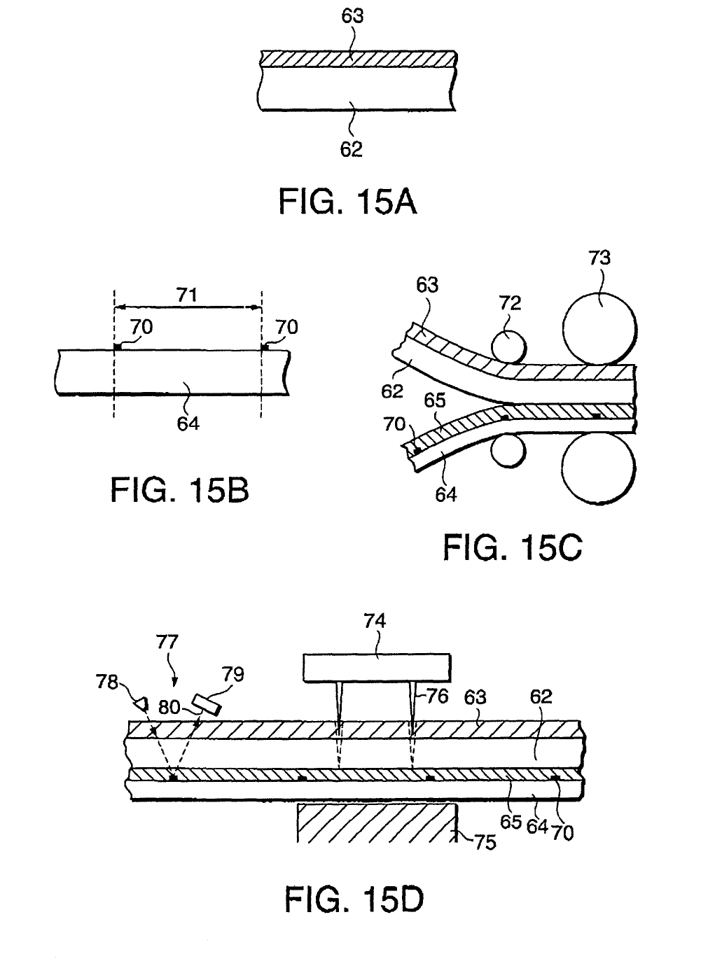

An embodiment of the production process of an intermediate transfer recording medium will be described with reference to FIG. 15.

As shown in FIG. 15A, a receptive layer 63 is first formed on a transparent sheet 62 by coating and drying in an conventional manner.

Next, as shown in FIG. 15B, register marks 70 are repeatedly provided on a sheet substrate 64 for each screen 71. The register marks 70 may be formed by any method, and examples of methods usable herein include gravure printing or offset printing, the provision of a deposit film by hot stamping using a transfer foil, the application of a deposit film provided with a pressure-sensitive adhesive on the backside of the sheet substrate, and the provision of through holes which extend from the surface to the backside of the sheet substrate 64. In this case, the register marks 70 are provided while leaving a space for each screen 71 -For example, the shape or the color of the register mark is not particularly limited so far as the register mark is detectable with a detector. Examples of shapes of the register mark include quadrangle, circle, bar cord, and line extending from end to end in the widthwise direction of the intermediate transfer recording medium. The color of the register mark may be any one detectable with a detector For example, when a light transmission detector is used, silver, black and other colors having a high level of opaqueness may be mentioned as the color of the register mark. On the other hand, when a light reflection detector is used, for example, a highly light reflective metalescent color may be mentioned as the color of the register mark.

A hologram mark (a mark having a hologram pattern) may be used as the register mark. The hologram mark may be formed by any conventional method for the formation of a hologram pattern, for example, by providing an original plate having a concave-convex pattern of interference fringes of a hologram and forming fine concaves and convexes by embossing. The so-called “hologram sensor” may be utilized as a sensor for the hologram mark. In this sensor, light emitted from a light emitting device is irregularly reflected from the hologram mark and emits diffracted light which is then detected with a photodetector to detect the position of the hologram mark.

The position of the register mark is not limited to the position shown in the drawing. For example, when the sheet substrate is transparent, the register mark may be provided on the sheet substrate in its side remote from the side on which the resin layer is to be formed.

As shown in FIG. 15C, the assembly comprising the receptive layer 63 provided on the transparent sheet 62 as described above in conjunction with FIG. 15A are laminated onto the sheet substrate 64 provided with the register mark 70 as described above in conjunction with FIG. 15B through a resin layer 65 so that the transparent sheet 62 on its side remote from the receptive layer 63 faces the sheet substrate 64 on its register mark 70 side.

In this lamination, the transparent sheet 62 side and the sheet substrate 64 side are guided by means of guide rolls 72 and are put on top of each other. In this case, a resin layer 65 is previously formed by coating on the sheet substrate by a conventional method although this is not shown in the drawing.

In this way, the transparent sheet 62 side and the sheet substrate 64 side are put on top of each other through the resin layer 65, and both the assemblies are pressed by laminate rolls 73 optionally with heating and consequently laminated to form an integral structure.

The resin layer may be in the form of a pressure-sensitive adhesive layer, an easy-adhesion adhesive layer, or an extrusion coating (EC), and lamination methods, such as dry lamination, hot-melt lamination, and EC lamination, may be used according to the form of the resin layer.

In the embodiment shown in FIG. 15C, the resin layer 65 is coated onto the sheet substrate 64, and the transparent sheet 62 side and the sheet substrate 64 side are laminated onto each other through the resin layer 65. Alternatively, a method may also be used wherein the resin layer is coated on the transparent sheet side and the transparent sheet side and the sheet substrate side are laminated onto each other through the resin layer.

As shown in the drawing, in a construction such that the register mark 70 comes into direct contact with the resin layer 65, for example, when an aqueous solvent is used in the coating liquid for the resin layer, it is important that a solvent, such as toluene or methyl ethyl ketone, be used in the coating liquid for the register mark from the viewpoint of rendering the register mark and the resin layer incompatible with each other at the time of the lamination of the sheet substrate and the transparent sheet through the resin layer. The reason for this is as follows. When the register mark is incompatible with the layer in contact with the register mark, adverse effect on the register mark print, such as bleeding of the register mark or trapping, can be avoided.

As shown in FIG. 15D, the intermediate transfer recording medium 61 produced by providing the receptive layer 63 on the transparent sheet 62 and laminating the transparent sheet 62 on its side remote from the receptive layer 63 onto the sheet substrate 64, provided with the register mark 70, through the resin layer 65, is subjected to half cutting using an upper die 74, provided with a half cutting blade 76 having predetermined size and pattern, and a pedestal 75.

Specifically, the intermediate transfer recording medium 61 is placed between the upper die 74, provided with the cutter blade 76, and the pedestal 75, and the upper die 74 is pressed toward the pedestal 75 to perform half cutting 67 in the intermediate transfer recording medium 61.

This half cutting should be carried out at predetermined positions in the intermediate transfer recording medium 61. To this end, the register mark 70 provided in the intermediate transfer recording medium is read by a specialty detector 77 for register mark reading, and, in synchronization of the read signal, the upper die 74 provided with the cutter blade 76 is dropped toward the pedestal 75. The registration for half cutting 67 is then carried out followed by half cutting 67.

Regarding the detector 77 shown in the drawing, light emitted from a light emitting device 78 is reflected from the register mark 70 provided in the intermediate transfer recording medium 61, and the reflected light 80 is detected with a photodetector 79 to detect the position of the register mark 70. In this embodiment, the register mark is detected with a light reflection sensor. The detection method, however, is not limited to this only. For example, a transmission sensor may also be utilized wherein a light emitting device provided on one side of the intermediate transfer recording medium emits light toward the register mark, and the transmitted light is detected with a photodetector provided on the other side of the intermediate transfer recording medium.

As described above, after the half cutting, the portion except for the image forming portion is preferably separated and removed using the half cut portion as the boundary between the portion remaining unremoved and the removal portion from the viewpoint of production. This permits the patch portion (the portion separated by the half cutting) of the image forming portion of the intermediate transfer recording medium to be easily transferred in a sharp and accurate edge shape on an object.

In the transfer of the patch portion onto the object, the area of the patch portion is smaller than or equal to the total transfer area of the object. In order to avoid an unfavorable phenomenon such that the end of the patch portion is transferred onto the object and projected from the object to a noticeable extent, the patch portion as the image forming portion is preferably smaller than the total transfer area of the object by one to several dots or by about 0.5 to 2 mm in terms of the end portion length.

In connection with the size of the transfer face, the total width of the intermediate transfer recording medium is preferably larger than the width of the transfer face of the object. In this case, when an image is formed on the receptive layer of the intermediate transfer recording medium followed by the transfer of the image formed portion onto the object, the object does not come into direct contact with a heating device, such as a thermal head, a press roll, or a press plate. Therefore, damage to the object can be prevented.

(Method for Image Formation)

The method for image formation according to the present invention comprises the steps of: providing the above intermediate transfer recording medium; transferring an image onto the receptive layer in the intermediate transfer recording medium to form an image on the receptive layer; and re-transferring only the image formed portion onto an object to form an image on the object.

In the thermal transfer recording method for forming an image on the receptive layer, thermal energy controlled by an image signal is generated by means of a thermal head and is used as activation energy of a recoding material such as ink. In this method, a thermal transfer sheet comprising a thermally transferable colorant layer provided on a substrate sheet is put on top of recording paper. The assembly is passed through between a thermal head and a platen under suitable pressure, and the recording material is activated by the thermal head at a temperature increased by energization and transferred onto the recording paper with the aid of pressure of the platen.

The transfer recording method is classified into sublimation dye thermal transfer (sublimation-type thermal transfer) and thermal ink transfer (hot melt-type thermal transfer). Both the types can be used in the formation of an image on an object according to the present invention. Further, the sublimation dye thermal transfer may be used in combination with the thermal ink transfer. In this case, for example, a halftone image may be formed by the sublimation dye thermal transfer recording while forming character images by the thermal ink transfer recording.

The thermal transfer recording can be carried out by the thermal head, as well as by thermal transfer means utilizing laser beam irradiation heating.

Regarding the thermal transfer recording, an intermediate transfer recording medium is preferably such that a register mark is provided in the intermediate transfer recording medium and half cutting has been performed based on the register mark. At the time of the thermal transfer recording, this register mark is detected to register the position of the thermal transfer image on the intermediate transfer recording medium.

According to the present invention, examples of means for re-transferring the image formed portion onto an object include: one wherein the object and the intermediate transfer recording medium with an image formed thereon are sandwiched between a thermal head and a platen and the assembly is heated by the thermal head; one wherein a heat roll system is used (a commercially available laminator is in many cases of this type wherein hot pressing is carried out by a pair of heat rolls); one wherein the object and the intermediate transfer recording medium are sandwiched between a heated flat plate and a flat plate or between a heated flat plate and a roll followed by hot pressing; and one wherein thermal transfer is carried out by heating utilizing laser beam irradiation.

When the thermal head is used as means for re-transferring the image onto the object, the thermal head may be the same as used in the image formation, or alternatively, may be different from the thermal head used in the image formation. In the method for image formation according to the present invention, the thermal transfer means for image formation and the means for the re-transfer of the image onto the object are preferably carried out on an in-line basis by means of one thermal transfer printer from the viewpoint of efficiency.

In the re-transfer, as with the thermal transfer recording preferably, the register mark of the intermediate transfer recording medium is detected to register the position of the thermally transferred image on the intermediate transfer recording medium with the position of the object.

Fifth Invention

According to the fifth invention, there is provided an intermediate transfer recording medium comprising: a sheet substrate provided with a resin layer; and a transparent sheet provided with a receptive layer, said transparent sheet provided with the receptive layer having been put on top of the sheet substrate provided with the resin layer so that the resin layer faces the transparent sheet on its side remote from the receptive layer, the resin layer being separable from the transparent sheet to transfer the transparent sheet provided with a receptive layer onto an object, the resin layer having a single layer structure or a multi-layer structure of two or more layers.

In this intermediate transfer recording medium, the resin layer is preferably formed of a polyolefin resin stacked on the sheet substrate by extrusion coating.

In the present invention, “extrusion coating” refers to a method wherein a resin pellet or powder is fed into a hopper and, while heating and kneading in a screw, is extruded through a T-die in the form of a film which is then stacked onto the substrate, or a method wherein the resin is extruded between two substrates to apply the substrates to each other.

In the above preferred embodiment, the polyolefin resin is preferably low-density polyethylene. Here “low density polyethylene” refers to polyethylene having a density of not more than 0.93 g/m^{2.}

The lower side temperature of a die at the time of extrusion of the low density polyethylene is preferably 295” C or below.

Further, according to another embodiment of the present invention, the polyolefin resin is preferably medium density polyethylene. Here “medium density polyethylene, refers to polyethylene having a density of 0.93 to 0.94 g/m².

According to a further embodiment of the present inventions preferably, the resin layer has a two-layer structure of a first resin layer and a second resin layer provided in that order from the transparent sheet side in the stacked state and the first resin layer is composed mainly of an acrylic resin.

In the above embodiment, the second resin layer is preferably an adhesive layer. According to another embodiment of the present invention, the second resin layer is preferably formed of a polyolefin resin.

According to still another embodiment of the present invention, the resin layer may have a three-layer structure of a first resin layer, a second resin layer, and a third resin layer provided in that order.

According to a preferred embodiment of the present invention, the transparent sheet portion including the receptive layer may have been subjected to half cutting.

The above embodiment includes a construction such that the transparent sheet including the receptive layer in its half cut portion, on which no image is to be formed, has been previously removed.

The present invention includes a printing method comprising the step of printing an image in an area larger than a patch portion as an image forming portion.

The following examples and comparative examples further illustrate the present invention. In the following description, “parts” or “%” is by mass.

### EXAMPLE A1

A receptive layer having the following composition was provided on a 25 μm-thick polyethylene terephthalate film (Lumirror, manufactured by Toray Industries, Inc.) as a transparent sheet to a thickness of 4 μm on a dry basis. Separately, a 38 μm-thick polyethylene terephthalate film (Lumirror, manufactured by Toray Industries, Inc.) was provided as a sheet substrate. A resin layer having the following composition was provided on the sheet substrate to a thickness of 3 μm on a dry basis. The sheet substrate with the resin layer formed thereon was dry laminated onto the transparent sheet with the receptive layer formed thereon so that the resin layer faced the transparent sheet on its side remote from the receptive layer.

Further, in the laminate thus obtained, as shown in FIG. 6, the transparent sheet portion including the receptive layer was cut by pressing an upper die 12, provided with a cutter blade 14, and a pedestal 13 against the transparent sheet portion including the receptive layer and the refuse of the transparent sheet provided with the receptive layer was continuously removed by means of a separation roll 15 in such a state that a region 7, to be transferred onto an object, in its outer peripheral portion (8) was connected to a connection 9. The refuse was wound by means of a refuse removal roll 16.

Thus, a continuously wound intermediate transfer recording medium of Example A1 was provided. This intermediate transfer recording medium was separable in its portion between the resin layer and the transparent sheet.

[Composition of coating liquid for receptive layer]

| | | |
|---|---|---|
| Vinyl chloride-vinyl acetate copolymer | 100 | parts |
| (VYHD, manufactured by Union | | |
| Carbide Corporation) | | |
| Epoxy-modified silicone (KF-393, | 8 | parts |
| manufactured by The Shin-Etsu | | |
| Chemical Co., Ltd.) | | |
| Amino-modified silicone (KS-343, | 8 | parts |
| manufactured by The Shin-Etsu | | |
| Chemical Co., Ltd.) | | |
| Methyl ethyl ketone/toluene | 400 | parts |
| (mass ratio = 1/1) | | |

[Composition of coating liquid for resin layer] (easy-adhesion
adhesive layer type)

| | | |
|---|---|---|
| NBR resin (Nipol SX 1503, | 30 | parts |
| manufactured by Nippon Zeon Co.) | | |
| Carnauba wax (WE 188, manufactured | 0.6 | part |
| by Konishi Co., Ltd.) | | |
| Water | 35 | parts |
| Isopropyl alcohol | 35 | parts |

### EXAMPLE A2

An intermediate transfer recording medium of Example A2 was provided in the same manner as in Example A1, except that the composition of the coating liquid for a resin layer used in Example Al was changed as follows.

[Composition of coating liquid for resin layer] (easy-adhesion
adhesive layer type)

| | | |
|---|---|---|
| Acrylic resin latex (LX 874, | 30 | parts |
| manufactured by Nippon Zeon Co., Ltd.) | | |
| Water | 35 | parts |
| Isopropyl alcohol | 35 | parts |

### EXAMPLE A3

A receptive layer was provide on a transparent sheet in the same manner as in Example Al. Separately, a 38 m-thick polyethylene terephthalate film (Lumirror, manufactured by Toray Industries, Inc.) was provided as a sheet substrate. A resin of low density polyethylene (LDPE) with 15% of titanium oxide being dispersed therein was extrusion coated on the sheet substrate to a thickness of 40 μm. Simultaneously with the extrusion, the transparent sheet with the receptive layer formed thereon was EC laminated onto the sheet substrate with the resin layer formed thereon so that the transparent sheet on its side remote from the receptive layer faced the LDPE layer provided on the sheet substrate.

Further, in the laminate thus obtained, as shown in FIG. 6, the transparent sheet portion including the receptive layer was cut by pressing an upper die 12, provided with a cutter blade 14, and a pedestal 13 against the transparent sheet portion including the receptive layer and the refuse of the transparent sheet provided with the receptive layer was continuously removed by means of a separation roll 15 in such a state that a region 7, to be transferred onto an object, in its outer peripheral portion (8) was connected to a connection 9. The refuse was wound by means of a refuse removal roll 16. Thus, a continuously wound intermediate transfer recording medium of Example A3 was provided. This intermediate transfer recording medium was separable in its portion between the resin layer and the transparent sheet.

### COMPARATIVE EXAMPLE A1

A peel layer having the following composition was formed on a 25 μm-thick polyethylene terephthalate film (Lumirror, manufactured by Toray Industries, Inc.) to a thickness of 1 μm on a dry basis. The coating liquid for a receptive layer used in Example A1 was coated onto the peel layer to form a receptive layer having a thickness of 3 μm on a dry basis. Further, an adhesive layer having the following composition 1 was formed on the receptive layer to a thickness of 3 μm on a dry basis. Thus, a receptive layer transfer sheet was provided.

Separately, the coating liquid for a peel layer used in the preparation of the receptive layer transfer sheet was coated on a 25 μm-thick polyethylene terephthalate film (Lumirror, manufactured by Toray Industries, Inc.) to form a peel layer having a thickness of 1 μm on a dry basis. A protective layer having the following composition was formed on the peel layer to a thickness of 3 μm on a dry basis. Further, an adhesive layer having the following composition 2 was formed on the protective layer to a thickness of 3 μm on a dry basis. Thus, a protective layer transfer sheet was provided.

[Composition of coating liquid for peel layer]

| | | |
|---|---|---|
| Polyvinyl alcohol resin (AH-17, | 100 | parts |
| manufactured by Nippon Synthetic | | |
| Chemical Industry Co., Ltd.) | | |
| Water | 400 | parts |

[Composition of coating liquid 1 for adhesive layer]

| | | |
|---|---|---|
| Polymethyl methacrylate resin (BR-106, | 100 | parts |
| manufactured by Mitsubishi Rayon Co., | | |
| Ltd.) | | |
| Foaming agent (F-50, manufactured by | 15 | parts |
| Matsumoto Yushi Seiyaku Co., Ltd.) | | |
| Titanium oxide (TCA-888, manufactured | 100 | parts |
| by Tohchem Products Corporation) | | |
| Methyl ethyl ketone/toluene | 300 | parts |
| (mass ratio = 1/1) | | |

[Composition of coating liquid for protective layer]

| | | |
|---|---|---|
| Vinyl chloride-vinyl acetate copolymer | 100 | parts |
| (VYHD, manufactured by Union Carbide | | |
| Corporation) | | |
| Methyl ethyl ketone/toluene | 400 | parts |
| (mass ratio = 1/1) | | |

[Composition of coating liquid 2 for adhesive layer]

| | | |
|---|---|---|
| Acrylic resin (BR-106, manufactured | 100 | parts |
| by Mitsubishi Rayon Co., Ltd.) | | |
| Methyl ethyl ketone/toluene | 300 | parts |
| (mass ratio = 1/1) | | |

An image was formed on the receptive layer in the samples provided in the examples and the comparative examples under the following conditions. For the sample provided in Comparative Example A1, a protective layer was further stacked on the image-receptive layer.

A thermal transfer sheet (manufactured by Dai Nippon Printing Co., Ltd.), wherein three color transfer layers for yellow, magenta, and cyan as dye layers had been provided in a face serial manner, and each of the intermediate transfer recording media provided in the respective examples were put on top of the other so that each color transfer layer faced the receptive layer. Recording was then carried out by a thermal head of a thermal transfer printer from the backside of the thermal transfer sheet under conditions of head application voltage 12.0 V, pulse width 16 msec, printing cycle 33.3 msec, and dot density 6 dots/line. Thus, a full-color photograph-like image (a mirror image) of a face was formed on the receptive layer in the intermediate transfer recording medium.

In the samples of the examples, the intermediate transfer recording medium was put on top of a PET card as an object so that the receptive layer with the image formed thereon in the intermediate transfer recording medium faced the PET card. A thermal head and a platen roll were pressed against the assembly, and energy was applied to a region 7, to be transferred onto an object, under conditions of 160 mJ/mm² and printing speed 33.3 msec/line (feed pitch 6 lines/m) to adhere the image-receptive layer to the object. The sheet substrate was then separated. Thus, only the region 7 could be re-transferred onto the object to form an image.

For the samples provided in the examples, the print thus obtained were such that the transparent sheet covered the surface of the image forming portion and thus functioned as an even firm protective layer, whereby fastness properties could be fully imparted to the image. Further, since the transparent sheet portion was previously cut in the half cut inside portion, the protective layer could be simply transferred onto the object for each image with high accuracy. By virtue of this, prints thus obtained had excellent design and fastness properties.

In the sample provided in Comparative Example A1, a PET card as an object and the receptive layer transfer sheet were put on top of each other, and the receptive layer was transferred onto the PET card by means of a thermal head. Next, the thermal transfer sheet as used in the recording of the intermediate transfer recording medium was put on top of the surface of the receptive layer, and a full-color photograph-like image (non-reverse image) of a face was formed on the receptive layer by means of a thermal head under conditions of head application voltage 12.0 V, pulse width 16 msec, printing cycles 33.3 msec, and dot density 6 dots/line.

Further, a protective layer was transferred from the protective layer transfer sheet onto the image forming portion through the application of energy by means of the thermal head.

Next, the samples prepared in the examples and the comparative example were tested for Taber abrasion under conditions of CS-10 as a truck wheel, load on image 500 g, and 1400 cycles. The results were as follows.

In the test, the image was visually inspected for whether or not the abrasion resulted in the disappearance of the image.

TABLE A1

| | Taber abrasion test |
|---|---|
| Ex. 1 | OK (Image did not disappear) |
| Ex. 2 | OK (Image did not disappear) |
| Ex. 3 | OK (Image did not disappear) |
| Comp. Ex. 1 | NG (Image disappeared) |

As described above, the intermediate transfer recording medium according to the present invention comprises a sheet substrate provided with a resin layer and a transparent sheet provided with a receptive layer, the transparent sheet provided with the receptive layer having been put on top of the sheet substrate provided with the resin layer so that the resin layer faces the transparent sheet on its side remote from the receptive layer, the resin layer being separable from the transparent sheet at the time of transfer to transfer the transparent sheet provided with a receptive layer onto an object, the transparent sheet portion including the receptive layer having been half cut in a specific form. In this case, the half cutting may be carried out by removing the transparent sheet provided with the receptive layer in a predetermined width around the outer periphery of the region to be transferred onto the object.

The intermediate transfer recording medium is used to form a transfer image in the receptive layer, and the image formed portion is re-transferred onto an object to form an image. In this case, since the transparent sheet provided with the receptive layer has been partially removed from the end of the region, to be transferred onto the object, toward the outside, an unnecessary portion is not transferred onto the object. Further, there is no possibility that, in the intermediate transfer recording medium, a pressure-sensitive adhesive is exposed leading to blocking or the like.

Therefore, the resultant print is such that the transparent sheet covers the surface of the image formed portion and thus functions as an even firm protective layer. Thus, fastness properties can be fully imparted to images. Further, since the transparent sheet portion is previously cut in the half cut inside portion, the protective layer can be simply transferred onto the object for each image with high accuracy. By virtue of this, prints thus obtained have excellent design and fastness properties.

A receptive layer having the following composition was provided on a 25 μm-thick polyethylene terephthalate film (Lumirror, manufactured by Toray Industries, Inc.) as a transparent sheet at a coverage of 3 g/m² on a dry basis. Next, a 25 μm-thick polyethylene terephthalate film (Lumirror, manufactured by Toray Industries, Inc.) was provided as a sheet substrate. A resin layer having the following composition was provided on the sheet substrate at a coverage of 1 g/m² on a dry basis. The sheet substrate with the resin layer formed thereon was dry laminated onto the transparent sheet with the receptive layer formed thereon so that the resin layer faced the transparent sheet on its side remote from the receptive layer.

Further, in the laminate thus obtained, as shown in FIG. 8, the transparent sheet portion including the receptive layer was half cut, and the transparent sheet, provided with the receptive layer, in its portion around the region to be transferred onto an object was torn off. Thus, a continuously wound intermediate transfer recording medium of Example B1 was prepared.

[Composition of coating liquid for receptive layer]

| | | |
|---|---|---|
| Vinyl chloride-vinyl acetate copolymer | 100 | parts |
| (#1000A, manufactured by Denki Kagaku | | |
| Kogyo K.K.) | | |
| Epoxy-modified silicone (KF-393, | 5 | parts |
| manufactured by The Shin-Etsu Chemical | | |
| Co., Ltd.) | | |
| Amino-modified silicone (KF-343, | 5 | parts |
| manufactured by The Shin-Etsu Chemical | | |
| Co, Ltd..) | | |
| Methyl ethyl ketone/toluene | 400 | parts |
| (mass ratio = 1/1) | | |

[Composition of coating liquid for resin layer]

| | | |
|---|---|---|
| Addition polymerization-type (hydrosilylation-type) | 100 | parts |
| silicone pressure-sensitive adhesive | | |
| (X-40-3102, manufactured by The Shin-Etsu | | |
| Chemical Co, Ltd.) | | |
| Catalyst (CAT-PL-50T, manufactured by | 0.5 | part |
| The Shin-Etsu Chemical Co., Ltd.) | | |
| Methyl ethyl ketone/toluene | 400 | parts |
| (mass ratio = 1/1) | | |

### EXAMPLE B1-1

An intermediate transfer recording medium of Example B1-1 was prepared in the same manner as in Example B1, except that the coating liquid for the receptive layer and the coating liquid for the resin layer used in Example B1 were changed respectively to coating liquids having the following compositions.

[Composition of coating liquid for receptive layer]

| | | |
|---|---|---|
| Polyester resin (MD-1500, | 100 | parts |
| manufactured by Toyobo Co., Ltd.) | | |
| Teflon filler (Ruburon L5, average | 1.5 | parts |
| particle diameter 7 μm, manufactured | | |
| by Daikin Industries, Ltd.) | | |
| Water/isopropyl alcohol | 200 | parts |
| (mass ratio = 1/1) | | |

[Composition of coating liquid for resin layer]

| | | |
|---|---|---|
| Addition polymerization-type | 100 | parts |
| (hydrosilylation-type) silicone | | |
| pressure-sensitive adhesive (X-40-3102, | | |
| manufactured by The Shin-Etsu Chemical | | |
| Co., Ltd.) | | |
| Catalyst (CAT-PL-50T, manufactured | 0.5 | part |
| by The Shin-Etsu Chemical Co., Ltd.) | | |
| Methyl ethyl ketone/toluene | 400 | parts |
| (mass ratio = 1/1) | | |

### EXAMPLE 2

An intermediate transfer recording medium of Example B2 was prepared in the same manner as in Example B1, except that the coating liquid for the resin layer used in Example B1 was changed to a coating liquid having the following composition.

[Composition of coating liquid for resin layer]

| | | |
|---|---|---|
| Addition polymerization-type | 100 | parts |
| (hydrosilylation-type) silicone | | |
| pressure-sensitive adhesive (X-40-3103, | | |
| manufactured by The Shin-Etsu Chemical | | |
| Co., Ltd.) | | |
| Microsilica (Snowtex MEK-ST, manufactured | 100 | parts |
| by Nissan Chemical Industries Ltd.) | | |
| Catalyst (CAT-PL-50T, manufactured by | 0.5 | part |
| The Shin-Etsu Chemical Co., Ltd.) | | |
| Methyl ethyl ketone/toluene | 700 | parts |
| (mass ratio = 1/1) | | |

### EXAMPLE B3

An intermediate transfer recording medium of Example B3 was prepared in the same manner as in Example B1, except that the coating liquid for the resin layer used in Example B1 was changed to a coating liquid having the following composition.

[Composition of coating liquid for resin layer]

| | | |
|---|---|---|
| Addition polymerization-type | 75 | parts |
| (hydrosilylation-type) silicone | | |
| pressure-sensitive adhesive (X-40-3102, | | |
| manufactured by The Shin-Etsu Chemical | | |
| Co., Ltd.) | | |
| Addition polymerization-type | 25 | parts |
| (hydrosilylation-type) silicone | | |
| pressure-sensitive adhesive (X-40-3103, | | |
| manufactured by The Shin-Etsu Chemical | | |
| Co., Ltd.) | | |
| Catalyst (CAT-PL-50T, manufactured | 0.5 | part |
| by The Shin-Etsu Chemical Co., Ltd.) | | |
| Methyl ethyl ketone/toluene | 400 | parts |
| (mass ratio = 1/1) | | |

### EXAMPLE 4

An intermediate transfer recording medium of Example B4 was prepared in the same manner as in Example B1, except that the coating liquid for the resin layer used in Example B1 was changed to a coating liquid having the following composition.

[Composition of coating liquid for resin layer]

| | | |
|---|---|---|
| Addition polymerization-type | 50 | parts |
| (hydrosilylation-type) silicone | | |
| pressure-sensitive adhesive (X-40-3102, | | |
| manufactured by The Shin-Etsu Chemical | | |
| Co., Ltd.) | | |
| Addition polymerization-type | 50 | parts |
| (hydrosilylation-type) silicone | | |
| pressure-sensitive adhesive (X-40-3103, | | |
| manufactured by The Shin-Etsu Chemical | | |
| Co., Ltd.) | | |
| Microsilica (Snowtex MEK-ST, manufactured | 30 | parts |
| by Nissan Chemical Industries Ltd.) | | |
| Catalyst (CAT-PL-50T, manufactured by | 0.5 | part |
| The Shin-Etsu Chemical Co., Ltd.) | | |
| Methyl ethyl ketone/toluene | 400 | parts |
| (mass ratio = 1/1) | | |

### EXAMPLE B5

An intermediate transfer recording medium of Example B5 was prepared in the same manner as in Example B1, except that, in the intermediate transfer recording medium prepared in Example B1, a release layer was provided on the transparent sheet in its side remote from the receptive layer by coating a coating liquid having the following composition at a coverage of 0.1 g/m² on a dry basis.

[Composition of coating liquid for release layer]

| | | |
|---|---|---|
| Release agent (X-70-201, manufactured | 100 | parts |
| by The Shin-Etsu Chemical Co., Ltd.) | | |
| Catalyst (CAT-PL-50T, manufactured | 0.5 | part |
| by The Shin-Etsu Chemical Co., Ltd.) | | |
| Solvent (FR Thinner, manufactured | 400 | parts |
| by The Shin-Etsu Chemical Co., Ltd.) | | |

### COMPARATIVE EXAMPLE B1

An intermediate transfer recording medium of Comparative Example B1 was prepared in the same manner as in Example B1, except that the coating liquid for the resin layer used in Example B1 was changed to a coating liquid having the following composition and the lamination was carried out at 60° C.

[Composition of coating liquid for resin layer]

| | | |
|---|---|---|
| NBR resin (Nipol SX-1503, | 30 | parts |
| manufactured by Nippon Zeon Co.) | | |
| Carnauba wax (WE 188, manufactured | 0.6 | part |
| by Konishi Co., Ltd.) | | |
| Water | 35 | parts |
| Isopropyl alcohol | 35 | parts |

### COMPARATIVE EXAMPLE B2

An intermediate transfer recording medium of Comparative Example B2 was prepared in the same manner as in Example B1, except that the coating liquid for the resin layer used in Example B1 was changed to a coating liquid having the following composition and the lamination was carried out at 60° C.

[Composition of coating liquid for resin layer]

| | | |
|---|---|---|
| Acrylic resin latex (NIPOL LX-874, | 30 | parts |
| manufactured by Nippon Zeon Co., Ltd.) | | |
| Water | 35 | parts |
| Isopropyl alcohol | 35 | parts |

### COMPARATIVE EXAMPLE B3

An intermediate transfer recording medium of Comparative Example B3 was prepared in the same manner as in Example B1, except that the coating liquid for the resin layer used in Example B1 was changed to a coating liquid having the following composition and the lamination was carried out at 60” C.

[Composition of coating liquid for resin layer]

| | | |
|---|---|---|
| Acrylic pressure-sensitive adhesive | 100 | parts |
| (SI( Dyne SK-1473, manufactured by | | |
| Soken Chemical Engineering Co., Ltd.) | | |
| Catalyst (M-5A, manufactured by Soken | 6 | parts |
| Chemical Engineering Co., Ltd.) | | |
| Toluene/ethyl acetate | 400 | parts |
| (mass ratio = 1/1) | | |

### COMPARATIVE EXAMPLE B4

An intermediate transfer recording medium of Comparative Example B4 was prepared in the same manner as in Example B1, except that the coating liquid for the resin layer used in Example B1 was changed to a coating liquid having the following composition.

[Composition of coating liquid for resin layer]

| | | |
|---|---|---|
| Acrylic pressure-sensitive adhesive | 100 | parts |
| (SK Dyne SK-1495, manufactured by | | |
| Soken Chemical Engineering Co., Ltd.) | | |
| Curing agent (L-45, manufactured by | 0.2 | part |
| Soken Chemical Engineering Co., Ltd.) | | |
| Toluene/ethyl acetate | 400 | parts |
| (mass ratio = 1/1) | | |

### COMPARATIVE EXAMPLE B5

An intermediate transfer recording medium of Comparative Example B5 was prepared in the same manner as in Example B1, except that the coating liquid for the resin layer used in Example B1 was changed to a coating liquid having the following composition and the lamination was carried out at 100° C.

[Composition of coating liquid for resin layer]

| | |
|---|---|
| Polyester resin (Resem ES-1H, manufactured | 100 parts |
| by Chukyo Yushi Co., Ltd.) | |
| Water | 200 parts |

The samples prepared in the above examples and comparative examples were evaluated for the following items.

(Evaluation Method)

(Peel Force)

Peel force between the resin layer and the transparent sheet was measured with Tensilon (load cell: 1 kg, load cell speed 100 mm/min) under conditions of sample width 1 inch and 180-degree peeling. Conditions other than described above were the same as those specified in JIS Z 0237.

(Peel Force After Storage)

The samples were stored in a 60° C./humidity free environment for 48 hr to examine a change in peel force with the elapse of time. The peel force was measured under the conditions as described above.

(Releasability)

A thermal transfer sheet (manufactured by Dai Nippon Printing Co., Ltd.), wherein three color transfer layers for yellow, magenta, and cyan as dye layers had been provided in a face serial manner, and the resin layer portion obtained by removing the transparent sheet provided with the receptive layer from each of the intermediate transfer recording media prepared in the above examples and comparative examples were put on top of each other so that the color transfer layer faced the resin layer. Recording was then carried out by a thermal head of a thermal transfer printer from the backside of the thermal transfer sheet under conditions of application voltage 12.0 V, pulse width 16 msec, printing cycle 33.3 msec, and dot density 6 dots/line to examine the releasability of the resin layer from the thermal transfer sheet.

For the intermediate transfer recording medium prepared in Example B1-1, the following thermal ink-type thermal transfer sheet for image formation was used to form an image.

Specifically, a 6 μm-thick polyethylene terephthalate film (Lumirror, manufactured by Toray Industries, Inc.) was provided as a substrate film, and a release layer, a peel layer, and a hot-melt black ink layer were formed in that order on the substrate film to form a thermal transfer sheet, In this thermal transfer sheet, a sublimable dye layer was not provided.

An ink prepared according to the following formulation was coated on the substrate film at a coverage of 0.2 g/m² on a solid basis, and the coating was dried to form a release layer.

[Composition of coating liquid for release layer]

| | | |
|---|---|---|
| Urethane resin (Crisvon 9004, manufactured | 20 | parts |
| by DIC) | | |
| Polyvinyl acetoacetal resin (KS-5, | 5 | parts |
| manufactured by Sekisui Chemical Co., | | |
| Ltd.) | | |
| Brightening agent (Uvitex OB, manufactured | 0.5 | part |
| by Ciba-Geiby Ltd.) | | |
| Dimethylfomalumide | 80 | parts |
| Methyl ethyl ketone | 120 | parts |

An ink prepared according to the following formulation was coated on the release layer at a coverage of 1 g/m² on a solid basis, and the coating was dried to form a peel layer.

[Composition of coating liquid for peel layer]

| | | |
|---|---|---|
| Vinyl chloride-vinyl acetate copolymer | 20 | parts |
| resin (1000 ALK, manufactured by Denki | | |
| Kagaku Kogyo K.K.) | | |
| Epoxy-modified silicone (KP 1800-U, | 1 | part |
| manufactured by The Shin-Etsu Chemical | | |
| Co, Ltd.) | | |
| Methyl ethyl ketone/toluene | 80 | parts |
| (mass ratio = 1/1) | | |

An ink prepared according to the following formulation was coated on the peel layer at a coverage of 1 g/m² on a solid basis, and the coating was dried to form a hot-melt ink layer.

[Composition of coating liquid for hot-melt ink layer]

| | |
|---|---|
| Acryl-vinyl chloride-vinyl acetate | 20 parts |
| copolymer resin | |
| Carbon black | 10 parts |
| Methyl ethyl ketone/toluene | 70 parts |
| (mass ratio = 1/1) | |

A thermal transfer sheet for yellow, a thermal transfer sheet for magenta, and a thermal transfer sheet for cyan were prepared in the same manner as described just above, except that pigments PY-180, PR-57:1, and PB-15:4 were used instead of carbon black. The thermal transfer sheets thus obtained were used to record images and characters in the receptive layer on the transparent sheet from the backside of the thermal transfer sheets by means of a thermal transfer printer (SMAPRO 560 D, manufactured by Alps Electric Co., Ltd.) under conditions of application voltage 12.0 V (thermal head resistance value 4412 Ω), pulse width 6.8 msec, printing cycle 8 msec, and dot density 12 dots/line to evaluate the releasability of the resin layer (receptive layer) from the thermal transfer sheet.

The releasability was visually evaluated according to the following criteria.

∘: The thermal transfer sheet was separated from the resin layer (receptive layer) without any trouble.

×: The thermal transfer sheet could not be separated from and was stuck to the resin layer (receptive layer).

(Peeling Noise)

A thermal transfer sheet (manufactured by Dai Nippon Printing Co., Ltd.), wherein three color transfer layers for yellow, magenta, and cyan as dye layers had been provided in a face serial manner, and each of the intermediate transfer recording media prepared in the above examples and comparative examples were put on top of each other so that the color transfer layer faced the receptive layer. Recording was then carried out by a thermal head of a thermal transfer printer from the backside of the thermal transfer sheet under conditions of application voltage 12.0 V, pulse width 16 msec, printing cycle 33.3 msec, and dot density 6 dots/line. Thereafter, a vinyl chloride card was put on top of the intermediate transfer recording medium so that the vinyl chloride card faced the image recorded face, followed by the transfer of the transparent sheet provided with the receptive layer onto the card from the backside of the intermediate transfer recording medium under conditions of temperature 130° C., speed 1 m/min, and pressure 3 kg/line to examine the peeling noise generated at the time of the separation of the transparent sheet from the substrate sheet. For the intermediate transfer recording medium prepared in Example B1-1, the above procedure was repeated, except that the thermal ink-type thermal transfer sheet was used to perform recording under printing conditions as used in the evaluation of the releasability.

In the evaluation of the peeling noise, whether or not noise was generated was examined through hearing by an evaluator.

∘: The transparent sheet could be smoothly separated from the substrate sheet without causing peeling noise.

×: At the time of the separation of the transparent sheet from the substrate sheet, harsh grating peeling noise occurred.

(Overall Evaluation)

The properties of the intermediate transfer recording media were evaluated overall based on the results of evaluations of peel force, peel force after storage, releasability, and peeling noise.

The criteria for the overall evaluation were as follows.

∘: The peel force was 0.01 to 0.5 N/inch, the peel force after the storage was reduced or increased by not more than about 10% as compared with the peel force before the storage, and the results of evaluations of releasability and peeling noise were good.

×: The releasability was poor, the peeling noise occurred, the peel force was outside the range of 0.01 to 0.5 N/inch, or the peel force after storage was increased or reduced by not less than 20% as compared with the peel force before storage, that is, was poor.

The results of evaluations are shown in the following table.

TABLE B1

| | Peel | Peel force | | | |
|---|---|---|---|---|---|
| | force, | after storage, | Releas- | Peeling | Overall |
| | N/inch | N/inch | ability | noise | evaluation |
| Ex. B1 | 0.05 | 0.05 | ◯ | ◯ | ◯ |
| Ex. B1-1 | 0.05 | 0.05 | ◯ | ◯ | ◯ |
| Ex. B2 | 0.25 | 0.25 | ◯ | ◯ | ◯ |
| Ex. B3 | 0.10 | 0.09 | ◯ | ◯ | ◯ |
| Ex. B4 | 0.18 | 0.20 | ◯ | ◯ | ◯ |
| Ex. B5 | 0.04 | 0.04 | ◯ | ◯ | ◯ |
| Comp. Ex. B1 | 0.18 | 0.36 | × | × | × |
| Comp. Ex. B2 | 0.47 | 2.31 | × | × | × |
| Comp. Ex. B3 | 0.35 | 1.13 | × | × | × |
| Comp. Ex. B4 | 0.10 | 0.55 | × | × | × |
| Comp. Ex. B5 | 1.80 | 1.85 | × | ◯*¹ | × |

*¹:Although peeling noise did not occur, crease took place in the transparent sheet on the object.

As described above, in the intermediate transfer recording medium according to the present invention comprising: a sheet substrate provided with a resin layer; and a transparent sheet provided with a receptive layer, the transparent sheet provided with the receptive layer having been put on top of the sheet substrate provided with the resin layer so that the resin layer faces the transparent sheet on its side remote from the receptive layer, the resin layer being separable from the transparent sheet to transfer the transparent sheet provided with the receptive layer onto an object, the use of a hydrosilylation-type silicone pressure-sensitive adhesive in the resin layer can complete the curing reaction of the resin layer at a low temperature in a short time and can eliminate the change in peel force between the resin layer and the transparent sheet with the elapse of time.

Further, since the hydrosilylation-type silicone pressure-sensitive adhesive is used, the peel force between the resin layer and the transparent sheet is not greatly influenced by heating (100 to 200° C.) at the time of transfer of the transparent sheet provided with the receptive layer onto an object.

In forming an image on the intermediate transfer recording medium, even when the resin layer has come into contact with the thermal transfer sheet due to the movement of the image forming position, there is no fear of the resin being fused to the thermal transfer sheet. That is, good releasability from the thermal transfer sheet can be realized.

Further, in the intermediate transfer recording medium according to the present invention, the curing reaction of the hydrosilylation-type silicone pressure-sensitive adhesive used in the resin layer can be completed at a low temperature in a short time, and, thus, the productivity of the intermediate transfer recording medium can be enhanced.

When the intermediate transfer recording medium according to the present invention is used, the transparent sheet covers the surface of the image formed portion in the object and can function as an even firm protective layer. Thus, fastness properties can be fully imparted to the image.

### EXAMPLE C1

The following coating liquid for a hologram layer was first coated on a 25 μ-thick polyethylene terephthalate film (Lumirror, manufactured by Toray Industries, Inc.) as a transparent sheet, and the coating was dried to form a hologram layer at a coverage of 2.0 g/m² on a dry basis. A hologram pattern was formed in the hologram layer by forming fine concaves and convexes by embossing using an original plate having a concave-convex pattern of interference fringes of a hologram.

(Coating liquid for hologram layer)

| | |
|---|---|
| Acrylic resin | 40 parts |
| Melamine resin | 10 parts |
| Cyclohexane | 50 parts |
| Methyl ethyl ketone | 50 parts |

Further, a 500 angstrom-thick titanium oxide layer was formed as a transparent deposit by vacuum deposition on the hologram layer with the hologram pattern formed thereon. Thus, a hologram formation layer composed of the hologram layer and the transparent deposit was formed. The following coating liquid for a receptive layer was coated on the hologram formation layer, and the coating was dried to form a receptive layer at a coverage of 3.0 g/m² on a dry basis.

(Coating liquid for receptive layer)

| | |
|---|---|
| Vinyl chloride-vinyl acetate copolymer | 40 parts |
| Acrylic silicone | 1.5 parts |
| Methyl ethyl ketone | 50 parts |
| Toluene | 50 parts |

Next, a 38 μm-thick polyethylene terephthalate film (Lumirror, manufactured by Toray Industries, Inc.) was provided as a sheet substrate. Register marks were formed on the sheet substrate at its positions as shown in FIG. 11 by gravure printing a register mark ink having the following composition at a coverage of 3 g/m² on a dry basis.

(Register mark ink)

| | |
|---|---|
| Carbon black | 8.0 parts |
| Urethane resin (HMS-20, manufactured | 5.0 parts |
| by Nippon Polyurethane Industry Co., | |
| Ltd.) | |
| Methyl ethyl ketone | 38.5 parts |
| Toluene | 38.5 parts |

The transparent sheet provided with the hologram formation layer and the receptive layer was then dry laminated onto the sheet substrate provided with the register marks so that the transparent sheet on its side remote from the receptive layer faced the sheet substrate on its side having the register marks through a resin layer having the following composition (coverage 3 g/m² on a dry basis) (see FIG. 11D). Further, in the laminate thus obtained, as shown in FIG. 11D, the transparent sheet 32 portion including the receptive layer 33 was subjected to half cutting 37 by pressing an upper die 44 provided with a cutter blade 46 and a pedestal 45 against the transparent sheet 32 portion including the receptive layer 33. Thus, a continuously wound intermediate transfer recording medium of Example C1 was prepared. The resin layer was separable from the transparent sheet.

(Coating liquid for resin layer) (Easy-adhesion adhesive layer
type)

| | |
|---|---|
| Acrylic resin latex (LX 874, | 30 parts |
| manufactured by Nippon Zeon Co.) | |
| Water | 35 parts |
| Isopropy) alcohol | 35 parts |

### EXAMPLE C2

A hologram formation layer and a receptive layer were provided on a transparent sheet in the same manner as in Example C1. Separately, a 38 μm-thick polyethylene terephthalate film (Lumirror, manufactured by Toray Industries, Inc.) was provided as a sheet substrate. A resin of low density polyethylene (LDPE) with 15% of titanium oxide being dispersed therein was extrusion coated on the sheet substrate to a thickness of 40 μm. Simultaneously with the extrusion, the transparent sheet with the receptive layer formed thereon was EC laminated onto the sheet substrate with the resin layer formed thereon so that the transparent sheet on its side remote from the receptive layer faced the LDPE layer provided on the sheet substrate. In this case, however, as shown in FIG. 11D, register marks were previously printed by the register mark ink as used in Example C1 in the same manner as in Example C1 on the sheet substrate in its side where the LDPE layer was to be formed.

Further, in the laminate thus obtained, as shown in FIG. 11, the transparent sheet portion including the receptive layer was half cut by pressing an upper die provided with a cutter blade and a pedestal against the transparent sheet portion including the receptive layer. In addition, the whole portion except for the image forming portion was separated using the half cut as the boundary between the removal portion and the image forming portion remaining unremoved. Thus, a continuously wound intermediate transfer recording medium of Example C2 was prepared This intermediate transfer recording medium was separable in its portion between the resin layer and the transparent sheet.

### COMPARATIVE EXAMPLE C1

A peel layer having the following composition was formed on a 25 μm-thick polyethylene terephthalate film (Lumirror, manufactured by Toray Industries, Inc.) at a coverage of 1 g/m² on a dry basis. The coating liquid for a receptive layer used in Example C1 was coated onto the peel layer to form a receptive layer at a coverage of 3 g/m² on a dry basis. Further, an adhesive layer having the following composition 1 was formed on the receptive layer at a coverage of 3 g/m² on a dry basis. Thus, a receptive layer transfer sheet was prepared. Separately, the coating liquid for a peel layer used in the preparation of the receptive layer transfer sheet was coated on a 25 μm-thick polyethylene terephthalate film (Lumirror, manufactured by Toray Industries, Inc.) to form a peel layer at a coverage of 1 g/m² on a dry basis. A protective layer having the following composition was formed on the peel layer at a coverage of 3 g/m² on a dry basis. An adhesive layer having the following composition 2 was then formed on the protective layer at a coverage of 3 g/m² on a dry basis. Thus, a protective layer transfer sheet was provided.

[Composition of coating liquid for peel layer]

| | |
|---|---|
| Polyvinyl alcohol resin (AH-17, | 100 parts |
| manufactured by Nippon Synthetic | |
| Chemical Industry Co., Ltd.) | |
| Water | 400 parts |

[Composition of coating liquid 1 for adhesive layer]

| | |
|---|---|
| Polymethyl methacrylate resin (BR-106, | 100 parts |
| manufactured by Mitsubishi Rayon Co., | |
| Ltd.) | |
| Foaming agent (F-50, manufactured by | 15 parts |
| Matsumoto Yushi Seiyaku Co., Ltd.) | |
| Titanium oxide (TCA-888, manufactured | 100 parts |
| by Tohchem Products Corporation) | |
| Methyl ethyl ketone/toluene | 300 parts |
| (mass ratio = 1/1) | |

[Composition of coating liquid for protective layer]

| | |
|---|---|
| Vinyl chloride-vinyl acetate copolymer | 100 parts |
| (VYHD, manufactured by Union carbide | |
| Corporation) | |
| Methyl ethyl ketone/toluene | 400 parts |
| (mass ratio = 1/1) | |

[Composition of coating liquid 2 for adhesive layer]

| | |
|---|---|
| Acrylic resin (BR-106, manufactured | 100 parts |
| by Mitsubishi Rayon Co., Ltd.) | |
| Methyl ethyl ketone/toluene | 300 parts |
| (mass ratio = 1/1) | |

An image was formed on the receptive layer in the samples provided in the examples and the comparative examples under the following conditions For the sample provided in Comparative Example C1, a protective layer was further stacked on the image-receptive layer. A thermal transfer sheet (manufactured by Dai Nippon Printing Co., Ltd.), wherein three color transfer layers for yellow, magenta, and cyan as dye layers had been provided in a face serial manner, and each of the intermediate transfer recording media provided in the respective examples were put on top of each other so that each color transfer layer faced the receptive layer. Recording was then carried out by a thermal head of a thermal transfer printer from the backside of the thermal transfer sheet under conditions of head application voltage 12.0 V, pulse width 16 msec, printing cycle 33.3 msec, and dot density 6 dots/line. Thus, a full-color photograph-like image (a mirror image) of a face was formed on the receptive layer in the intermediate transfer recording medium.

Next, the intermediate transfer recording medium was put on top of a 600 μm-thick white PET-G sheet (Diafix PG-W, PET-G, manufactured by Mitsubishi Plastic Industries Ltd.) as an object so that the receptive layer with the image formed thereon faced the PET-G sheet. A thermal head and a platen roll were pressed against the assembly, and energy was applied to the image formed portion under conditions of 160 mJ/mm² and printing speed 33.3 msec/line (feed pitch 6 lines/mm) to adhere the image-receptive layer to the object. The sheet substrate was then separated. Thus, only the image formed portion could be re-transferred onto the object to form an image on the object. Further, for the sample of Example C1, at the time of the re-transfer, the transparent sheet portion was cut in such a state that the half cut served as the boundary between the removal portion and the portion remaining unremoved. As a result, the transparent sheet covered the surface of the image formed portion and thus functioned as an even firm protective layer, whereby fastness properties could be fully imparted to the image. Further, since the transparent sheet portion could be tidily cut at the half cut portion, the protective layer could be simply transferred onto the image with high accuracy. For the sample of Example C2, since the whole portion except for the image formed portion was previously separated using the half cut as the boundary between the removal portion and the portion remaining unremoved, at the time of the re-transfer, the transparent sheet portion was not cut and covered the surface of the image formed portion and thus functioned as an even firm protective layer, whereby fastness properties could be fully imparted to the image. Further, the protective layer could be transferred onto the image with better accuracy in a simpler manner.

The prints (re-transferred prints) prepared in Example C1 and Example C2 have a hologram image so as to cover the thermally transferred image. Therefore, alteration and forgery can be fully prevented.

In the sample provided in Comparative Example C1, the same white PET-G sheet as used in the examples was put as an object on top of the receptive layer transfer sheet, and the receptive layer was transferred onto the PET-G sheet by means of a thermal head. Next, the thermal transfer sheet as used in the recording of the intermediate transfer recording medium was put on top of the surface of the receptive layer, and a full-color photograph-like image (mirror image) of a face was formed on the receptive layer by means of a thermal head under conditions of head application voltage 12.0 V, pulse width 16 msec, printing cycles 33.3 msec, and dot density 6 dots/line. Further, a protective layer was transferred from the protective layer transfer sheet onto the image forming portion through the application of energy by means of the thermal head. Thus, an image was formed on the object. Next, the samples prepared in the examples and the comparative example were tested for Taber abrasion under conditions of CS-10 as a truck wheel, load on image 500 g, and 1400 cycles. In this case, the samples were visually inspected for disappearance of image. As a result, for both the samples of Example C1 and C2, the image did not disappear, whereas, for the sample of Comparative Example C1, the image disappeared.

As described above, according to the present invention, the process for producing an intermediate transfer recording medium comprising a sheet substrate provided with a resin layer and a transparent sheet provided with a receptive layer, the transparent sheet provided with the receptive layer having been put on top of the sheet substrate provided with the resin layer so that the resin layer faces the transparent sheet on its side remote from the receptive layer, the transparent sheet portion including the receptive layer having been half cut, a hologram formation layer being stacked on the transparent sheet, the resin layer being separable from the transparent sheet, comprises the steps of: providing an original sheet comprising a hologram formation layer stacked on a transparent sheet; forming a receptive layer by coating on the original sheet; applying the transparent sheet on its side remote from the receptive layer onto a sheet substrate in which register marks have been previously provided at respective positions for one screen unit, through a resin layer; and then reading the register marks to perform registration for half cutting and then to perform half cutting.

Thermally transferred images formed using the intermediate transfer recording medium thus obtained have various excellent fastness properties even under severe service conditions, and, by virtue of the adoption of half cutting, the protective layer (transparent sheet) can be transferred onto the image with high accuracy in a simple manner. Further, since a hologram image is provided on the transparent sheet, the alteration and forgery of the object with a thermal transferred image provided thereon can be fully prevented.

### EXAMPLE D1

The following coating liquid for a receptive layer was first coated on a 25 μm-thick polyethylene terephthalate film (Lumirror, manufactured by Toray Industries, Inc.) as a transparent sheet, and the coating was dried to form a receptive layer at a coverage of 3.0 g/m² on a dry basis.

(Coating liquid for receptive layer)

| | |
|---|---|
| Vinyl chloride-vinyl acetate copolymer | 40 parts |
| Acrylic silicone | 1.5 parts |
| Methyl ethyl ketone | 50 parts |
| Toluene | 50 parts |

Next, a 38 μm-thick polyethylene terephthalate film (Lumirror, manufactured by Toray Industries, Inc.) was provided as a sheet substrate. Register marks were formed on the sheet substrate at its positions as shown in FIG. 15 by gravure printing a register mark ink having the following composition at a coverage of 3 g/m² on a dry basis.

| (Register mark ink) | | |
|---|---|---|
| Carbon black | 8.0 | parts |
| Urethane resin (HMS-20, manufactured | 5.0 | parts |
| by Nippon Polyurethane Industry Co., | | |
| Ltd.) | | |
| Methyl ethyl ketone | 38.5 | parts |
| Toluene | 38.5 | parts |

The transparent sheet provided with the receptive layer was then dry laminated onto the sheet substrate provided with the register marks so that the transparent sheet on its side remote from the receptive layer faced the sheet substrate on its side having the register marks through a resin layer having the following composition (coverage 3 g/m² on a dry basis) (see FIG. 15C). Further, in the laminate thus obtained, as shown in FIG. 15D, the transparent sheet 62 portion including the receptive layer 63 was subjected to half cutting 67 by pressing an upper die 74 provided with a cutter blade 76 and a pedestal 75 against the transparent sheet 62 portion including the receptive layer 63. Thus, a continuously wound intermediate transfer recording medium of Example D1 was prepared. The resin layer was separable from the transparent sheet.

(Coating liquid for resin layer) (Easy-adhesion adhesive layer
type)

| | |
|---|---|
| Acrylic resin latex (LX 874, | 30 parts |
| manufactured by Nippon Zeon Co.) | |
| Water | 35 parts |
| Isopropyl alcohol | 35 parts |

### EXAMPLE D2

A receptive layer were provided on a transparent sheet in the same manner as in Example D1. Separately, a 38 μm-thick polyethylene terephthalate film (Lumirror, manufactured by Toray Industries, Inc.) was provided as a sheet substrate. A resin of low density polyethylene (LDPE) with 15% of titanium oxide being dispersed therein was extrusion coated on the sheet substrate to a thickness of 40 μm. Simultaneously with the extrusion, the transparent sheet with the receptive layer formed thereon was EC laminated onto the sheet substrate with the resin layer formed thereon so that the transparent sheet on its side remote from the receptive layer faced the LDPE layer provided on the sheet substrate. In this case, however, as shown in FIG. 15C, register marks were previously printed by the register mark ink as used in Example D1 in the same manner as Example D1 on the sheet substrate in its side where the LDPE layer was to be formed Further, in the laminate thus obtained, as shown in FIG. 15, the transparent sheet portion including the receptive layer was half cut by pressing an upper die, provided with a cutter blade, and a pedestal against the transparent sheet portion including the receptive layer. In addition, the whole portion except for the patch portion including the image forming portion was separated using the half cut as the boundary between the removal portion and the image forming portion remaining unremoved. Thus, a continuously wound intermediate transfer recording medium of Example D2 was prepared. This intermediate transfer recording medium was separable in its portion between the resin layer and the transparent sheet.

### COMPARATIVE EXAMPLE D1

A peel layer having the following composition was formed on a 25 μm-thick polyethylene terephthalate film (Lumirror, manufactured by Toray Industries, Inc.) at a coverage of 1 g/m² on a dry basis. The coating liquid for a receptive layer used in Example D1 was coated onto the peel layer to form a receptive layer at a coverage of 3 g/m² on a dry basis. Further, an adhesive layer having the following composition 1 was formed on the receptive layer at a coverage of 3 g/m² on a dry basis. Thus, a receptive layer transfer sheet was prepared. Separately, the coating liquid for a peel layer used in the preparation of the receptive layer transfer sheet was coated on a 25 μm-thick polyethylene terephthalate film (Lumirror, manufactured by Toray Industries, Inc.) to form a peel layer at a coverage of 1 g/m² on a dry basis. A protective layer having the following composition was formed on the peel layer at a coverage of 3 g/m² on a dry basis. An adhesive layer having the following composition 2 was then formed on the protective layer at a coverage of 3 g/m² on a dry basis. Thus, a protective layer transfer sheet was prepared.

| [Composition of coating liquid for peel layer] | |
|---|---|
| Polyvinyl alcohol resin (AH-17, | 100 parts |
| manufactured by Nippon Synthetic | |
| Chemical Industry Co., Ltd.) | |
| Water | 400 parts |
| [Composition of coating liquid 1 for adhesive layer] | |
| Polymethyl methacrylate resin (BR-106, | 100 parts |
| manufactured by Mitsubishi Rayon Co., | |
| Ltd.) | |
| Foaming agent (F-50, manufactured by | 15 parts |
| Matsumoto Yushi Seiyaku Co., Ltd.) | |
| Titanium oxide (TCA-888, manufactured | 100 parts |
| by Tohchem Products Corporation) | |
| Methyl ethyl ketone/toluene | 300 parts |
| (mass ratio = 1/1) | |
| [Composition of coating liquid for protective layer] | |
| Vinyl chloride-vinyl acetate copolymer | 100 parts |
| (VYHD, manufactured by Union Carbide | |
| Corporation) | |
| Methyl ethyl ketone/toluene | 400 parts |
| (mass ratio = 1/1) | |
| [Composition of coating liquid 2 for adhesive layer] | |
| Acrylic resin (BR-106, manufactured | 100 parts |
| by Mitsubishi Rayon Co., Ltd.) | |
| Methyl ethyl ketone/toluene | 300 parts |
| (mass ratio = 1/1) | |

An image was formed on the receptive layer in the samples provided in the examples and the comparative examples under the following conditions. For the sample provided in Comparative Example D1, a protective layer was further stacked on the image-receptive layer. A thermal transfer sheet (manufactured by Dai Nippon Printing Co., Ltd.), wherein three color transfer layers for yellow, magenta, and cyan as dye layers had been provided in a face serial manner, and each of the intermediate transfer recording media provided in the respective examples were put on top of each other so that each color transfer layer faced the receptive layer. Recording was then carried out by a thermal head of a thermal transfer printer from the backside of the thermal transfer sheet under conditions of head application voltage 12.0 V, pulse width 16 msec, printing cycle 33.3 msec, and dot density 6 dots/line Thus, a full-color photograph-like image (a mirror image) of a face was formed on the receptive layer in the intermediate transfer recording medium.

Next, the intermediate transfer recording medium was put on top of a 600 μm-thick white PET-G sheet (Diafix PG-W, PET-G, manufactured by Mitsubishi Plastic Industries Ltd.) as an object so that the receptive layer with the image formed thereon faced the PET-G sheet. A thermal head and a platen roll were pressed against the assembly, and energy was applied to the image formed portion under conditions of 160 mJ/mm² and printing speed 33.3 msec/line (feed pitch 6 lines/mm) to adhere the image-receptive layer to the object. The sheet substrate was then separated. Thus, only the image formed portion could be re-transferred onto the object to form an image on the object. Further, for the sample of Example D1, at the time of the re-transfer, the transparent sheet portion was cut in such a state that the half cut served as the boundary between the removal portion and the portion remaining unremoved. As a result, the transparent sheet covered the surface of the image formed portion and thus functioned as an even firm protective layer, whereby fastness properties could be fully imparted to the image. Further, since the transparent sheet portion could be tidily cut at the half cut portion, the protective layer could be simply transferred onto the image with high accuracy. For the sample of Example D2, since the whole portion except for the image formed portion was previously separated using the half cut as the boundary between the removal portion and the portion remaining unremoved, at the time of the re-transfer, the transparent sheet portion was not cut and covered the surface of the image formed portion and thus functioned as an even firm protective layer, whereby fastness properties could be fully imparted to the image. Further, the protective layer could be transferred onto the image with better accuracy in a simpler manner.

The peel force for separating the transparent sheet portion provided with the receptive layer from the sheet substrate provided with the resin layer in re-transferring only the image formed portion onto the object after the formation of an image in the receptive layer of the intermediate transfer recording media, provided in Examples D1 and D2, in the same manner as described above was measured by the 180-degree peel method according to JIS Z 0237. As a result, for the sample of Example D1, the peel force was 4.5 gf/inch (44.1 mN/inch) as measured at 290° C. (LDPE), and, for the sample of Example D2, the peel force was 4.0 gf/inch (38.2 mN/inch) as measured at 320° C. (MDPE).

In the sample provided in Comparative Example D1, the same white PET-G sheet as used in the examples was put as an object on top of the receptive layer transfer sheet, and the receptive layer was transferred onto the PET-G sheet by means of a thermal head. Next, the thermal transfer sheet as used: in the recording of the intermediate transfer recording medium was put on top of the surface of the receptive layer, and a full-color photograph-like image (mirror image) of a face was formed on the receptive layer by means of a thermal head under conditions of head application voltage 12.0 V, pulse width 16 msec, printing cycles 33.3 msec, and dot density 6 dots/line. Further, a protective layer was transferred from the protective layer transfer sheet onto the image forming portion through the application of energy by means of the thermal head. Thus, an image was formed on the object. In the sample prepared in Comparative Example D1, for the print with the protective layer transferred thereon, the protective layer was a thin layer having a thickness of several μm, and, thus, the thermally transferred image had unsatisfactory fastness properties. Further, in the sample of Comparative Example D1, since the receptive layer with the image formed thereon had not been half cut, in re-transferring the receptive layer onto the object, the edge was not clearly separated, and a failure of the receptive layer to be transferred occurred.

As described above, according to the present invention, in an intermediate transfer recording medium comprising: a sheet substrate provided with a resin layer; and a transparent sheet provided with a receptive layer, the transparent sheet provided with the receptive layer having been put on top of the sheet substrate provided with the resin layer so that the resin layer faces the transparent sheet on its side remote from the receptive layer, the transparent sheet portion including the receptive layer having been half cut, the resin layer being separable from the transparent sheet, the peel force necessary for separating the transparent sheet portion from the sheet substrate provided with the resin layer at the time of the transfer of the transparent sheet portion including the receptive layer onto an object is in the range of 5 to 100 gf/inch as measured by the 180-degree peel method according to JIS Z 0237. Thermally transferred images formed using this intermediate transfer recording medium had various excellent fastness properties even under severe service conditions, and, by virtue of the adoption of half cutting, the protective layer (transparent sheet) could be transferred onto the image with high accuracy in a simple manner. Further, the regulation of the peel force, for separating the transparent sheet portion from the sheet substrate provided with the resin layer, in the above-defined range could prevent a failure of the transparent sheet portion to be transferred and permitted the transparent sheet portion to be simply transferred on to the object.

### EXAMPLE E1

A coating liquid having the following composition for a receptive layer was coated onto a 25 μm-thick polyethylene terephthalate film (PET) (Lumirror, manufactured by Toray Industries, Inc.) as a transparent sheet, and the coating was dried to form a receptive layer having a thickness of 4 μm on a dry basis. The transparent sheet with the receptive layer formed thereon was then applied to a 25 μm-thick PET film (Lumirror, manufactured by Toray Industries, Inc.) as a support film through a 20 μm-thick layer of low density polyethylene (Mirason 16 P, density 0.923 g/cm³, lower side temperature of die 295° C., manufactured by Mitsui Petrochemical Industries, Ltd.) by extrusion lamination to prepare an intermediate transfer medium. In this case, the support film used was such that the support film on its side, where the low density polyethylene was to be stacked, had been subjected to corona treatment. Further, the extrusion lamination was carried out in such a manner that the untreated (uncoated) surface of the PET film as the transparent sheet remote from the receptive layer came into contact with the low density polyethylene.

### COMPARATIVE EXAMPLE E1

An intermediate transfer medium was prepared in the same manner as in Example E1, except that the lower side temperature of the die at the time of extrusion lamination changed to 305° C.

### COMPARATIVE EXAMPLE E2

An intermediate transfer medium was prepared in the same manner as in Example E1, except that the lower side temperature of the die at the time of extrusion lamination changed to 330° C.

### COMPARATIVE EXAMPLE E3

An intermediate transfer medium was prepared in the same manner as in Example E1, except that the resin to be extrusion laminated was changed to polypropylene (F 329 RA, manufactured by Grand Polymer Co., Ltd., lower side temperature of die 290° C.).

### EXAMPLE E2

An intermediate transfer medium was prepared in the same manner as in Example E1, except that the resin to be extrusion laminated was changed to medium density polyethylene (Sumikathene L 5721, density 0.937 g/cm³, lower side temperature of die 320° C., manufactured by Sumitomo Chemical Co., Ltd.).

### EXAMPLE E3

A coating liquid having the following composition for a receptive layer was coated onto a 25 μm-thick polyethylene terephthalate film (PET) (Lumirror, manufactured by Toray Industries, Inc.) as a transparent sheet, and the coating was dried to form a receptive layer having a thickness of 4 μm on a dry basis. A first resin layer formed of an acrylic resin was stacked in a thickness of 1 μm on a dry basis onto the transparent sheet in its side remote from the receptive layer. Further, a urethane adhesive (Takelac A-969 V/Takenate A-5 (manufactured by Takeda Chemical Industries, Ltd.)=3/1) was stacked thereon to a thickness of 2.5 μm on a dry basis, and, in addition, a 25 μm-thick PET film (Lumirror, manufactured by Toray Industries, Inc.) as a substrate film was dry laminated thereto to prepare an intermediate transfer medium.

### EXAMPLE E4

A coating liquid having the following composition for a receptive layer was coated onto a 25 μm-thick polyethylene terephthalate film (PET) (Lumirror, manufactured by Toray Industries, Inc.) as a transparent sheet, and the coating was dried to form a receptive layer having a thickness of 4 μm on a dry basis. A first resin layer formed of an acrylic resin was stacked in a thickness of 1 μm on a dry basis onto the transparent sheet in its side remote from the receptive layer. Further, a second resin layer formed of an ethylene-vinyl acetate copolymer resin was stacked thereon in a thickness of 1 μm on a dry basis. The laminate was then applied to a 25 μm-thick PET film (Lumirror, manufactured by Toray Industries, Inc.) as a support film through a 20 μm-thick layer of low density polyethylene (mirason 16 P, density 0.923 g/m², lower side temperature of die 330° C., manufactured by Mitsui Petrochemical Industries, Ltd.) by extrusion lamination to prepare an intermediate transfer medium.

### COMPARATIVE EXAMPLE E5

A coating liquid having the following composition for a receptive layer was coated onto a 25 μm-thick polyethylene terephthalate film (PET) (Lumirror, manufactured by Toray Industries, Inc.) as a transparent sheet, and the coating was dried to form a receptive layer having a thickness of 4 μm on a dry basis. Separately, a 25 μm-thick PET film (Lumirror, manufactured by Toray Industries, Inc.) was provided as support film, and a resin layer was provided on the support film to a thickness of 3 μm on a dry basis. The transparent sheet with the receptive layer formed thereon was dry laminated onto the support film with the resin layer provided thereon so that the surface of the transparent sheet remote from the receptive layer faced the resin layer. Thus, an intermediate transfer medium was prepared.

| [Composition of coating liquid for receptive layer] | |
|---|---|
| Vinyl chloride-vinyl acetate copolymer | 100 parts |
| (VYHD, manufactured by Union Carbide | |
| Corporation) | |
| Epoxy-modified silicone (KF-393, | 8 parts |
| manufactured by The Shin-Etsu Chemical | |
| Co., Ltd.) | |
| Amino-modified silicone (KS-343, | 8 parts |
| manufactured by The Shin-Etsu Chemical | |
| Co., Ltd.) | |
| Methyl ethyl ketone/toluene | 400 parts |
| (mass ratio = 1/1) | |

For the intermediate transfer media thus prepared, the image non-forming portion was half cut and was removed, followed by continuous winding. The samples thus obtained were evaluated for releasability and blocking. The results are shown in Table E1 below.

TABLE E1

| | | 1st resin | 2nd resin | 3rd resin | | Releas- | Block- |
|---|---|---|---|---|---|---|---|
| | Transparent sheet | layer | layer | layer | Support film | ability | ing |
| Ex. 1 | 25 μm PET (un-treated | LDPE 290° C. | — | — | 25 μm PET (co-rona | 3 | ◯ |
| | surface) | | | | treatment) | | |
| EX. 2 | ↑ | MDPE 320° C. | — | — | ↑ | 3 | ◯ |
| Comp. Ex. 1 | ↑ | LDPE 305° C. | — | — | ↑ | 5 | ◯ |
| Comp. Ex. 2 | ↑ | LDPE 330° C. | — | — | ↑ | 5 | ◯ |
| Comp. Ex. 3 | ↑ | PP 290° C. | — | — | ↑ | 1 | ◯ |
| Ex. 3 | ↑ | Acryl + PEs | Urethane resin | — | ↑ | 3 | ◯ |
| Ex. 4 | ↑ | ↑ | Ethylene-vinyl | LDPE | ↑ | 3 | ◯ |
| | | | acetate | 330° C. | | | |
| Comp. Ex. 4 | ↑ | NBR | — | — | ↑ | 4 | × |

Releasability: The releasability of the transparent sheet from the first resin layer provided on the support sheet was evaluated.
5 - heavy, 3 - moderate, and 1 - light.
Blocking: After the image non-forming portion was removed, the intermediate transfer medium was rolled. The roll was then allowed to stand under conditions of 40° C. and free for 48 hr, and sticking between the first resin layer and the backside of the support sheet was then evaluated.

As is apparent from the above results, the adoption of the construction of the fifth invention could simultaneously realize a property such that blocking does not occur upon winding in a roll form of the intermediate transfer medium with the image non-forming portion removed therefrom and a property such that, at the time of unwinding, the releasability of the transparent sheet from the resin layer provided on the support sheet is good.

1. An intermediate transfer recording medium comprising: a sheet substrate provided with a resin layer; and a transparent sheet provided with a receptive layer, said transparent sheet provided with the receptive layer having been put on top of the sheet substrate provided with the resin layer so that the resin layer faces the transparent sheet on its side remote from the receptive layer, the resin layer being separable from the transparent sheet to transfer the transparent sheet provided with the receptive layer onto an object, the transparent sheet portion including the receptive layer having been half cut in a specific shape.

2. The intermediate transfer recording medium according to claim 1, wherein the half cutting has been carried out by removing the transparent sheet provided with the receptive layer in a predetermined width around the outer periphery of the region to be transferred onto the object.

3. The intermediate transfer recording medium according to claim 2, wherein the transparent sheet, provided with the receptive layer, in its removed portion is continuous in the direction of flow.

4. The intermediate transfer recording medium according to claim 1, which is in such a form that has been continuously wound.

5. The intermediate transfer recording medium according to claim 1, which has an identification mark for detecting the half cut.

6. A method for image formation, comprising the steps of: providing the intermediate transfer recording medium according to any one of claims 1 to 5; forming a transfer image on the receptive layer in the intermediate transfer recording medium; and re-transferring only the image-formed portion onto an object to form an image on the object.

7. A method for image formation, comprising the steps of: providing the intermediate transfer recording medium according to any one of claims 1 to 5; forming a transfer image on the receptive layer in the intermediate transfer recording medium; transferring an adhesive layer onto the receptive layer; and re-transferring only the portion with the image and the adhesive layer formed thereon onto an object to form an image on the object.

8. An intermediate transfer recording medium comprising: a sheet substrate provided with a resin layer; and a transparent sheet provided with a receptive layer, said transparent sheet provided with the receptive layer having been put on top of the sheet substrate provided with the resin layer so that the resin layer faces the transparent sheet on its side remote from the receptive layer, the resin layer being separable from the transparent sheet to transfer the transparent sheet provided with the receptive layer onto an object, the resin layer being formed of a hydrosilylation-type silicone pressure-sensitive adhesive.

9. The intermediate transfer recording medium according to claim 8, wherein the peel force between the resin layer and the transparent sheet is 0.01 to 0.5 N/inch.

10. The intermediate transfer recording medium according to claim 8, wherein the rein layer further comprises a filler.

11. An intermediate transfer recording medium comprising: a sheet substrate provided with a resin layer; a transparent sheet provided with a receptive layer, the transparent sheet provided with the receptive layer having been put on top of the sheet substrate provided with the resin layer so that the resin layer faces the transparent sheet on its side remote from the receptive layer, the transparent sheet portion including the receptive layer having been half cut, the resin layer being separable from the transparent sheet; and a hologram formation layer provided between the transparent sheet and the receptive layer.

12. The intermediate transfer recording medium according to claim 11, wherein the whole portion except for the image forming portion can be separated and removed using the half cut as a boundary between the image forming portion remaining unremoved and the removal portion.

13. The intermediate transfer recording medium according to claim 1, wherein a patch portion as the image forming portion, which has been separated by the half cutting, has a size smaller than an object in its whole area on which an Image is to be transferred.

14. The intermediate transfer recording medium according to claim 11, wherein a patch portion as the image forming portion, which has been separated by the half cutting, has a partially removed portion relative to an object.

15. The intermediate transfer recording medium according to claim 11, wherein the total width of the intermediate transfer recording medium is larger than the width of an object in its face on which an image is to be transferred.

16. A process for producing an intermediate transfer recording medium comprising a sheet substrate provided with a resin layer and a transparent sheet provided with a receptive layer, the transparent sheet provided with the receptive layer having been put on top of the sheet substrate provided with the resin layer so that the resin layer faces the transparent sheet on its side remote from the receptive layer, the transparent sheet portion including the receptive layer having been half cut, a hologram formation layer being stacked on the transparent sheet, the resin layer being separable from the transparent sheet, said process comprising the steps of: providing an original sheet comprising a hologram formation layer stacked on a transparent sheet; forming a receptive layer by coating on the original sheet; applying the transparent sheet on its side remote from the receptive layer onto a sheet substrate, in which register marks have been previously provided at respective positions for one screen unit, through a resin layer; and then reading the register marks to perform registration for half cutting and then to perform half cutting.

17. The process according to claim 16, wherein, after the half cutting, the whole portion except for the image forming portion is separated and removed using the half cut as the boundary between the removal portion and the image forming portion remaining unremoved.

18. A method for image formation, comprising the steps of: providing the intermediate transfer recording medium according to any one of claims 11 to 15; forming a transfer image on the receptive layer; and re-transferring only the portion with the image formed thereon onto an object to form an image on the object.

19. An intermediate transfer recording medium comprising: a sheet substrate provided with a resin layer; and a transparent sheet provided with a receptive layer, the transparent sheet provided with the receptive layer having been put on top of the sheet substrate provided with the resin layer so that the resin layer faces the transparent sheet on its side remote from the receptive layer, the transparent sheet portion including the receptive layer having been half cut, the resin layer being separable from the transparent sheet, the peel force necessary for separating the transparent sheet portion from the sheet substrate provided with the resin layer at the time of the transfer of the transparent sheet portion including the receptive layer onto an object being in the range of 5 to 100 gf/inch as measured by the 180-degree peel method according to JIS Z 0237.

20. The intermediate transfer recording medium according to claim 19, wherein the whole portion except for the image forming portion can be separated and removed using the half cut as the boundary between the image forming portion remaining unremoved and the removal portion.

21. The intermediate transfer recording medium according to claim 19, wherein a patch portion as the image forming portion, which has been separated by the half cutting, has a size smaller than the object in its whole area on which an image is to be transferred.

22. The intermediate transfer recording medium according to claim 19, wherein a patch portion as the image forming portion, which has been separated by the half cutting, has a partially removed portion relative to the object.

23. The intermediate transfer recording medium according to claim 19, wherein the total width of the intermediate transfer recording medium is larger than the width of the object in its face on which an image is to be transferred.

24. A method for image formation, comprising the steps of: providing the intermediate transfer recording medium according to any one of claims 19 to 23; forming a transfer image on the receptive layer; and re-transferring only the portion with the image formed thereon onto the object to form an image on the object.

25. An intermediate transfer recording medium comprising: a sheet substrate provided with a resin layer; and a transparent sheet provided with a receptive layer, said transparent sheet provided with the receptive layer having been put on top of the sheet substrate provided with the resin layer so that the resin layer faces the transparent sheet on its side remote from the receptive layer, the resin layer being separable from the transparent sheet to transfer the transparent sheet provided with a receptive layer onto an object, the resin layer having a single layer structure or a multi-layer structure of two or more layers.

26. The intermediate transfer recording medium according to claim 25, wherein the resin layer is formed of a polyolefin resin stacked on the sheet substrate by extrusion coating.

27. The intermediate transfer recording medium according to claim 26, wherein the polyolefin resin is low density polyethylene.

28. The intermediate transfer recording medium according to claim 27, wherein the lower side temperature of a die at the time of extrusion of the low density polyethylene is 295° C. or below.

29. The intermediate transfer recording medium according to claim 25, wherein the polyolefin resin is medium density polyethylene.

30. The intermediate transfer recording medium according to claim 25, wherein the resin layer has a two-layer structure of a first resin layer and a second resin layer provided in that order from the transparent sheet side and the first resin layer is composed mainly of an acrylic resin.

31. The intermediate transfer recording medium according to claim 30, wherein the second resin layer is an adhesive layer.

32. The intermediate transfer recording medium according to claim 25, wherein the resin layer has a three-layer structure of a first resin layer, a second resin layer, and a third resin layer provided in that order.

33. The intermediate transfer recording medium according to claim 25, wherein the transparent sheet portion including the receptive layer has been half cut.

34. The intermediate transfer recording medium according to claim 33, wherein the transparent sheet including the receptive layer in its half cut portion, on which no image is to be formed, has been previously removed.

35. A printing method comprising the step of, in using the intermediate transfer recording medium according to any one of claims 25 to 34, printing an image in an area larger than a patch portion as the image forming portion.
